(19) United States
(12) Patent Application Publication
(10) Pub. No.: US 2019/0074467 A1
(43) Pub. Date: Mar. 7, 2019

(54) SOLVENT COATABLE OLED EMITTER COMPOSITION CONTAINING NON-PLASMONIC MOLECULAR NOBLE METAL NANOPARTICLES AND EMITTER MATERIALS IN NONCRYSTALLIZABLE MOLECULAR ORGANIC SEMICONDUCTORS

(71) Applicant: Molecular Glasses, Inc., Rochester, NY (US)

(72) Inventor: Rajarshi Chakraborty, Rochester, NY (US)

(73) Assignee: Molecular Glasses, Inc., Rochester, NY (US)

(21) Appl. No.: 16/013,704

(22) Filed: Jun. 20, 2018

Related U.S. Application Data
(60) Provisional application No. 62/553,563, filed on Sep. 1, 2017.

(51) Int. Cl. H01L 51/50; H01L 51/00; C09K 11/06

(52) U.S. Cl. CPC H01L 51/5016; C09K 2211/18; C09K 11/06; H01L 51/0053

(57) ABSTRACT

Embodiments of this disclosure includes a solvent coatable emitter composition that includes an emitter material; and noble metal nanoparticles having a median size of less than or equal to 5 nanometers, wherein the size distribution is less than 20%.

### CROSS REFERENCE TO RELATED APPLICATIONS

This application claims the benefit of U.S. Provisional Application Ser. No. 62/553,563 filed Sep. 1, 2017, the entire contents of which are incorporated by reference.

### TECHNICAL FIELD

Embodiments of the present disclosure generally relate to organic light emitting diode-devices comprising a solvent coatable light emitting layer that contains noble metal particles with average particle size less than 5 nanometers, an emitter material and a non-crystallizable molecular organic semiconductor. The resulting device has enhanced light emission, lower efficiency roll-off, and improved operating stability.

### BACKGROUND

While organic electroluminescent (EL) devices have been known for over two decades their performance limitations have represented a barrier to many desirable applications. In simplest form, an organic EL device is comprised of an anode for hole injection, a cathode for electron injection and an organic medium sandwiched between these electrodes to support charge recombination that yields emission of light. These devices are also commonly referred to as organic light-emitting diodes, or OLEDs. The organic layers in earlier devices, usually composed of a polycyclic aromatic hydrocarbon, were very thick (much greater than 1 μm). Consequently, operating voltages were very high, often greater than 100V.

More recent organic EL devices include an organic EL element consisting of extremely thin layers (e.g. <1.0 μm) between the anode and the cathode. Herein, the organic EL element encompasses the layers between the anode and cathode electrodes. Reducing the thickness lowered the resistance of the organic layer and has enabled devices that operate at much lower voltage. In a basic two-layer EL device structure, described first in U.S. Pat. No. 4,356,429, one organic layer of the EL element adjacent to the anode is specifically chosen to transport holes, therefore, it is referred to as the hole-transporting layer, and the other organic layer is specifically chosen to transport electrons, referred to as the electron-transporting layer. The interface between the two layers provides an efficient site for the recombination of the injected hole/electron pair and the resultant electroluminescence.

There have also been proposed three-layer organic EL devices that contain an organic light-emitting layer (LEL) between the hole-transporting layer and electron-transporting layer, such as that disclosed by Tang et al [J. Applied Physics, Vol. 65, Pages 3610-3616, 1989]. The light-emitting layer commonly consists of a host material doped with a guest material-dopant, which results in an efficiency improvement and allows color tuning.

Since these early inventions, further improvements in device materials have resulted in improved performance in attributes such as operational lifetime, color, luminance efficiency and manufacturability.

Notwithstanding these developments, there are continuing needs for organic EL device components that will provide better performance and, particularly, long operational lifetimes. This is especially true for phosphorescent emitter-containing LEL, particularly blue phosphorescent emitter-containing LEL. There are a number of approaches to achieve better operational lifetimes disclosed in prior publications. An improvement in operational stability due to admixing hole transport material to emissive electron transport was reported by Z. Popovich et al. in Proceeding of the SPIE, vol. 3476, 1998, p. 68-73. An improvement in both device efficiency and operational lifetime was reported to result from doping emissive layer by fluorescent dye such as dimethyl quinacridone [J. Shi and C. W. Tang Appl. Phys. Lett., vol. 70, 1997, p. 1665-1667]. Further improvements in operational lifetime of the devices doped with fluorescent dyes were realized by co-doping emissive layer with anthracene derivatives [JP 99273861, JP 284050]. Co-doping by rubrene has been reported to result in 60% increase in operational half-life of the device doped with red fluorescent dye DCJTB [EP 1162674]. This improvement is still insufficient for many commercial applications of the OLED devices. It is desirable to achieve further improvements in OLED stability.

The conversion of electrical energy into light is mediated by excitons. An exciton is like a two particle system: one is an electron excited into an unfilled higher energy orbital of a molecule while the second is a hole created in the ground state due to the excitation of the electron. However, excitons also play an important role in the failure of high efficiency OLED devices. Thus exciton management is essential for improved OLED performance. In their 2012 review, S. Reineke, and M. A. Baldo (S. Reineke and M. A. Baldo, Phys. Status Solidi A 209, 12. 2012 2341-2353) identified three processes that account for triplet exciton quenching: (1) Triplet-polaron quenching (TPA); (2) Electric field induced exciton dissociation; (3) Triplet-triplet annihilation (TTA).

Of the three processes, TTA is the only process that scales with the square of the exciton density, and dominates the decrease in efficiency at high exciton densities (efficiency roll-off). TTA in a doped film can have different underlying mechanisms. One of them is a single-step long-range interaction (dipole-dipole coupling), based on Forster-type energy transfer. The rate of TTA energy transfer is proportional to the spectral overlap of the phosphorescent emission of the donor and the absorption of the acceptor excited triplet state. In a host-guest system where the triplet level of the host is higher than the guest, the single-step long-range mechanism should be the only channel of TTA for typical guest concentrations ranging from 1 to 10 mole %.

An additional TTA channel is mediated by hopping-assisted migration (Dexter-type energy transfer) of triplet excitons in clusters of guest molecules. This mechanism was identified in a TCTA: Ir(ppy)3 guest-host system at concentration around 10 mole %. High angle annular dark field (HAAD) TEM has indeed revealed the presence of Ir(ppy) clusters and aggregation.

More recently, Y. Zhang, and H. Aziz (Yingjie Zhang, and Hany Aziz, ACS Appl. Mater. Interfaces, 2016) reports that the degradation mechanisms in blue PHOLEDs are fundamentally the same as those in green PHOLEDs. Their investigations show that quantum yield of both the host and the emitter in the EML degrade due to exciton-polaron interactions, and that the deterioration in material quantum yield plays the primary role in device degradation under operation. The results show that charge balance is also affected by exciton-polaron interactions, but the phenomenon plays a secondary role in comparison. They concluded that the limited stability of the blue devices is a result of faster deterioration in the quantum yield of the emitter.

Molaire in US Application Publication No. 2017/0237004, OLED DEVICES WITH IMPROVED LIFETIME USING NON-CRYSTALLIZABLE MOLECULAR GLASS MIXTURE HOSTS discloses the use of high-entropy molecular glass host in the light-emitting layer (LEL)

Bazan, in U.S. Pat. No. 6,999,222, discloses optoelectronic devices and methods for their fabrication having enhanced and controllable rates of the radiative relaxation of triplet light emitters are provided exemplified by organic light emitting devices based on phosphorescent materials with enhanced emission properties. Acceleration of the radiative processes is achieved by the interaction of the light emitting species with surface plasmon resonances in the vicinity of metal surfaces. Non-radiative Forster-type processes are efficiently suppressed by introducing a transparent dielectric or molecular layer between the metal surface and the chromophore. For materials with low emission oscillator strengths (such as triplet emitters), the optimal separation distance from the metal surface is determined, thus suppressing energy transfer and achieving a significant acceleration of the emission rate.

Typically, metal nanoparticles having a diameter of eight nanometers or larger are required for plasma resonance coupling (Different sized luminescent gold nanoparticles, Jie Zheng, Chen Zhou, Mengxiao Yu and Jinbin Liu, Nanoscale, 2012, 4, 4073). Luminescent gold nanoparticles can be divided into molecular luminescent gold nanoparticles and plasmonic ones.

### SUMMARY

The light-emitting layers (LEL) in organic light emitting diode (OLED) device, regardless of the emitter material and emission wavelength, shortens the excited lifetime, improves light emission, efficiency roll-off, and device lifetime. Ongoing needs exist to optimize the emitter material.

Embodiments of this disclosure include solvent coatable emitter compositions containing an emitter material and noble metal nanoparticles. The noble metal nanoparticles comprise a median size of 5 nanometers or less than 5 nanometers.

The OLED devices according to this disclosure contain a solvent coatable light emitting layer exhibiting short excited state lifetime and improved operational stability.

In one or more embodiments, the solvent coatable light emitting composition includes a non-crystallizable molecular glass organic semiconductor, emitter material dissolved in a solvent, and non-plasmonic molecular noble metal nanoparticles.

The non-plasmonic molecular noble metal nanoparticles include gold nanoparticles, copper nanoparticles, and silver nanoparticles. These noble metal nanoparticles have a median size of equal to or less than 5 nanometers (nm), in which the distribution is less than 20%.

In embodiments, the OLED multilayer electroluminescent device includes a cathode, an anode, a light-emitting layer (LEL) disposed therebetween, and charge-transporting layers disposed between (A) the cathode and the light-emitting layer, (B) the anode and the light-emitting layer, or (C) both (A) and (B). The light-emitting layer (LEL) includes a high-entropy non-crystallizable molecular semiconductor mixture host, an emitter, and non-plasmonic molecular noble metal particles size of equal to or less than 5 nm.

In embodiments, methods of making a light-emitting layer include dissolving an emitter in a solvent to form an emitter solvent. Non-plasmonic molecular noble metal nanoparticles are added to the emitter solvent to form a nanoparticle/emitter solution. The nanoparticle/emitter solution is coated onto a host material; and the solvent is removed from the host material at a temperature of 25° C. or less than 25° C.

In one or more embodiments, a method of making a light-emitting layer includes forming a light-emitting layer. The light-emitting layer is coated with non-plasmonic molecular noble metal solution, wherein non-plasmonic molecular noble metal solution comprises non-plasmonic molecular noble metal nanoparticles dispersed in solvent. The solvent is removed from the light-emitting later at a temperature less than 50° C.

### BRIEF DESCRIPTION OF FIGURES

FIG. 1 shows a division of luminescent gold particles in two major classes: molecular nanoparticles and plasmonics nanoparticles.

FIG. 2 shows an experimental setup for collecting delayed luminescence.

FIG. 3 shows a collection of exponential decay of excited states.

FIG. 4 is a graph of an absorption spectrum of gold (Au) nanoparticles dispersed in polystyrene (drop-cast film).

FIG. 5 shows normalized absorption and emission spectra of tris [1-phenylisoquinoline-C2, N] iridium(III) (Ir(Piq)3)films at room temperature.

FIG. 6 shows normalized PL spectra of PROPRIETARY PHOSPHORESCENT YELLOW EMITTER in HT-1700 host films at room temperature.

FIG. 7 shows delayed luminescence of Ir(PiQ)3 film at various time delays.

FIG. 8 shows delayed luminescence of gold nanoparticles (2 nm) doped Ir(PiQ)3 film at various time delays.

FIG. 9 shows decay dynamics of drop cast films at room temperature. The samples were excited with 532 nm laser pulses at room temperature under vacuum.

FIG. 10 shows delayed luminescence of proprietary phosphorescent yellow emitter film at various time delays.

FIG. 11 shows delayed luminescence of Au Np doped of proprietary phosphorescent yellow emitter film at various time delays.

FIG. 12 shows normalized decay dynamics of drop cast films at room temperature.

FIG. 13 shows the quantum yield for DMAC-DPS neat films as a function of gold nanoparticle concentration.

FIG. 14 shows the lambda max for DMAC-DPS neat films as a function of gold nanoparticle concentration.

FIG. 15 shows the quantum yield for ambipolar mixture 136 and DMAC-DPS 90:10 wt/wt mixture as a function of gold nanoparticle concentration.

FIG. 16 shows the lambda max for ambipolar mixture 136 and DMAC-DPS 90:10 wt/wt mixture as a function of gold nanoparticle concentration.

FIG. 17 shows the electroluminance curves for OLED devices incorporating a gold nanoparticle containing emitter layer as a function of concentration.

FIG. 18 shows the comparative luminance for OLED devices incorporating a gold nanoparticle containing emitter layer as a function of concentration.

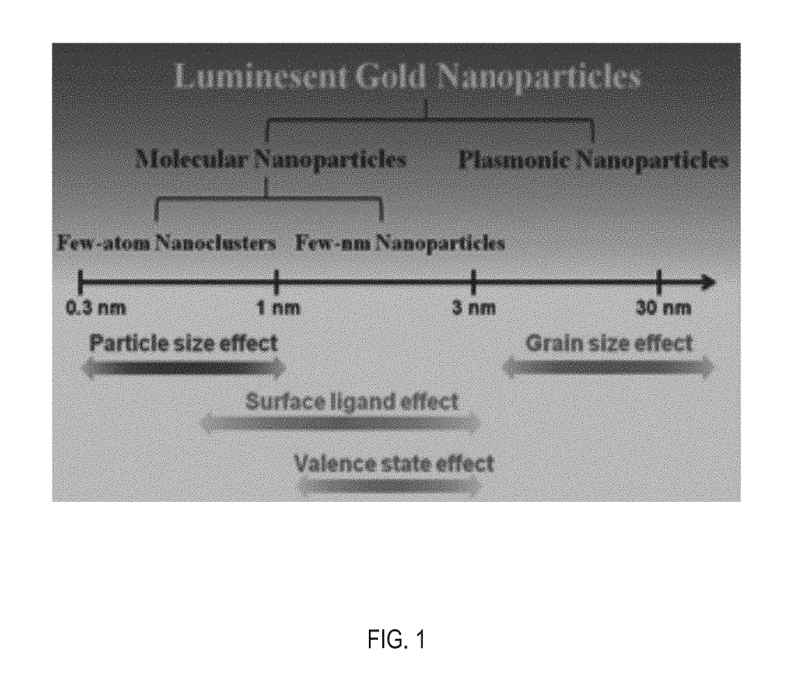

### DETAILED DESCRIPTION

Throughout this document, the following terms will have the following meanings.

The term “prompt fluorescence” means instantaneous fluorescence in few nanoseconds.

The term “delayed luminescence” means fluorescence and/or phosphorescence which is emitted after instantaneous fluorescence.

The term “time gated data” means the internal charge coupled device camera comprised of a sensor and a gated image intensifier. The image intensifier could be switched rapidly on and off through the application of positive and negative potentials and thus acting as a very fast shutter. The time between the excitation of the sample and the opening of the shutter is referred to as the time delay. The time that the gate voltage remained on is called the gate width. The spectral information/data collected by varying the delay and the gate width is called time gated data.

The term “Gate width” means the time that the gate voltage remained on.

The term “steady state spectroscopy” means that the samples are continuously irradiated with a continuous beam of light, excited states are continuously created and eliminated.

The term “blue shift” means displacement of the emission peak towards shorter wavelength.

The term “red shift” means displacement of the emission peak towards shorter wavelength.

The term “full width at half maxima (FWHM)” means the width of a spectrum at half of the maximum intensity.

“Time resolved emission” means the emission recorded at various time scales.

The term “host” means a non-crystallizable organic glass mixture.

In one or more embodiments, the solvent coatable light emitting composition includes a non-crystallizable molecular glass organic semiconductor, emitter material dissolved in a solvent, and non-plasmonic molecular noble metal nanoparticles having a median size of less than or equal to 5 nanometers, in which the size distribution is less than 20%.

In some embodiments, the non-plasmonic molecular noble metal nanoparticles of the emitter composition have median size of less than or equal to 2 nanometers in which the size distribution is less than 20%.

In one or more embodiments, the non-plasmonic molecular noble metal nanoparticles are chosen from gold nanoparticles, silver nanoparticles, platinum nanoparticles, palladium nanoparticles, rhodium nanoparticles, iridium nanoparticles, or copper nanoparticles. The nanoparticles are typically stabilized in aqueous or organic solvents. Typical stabilizers include dodecanethiol, citrate surfactant, gelatin (GEL), polyvinylpyrrolidone (PVP), or polyvinyl alcohol (PVA), four-chained disulfide, tetraalkylammonium cations, ionic liquids.

In one or more embodiments, the emitter composition has a refractive index of less than the refractive index of a comparative emitter composition. The comparative emitter composition includes the same components and the same amount of each component as compared to the emitter compositions of this disclosure, except that the comparative emitter composition does not include the non-plasmonic molecular noble metal nanoparticles having a median size of less than or equal to 5 nanometers, wherein the size distribution is less than 20%.

In embodiments, the organic light emitting diode (OLED) device includes a cathode, an anode, a light-emitting layer (LEL) disposed therebetween, and charge-transporting layers disposed between (A) the cathode and the light-emitting layer, (B) the anode and the light-emitting layer, or (C) both (A) and (B). The light-emitting layer (LEL) includes a high-entropy non-crystallizable molecular semiconductor mixture host, an emitter, and non-plasmonic molecular noble metal particles size of equal to or less than 5 nm.

In some embodiments, the OLED device is bottom emitting. In other embodiments, the OLED device is top emitting, and in further embodiments, the OLED device may be both top emitting and bottom emitting.

In some embodiments, the OLED device includes a multilayer electroluminescent device comprising a cathode, an anode, optional charge-injecting layers, charge-transporting layers, and a light-emitting layer (LEL). The light-emitting layer includes a neat host or a mixed-host, wherein the neat host or both members of the mixed host are high-entropy non-crystallizable molecular semiconductor mixtures comprising three or more than three components. The host material can be hole-transporting, electron-transporting, or ambipolar, that is capable on transporting both positive and negative charges (electrons). In some embodiments, the host material includes a mixed-host, which is a mixture of a hole-transporting high-entropy non-crystallizable material and an electron-transporting high-entropy non-crystallizable material. However, in some embodiments of the OLED, as demonstrated in U.S. Patent Publication No. 2015/0053894, the high-entropy non-crystallizable materials can be mixed with highly crystalline materials at high concentration to yield a new mixture that is non-crystallizable and soluble. Thus, the mixed-host may be either a mixture of a high-entropy hole-transporting material, as described herein, and an electron-transporting crystallizable material, or a high-entropy electron-transporting material and a hole-transporting crystallizable material. Whereas, neat host materials may contain either hole transporting properties or electron transporting properties.

To achieve a highly efficient phosphorescent OLED, triplet emitter-dopants are usually embedded in a suitable host to reduce concentration quenching. A good host material should fulfill the following requirements: (1) the triplet energy must be higher compared to the emitter, which prevents energy back transfer to the host material, (2) suitable energy levels aligned with the neighboring layers for efficient charge carrier injection to obtain a low driving voltage; (3) decent charge carrier transporting abilities to increase the chance for hole and electron recombination within the emitting layer; and (4) the HOMO (highest occupied molecular orbital) of the host materials should be deeper than that of the emitters, while the LUMO (lowest unoccupied molecular orbital) of the host materials should be shallower than that of the emitters.

Blue phosphorescent and thermally assisting delayed fluorescent emitters have higher triplet energy than green, yellow and red emitters, in that order. Thus, blue emitters require higher triplet host (2.8 eV to 3.0 eV) than green, yellow and red emitters.

In mixed-host systems, the triplet energy of the individual host should meet the requirements described above such that the triplet energy of the mixed host is greater than the emitter. The triplet energy of the host materials is estimated from the phosphorescence emission of the host at or below 77 K.

In one or more embodiments, the light-emitting layer of the device of this disclosure includes host material, emitter material, and non-plasmonic noble metal nanoparticles having a median size of less than or equal to 5 nanometers, wherein the size distribution is less than 20%. In one or more embodiments, the emitter material includes an emitter-dopant. The emitter-dopant may be present in an amount of up to 20 wt. % of the host, from 0.1 to 18.0 wt. % of the host, from 0.5 to 10 wt.% of the host, or from 0.1 to 5 wt. %. The emitter-dopant may include a fluorescent emitter, a phosphorescent emitter, a thermally delayed fluorescent emitter, or a combination thereof.

In embodiments, the solvent of the solvent coatable emitter composition may include polar organic solvents. A non-limiting list of polar organic solvents includes: chloroform, tetrahydrofuran (THF), dichloromethane, acetonitrile, acetone, methylacetate, ethyl acetate, and toluene.

The emitter dopant can be a fluorescent emitter, a phosphorescent emitter, or a thermally delayed fluorescent emitter. The composition of the host is adjusted for the type of emitter. For example, high-triplet energy host is required for phosphorescent and thermally activated delayed fluorescence (TADF) emitters.

Examples of fluorescent emitters include coumarin dyes such as 2,3,5,6-1H,4H-tetrahydro-8-trichloromethylquinolizino(9,9a,1gh) coumarin, cyanine-based dyes such as 4-dicyanomethylene-2-methyl-6-(p-dimethylaminostyrylene)-4H-pyran, pyridine-based dyes such as 1-ethyl-2-(4-(p-dimethylaminophenyl)-1,3 -butadienyl)-pyridium perchlorate, xanthene-based dyes such as rhodamine B, and oxazine-based dyes. The fluorescent material can also include inorganic phosphors.

Examples of phosphorescent emitters include Ir(ppy)3 (fac tris(2-phenylpyridine) iridium) (green) or FIrpic (iridium(III)bis[4,6-di-(fluorophenyl)-pyridinato-N, C2′] picolinate) (blue), a red phosphorescent dopant RD61 available from UDC. Other blue phosphorescence emitter include iridium (III) bis(4′,6′-difluorophenylpyridinato) tetrakis(1-pyrazolyl)borate (FIr6) (HOMO level=6.1 eV, LUMO level=3.1 eV, T1=2.71 eV), iridium (III) bis[4,6-(di-fluorophenyl)-pyridinato-N, C2′]picolinate (FIrpic), iridium (III) tris[N-(4′-cyanophenyl)-N′-methylimidazole-2-ylidene-C2, C2′] (Ir(cn-pmic)3), tris((3,5-difluoro-4-cyanophenyl)pyridine)iridium (FCNIr), and Ir(cnbic)3, and complexes of heavy atom metals such as platinum (Pt), rhenium (Re), ruthenium (Ru), copper (Cu), and osmium (Os). (2,4-Pentanedionato) bis[2-(2-quinolinyl) phenyl] iridium(III), Bis[5-methyl-2-(2-pyridinyl-N) Phenyl-C] (2,4-pentanedionato-O2, O4) iridium(III), Bis [2-(2-benzothiazolyl-N3)phenolato-O]zinc,Bis [2-(4,6-difluorophenyl)pyridinato-C2,N] (picolinato)iridium(III), Bis [2-(1-isoquinolinyl-N)phenyl-C](2,4-pentanedionato-O2,O4)iridium(III), Tris[2-(benzo [b]thiophen-2-yl)pyridinato-C3,N]iridium(III), Bis [2-(1isoquinolinyl-N)phenyl-C] (2,4-pentanedionato-O2,O4)iridium(III), Bis[2-(2-pyridinyl-N)phenyl-C](2,4-pentanedionato-O2,O4)iridium(III), Dichlorotris(1,10-phenanthroline)ruthenium(II) hydrate, Bis(2-benzo [b]thiophen-2-ylpyridine)(acetylacetonate)iridium(III), Lithium tetra(2-methyl-8-hydroxyquinolinato)boron, bis(2,2′-bipyridyl)dichlororuthenium(II) hexahydrate, and other emitting materials capable of phosphorescence.

Examples of thermally activated delayed fluorescence (TADF) emitter-dopants include, but are not limited to: 2,5-bis(carbazol-9-yl)-1,4-dicyanobenzene (4CzTPN described in Mater. Horiz., 2014, 1, 264-269; the Organic Luminescent Compound with Delayed Fluorescence of US application 20140145149 to Lin; Chun et al; the delayed fluorescence material of US application 20140138669 to Nakagawa, and Tetsuya (Fukuoka, J P) Adachi, Chihaya (Fukuoka, J P) the benzothiophene or benzofuran fused to a carbazoles delayed fluorescent material of US application 20140145151 to Xia;

The light-emitting layer (LEL) of this disclosure also includes noble metal nanoparticles having a size median of equal to or less than 5 nm, or equal to or less than 2 nm. Examples of noble metal nanoparticles include gold nanoparticles, silver nanoparticles, platinum nanoparticles, palladium nanoparticles, rhodium nanoparticles, iridium nanoparticles, or copper nanoparticles. The nanoparticles are typically stabilized in aqueous or organic solvents. Typical stabilizers include dodecanethiol, citrate surfactant, gelatin (GEL), polyvinylpyrrolidone (PVP), or polyvinyl alcohol (PVA), four-chained disulfide, tetraalkylammonium cations, ionic liquids.

In some embodiments, the non-plasmonic molecular noble metal nanoparticles are incorporated into the light emitting layer via a solvent coatable noble metal solution, in which noble metal nanoparticles are dissolved in a solvent, organic or aqueous, and added to an emitter solution to form a noble metal/emitter solution. The noble metal/emitter solution is applied to the host material. The solvent is evaporated at room temperature or temperatures less than 25° C.

In some embodiments, the nanoparticle/emitter solution has a concentration of non-plasmonic molecular noble metal from 0.50 volume percent to 6.0 volume percent based on the amount of a 1 mg/mL stock solution in the emitter/nanoparticle solution. In one or more embodiments, the nanoparticle/emitter solution has a concentration of non-plasmonic molecular noble metal from 0.75 volume percent to 3.0 volume percent, and in other embodiments, the nanoparticle/emitter solution has a concentration of non-plasmonic molecular noble metal from 0.75 volume percent to 2.0 volume percent.

In other embodiments the light-emitter layer is formed by added the emitter to the host or creating a light-emitting layer. The light-emitting layer is coated with noble metal solution, in which the noble metal solution includes noble metal nanoparticles dissolved in a solvent, organic or aqueous. The solvent is removed at low temperatures and under atmospheric conditions. Low temperatures include temperatures less than 50° C. or less than 25° C.

High-entropy non-crystallizable molecular glass mixtures are defined as a mixture of compatible organic monomeric molecules with an infinitely low crystallization rate under the most favorable conditions. These mixtures can be formed in a one-part reaction of a multifunctional nucleus with a mixture of substituents. The “non-crystallizability” and the “high-entropy” of the mixture is controlled by the structural dissymmetry of the nucleus, the substituents, or a combination thereof, and the number of components making up the mixture. In cases, where the nucleus is highly symmetric and rigid, the components with similar (non-distinct) substituents might crystallize out under the right conditions. Thus it is advantageous when possible to avoid those components, by designing an asymmetric glass mixture, wherein all the components of the mixture have distinct substituents. Without being bound to theory, we predict that the asymmetric mixtures are more likely to be fully non-crystallizable.

Increasing the number of components of the glass mixture, by adding more substituents is another way to enhance the non-crystallizability and the entropy of the glass mixtures having highly symmetric and rigid nuclei.

The high-entropy non-crystallizable glass mixtures of this disclosure are described by Molaire in United States Patent Application 2015/0275076 filed Mar. 22, 2015, United States Patent Application 2015/0053894, filed Aug. 25, 2014; United States Patent Application 2015/0179714, filed Dec. 21, 2014; WIPO Patent Publication No. WO/2015/148327, filed Mar. 22, 2015; WIPO Patent Publication No. WO/2015/117100, filed Feb. 2, 2015; WIPO Patent Publication No. WO/2015/031242, filed Aug. 25, 2014; WIPO Patent Publication No. WO/2015/095859, filed Dec. 22, 2014; WIPO Patent Publication No. WO/2017/053426, filed Sep. 21, 2016, and incorporated by reference into this disclosure in its entirety.

In some embodiments, the light-emitting layer includes the high-entropy non-crystallizable glass mixture hosts and dopant-emitter. The high-entropy non-crystallizable glass mixture hosts may include hole-transporting, electron-transporting, or ambipolar. The high-entropy non-crystallizable glass mixture host and the emitter dopant should be chosen so that a hole-transporting host is combined with an electron-trapping emitter-dopant or an electron-transporting host with a hole-trapping emitter-dopant. Ambipolar host can be used with either type of emitter-dopant.

Specific examples of high-entropy non-crystallizable hosts include those disclosed in International PCT Application No. PCT/US2016/052884, which is incorporated by reference herein in its entirety. Specific examples of high-entropy non-crystallizable hosts include the isomeric hole-transporting materials.

Specific examples of non-crystallizable hosts include those disclosed in U.S. provisional patent application Ser. No. 6,221,605, such as the isomeric hole-transporting materials:

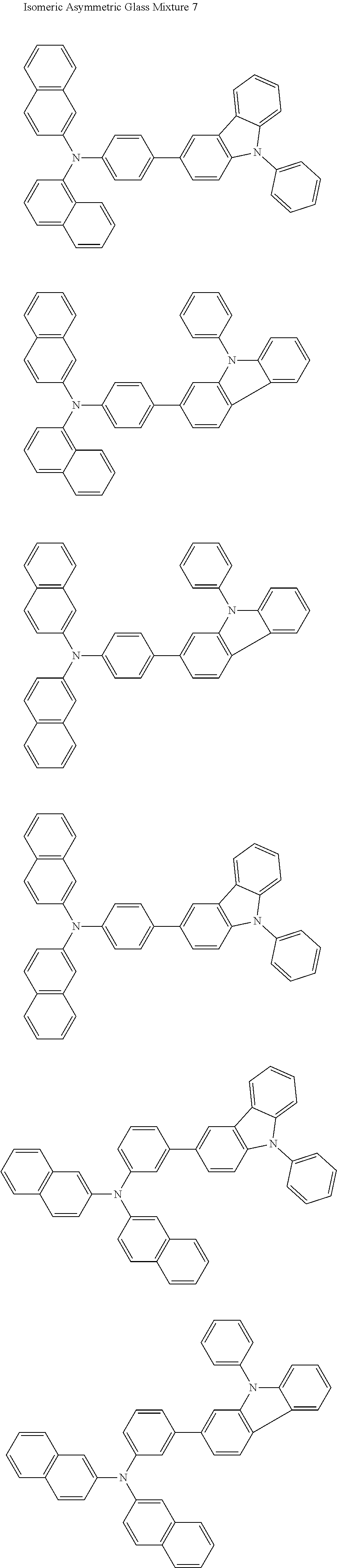 [SMILES: c1ccc(-n2c3ccccc3c3cc(-c4ccc(N(c5ccc6ccccc6c5)c5cccc6ccccc56)cc4)ccc32)cc1 ; c1ccc(-n2c3ccccc3c3ccc(-c4ccc(N(c5ccc6ccccc6c5)c5cccc6ccccc56)cc4)cc32)cc1 ; c1ccc(-n2c3ccccc3c3ccc(-c4ccc(N(c5ccc6ccccc6c5)c5ccc6ccccc6c5)cc4)cc32)cc1 ; c1ccc(-n2c3ccccc3c3cc(-c4ccc(N(c5ccc6ccccc6c5)c5ccc6ccccc6c5)cc4)ccc32)cc1 ; c1ccc(-n2c3ccccc3c3cc(-c4cccc(N(c5ccc6ccccc6c5)c5ccc6ccccc6c5)c4)ccc32)cc1 ; c1ccc(-n2c3ccccc3c3ccc(-c4cccc(N(c5ccc6ccccc6c5)c5ccc6ccccc6c5)c4)cc32)cc1]

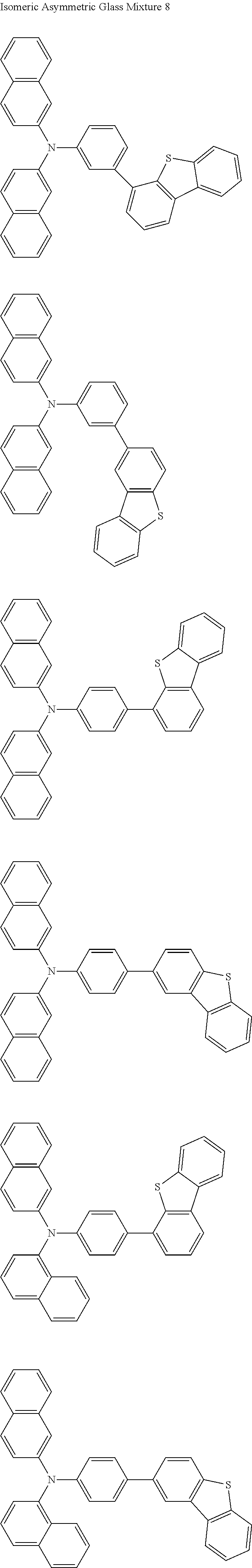 [SMILES: c1cc(-c2cccc3c2sc2ccccc23)cc(N(c2ccc3ccccc3c2)c2ccc3ccccc3c2)c1 ; c1cc(-c2ccc3sc4ccccc4c3c2)cc(N(c2ccc3ccccc3c2)c2ccc3ccccc3c2)c1 ; c1ccc2cc(N(c3ccc(-c4cccc5c4sc4ccccc45)cc3)c3ccc4ccccc4c3)ccc2c1 ; c1ccc2cc(N(c3ccc(-c4ccc5sc6ccccc6c5c4)cc3)c3ccc4ccccc4c3)ccc2c1 ; c1ccc2cc(N(c3ccc(-c4cccc5c4sc4ccccc45)cc3)c3cccc4ccccc34)ccc2c1 ; c1ccc2cc(N(c3ccc(-c4ccc5sc6ccccc6c5c4)cc3)c3cccc4ccccc34)ccc2c1]

The isomeric ambipolar materials

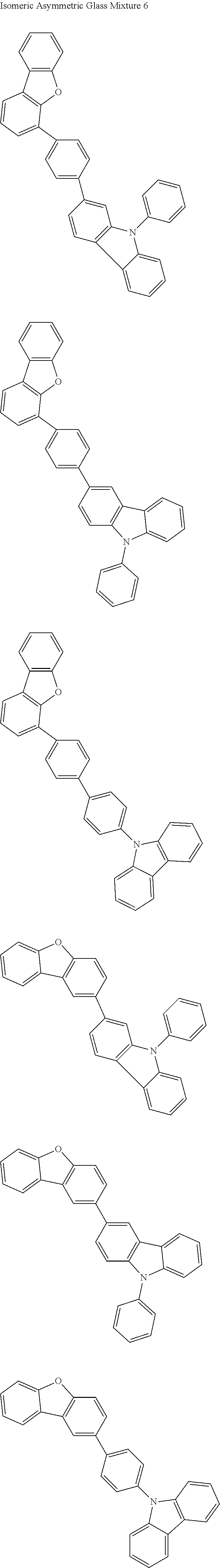 [SMILES: c1ccc(-n2c3ccccc3c3ccc(-c4ccc(-c5cccc6c5oc5ccccc56)cc4)cc32)cc1 ; c1ccc(-n2c3ccccc3c3cc(-c4ccc(-c5cccc6c5oc5ccccc56)cc4)ccc32)cc1 ; c1ccc2c(c1)oc1c(-c3ccc(-c4ccc(-n5c6ccccc6c6ccccc65)cc4)cc3)cccc12 ; c1ccc(-n2c3ccccc3c3ccc(-c4ccc5oc6ccccc6c5c4)cc32)cc1 ; c1ccc(-n2c3ccccc3c3cc(-c4ccc5oc6ccccc6c5c4)ccc32)cc1 ; c1ccc2c(c1)oc1ccc(-c3ccc(-n4c5ccccc5c5ccccc54)cc3)cc12]

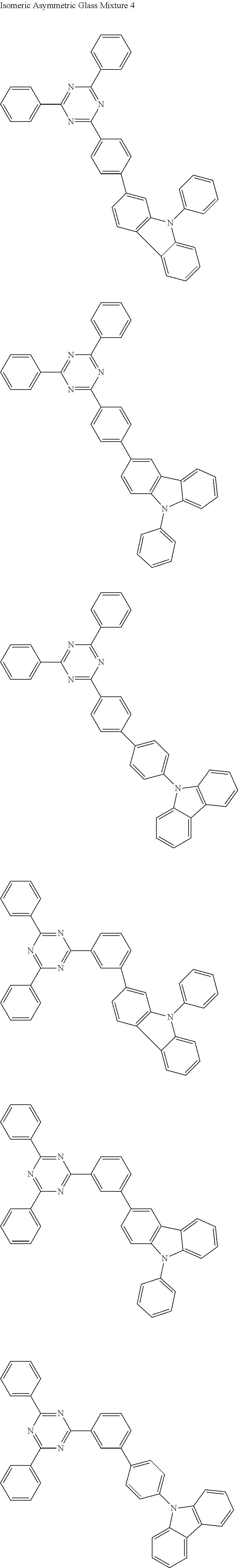 [SMILES: c1ccc(-c2nc(-c3ccccc3)nc(-c3ccc(-c4ccc5c6ccccc6n(-c6ccccc6)c5c4)cc3)n2)cc1 ; c1ccc(-c2nc(-c3ccccc3)nc(-c3ccc(-c4ccc5c(c4)c4ccccc4n5-c4ccccc4)cc3)n2)cc1 ; c1ccc(-c2nc(-c3ccccc3)nc(-c3ccc(-c4ccc(-n5c6ccccc6c6ccccc65)cc4)cc3)n2)cc1 ; c1ccc(-c2nc(-c3ccccc3)nc(-c3cccc(-c4ccc5c6ccccc6n(-c6ccccc6)c5c4)c3)n2)cc1 ; c1ccc(-c2nc(-c3ccccc3)nc(-c3cccc(-c4ccc5c(c4)c4ccccc4n5-c4ccccc4)c3)n2)cc1 ; c1ccc(-c2nc(-c3ccccc3)nc(-c3cccc(-c4ccc(-n5c6ccccc6c6ccccc65)cc4)c3)n2)cc1]

The isomeric electron-transporting non-crystallizable mixtures

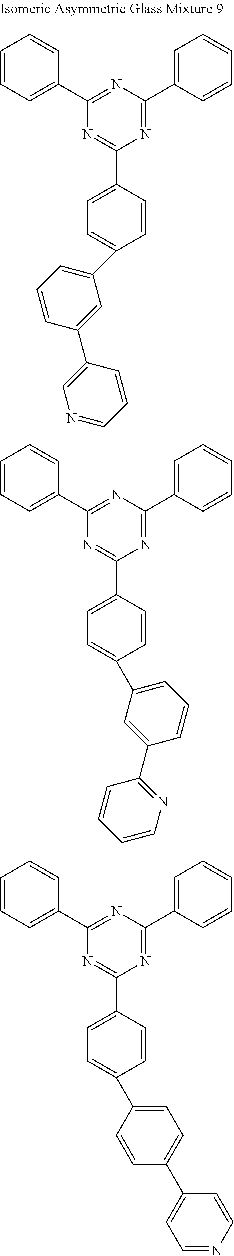

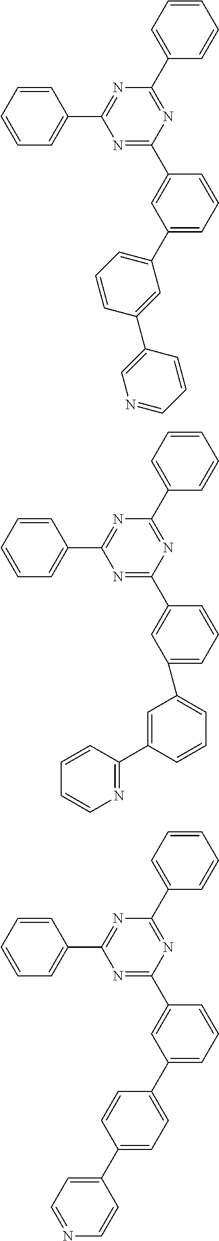

The non-crystallizable hole-transporting materials of United States Patent Application 20150275076, Non-crystallizable Pi-conjugated Molecular Glass Mixtures, Charge Transporting Molecular Glass Mixtures, Luminescent Molecular Glass Mixtures, or Combinations Thereof for Organic Light Emitting Diodes and other Organic Electronics and Photonics Applications

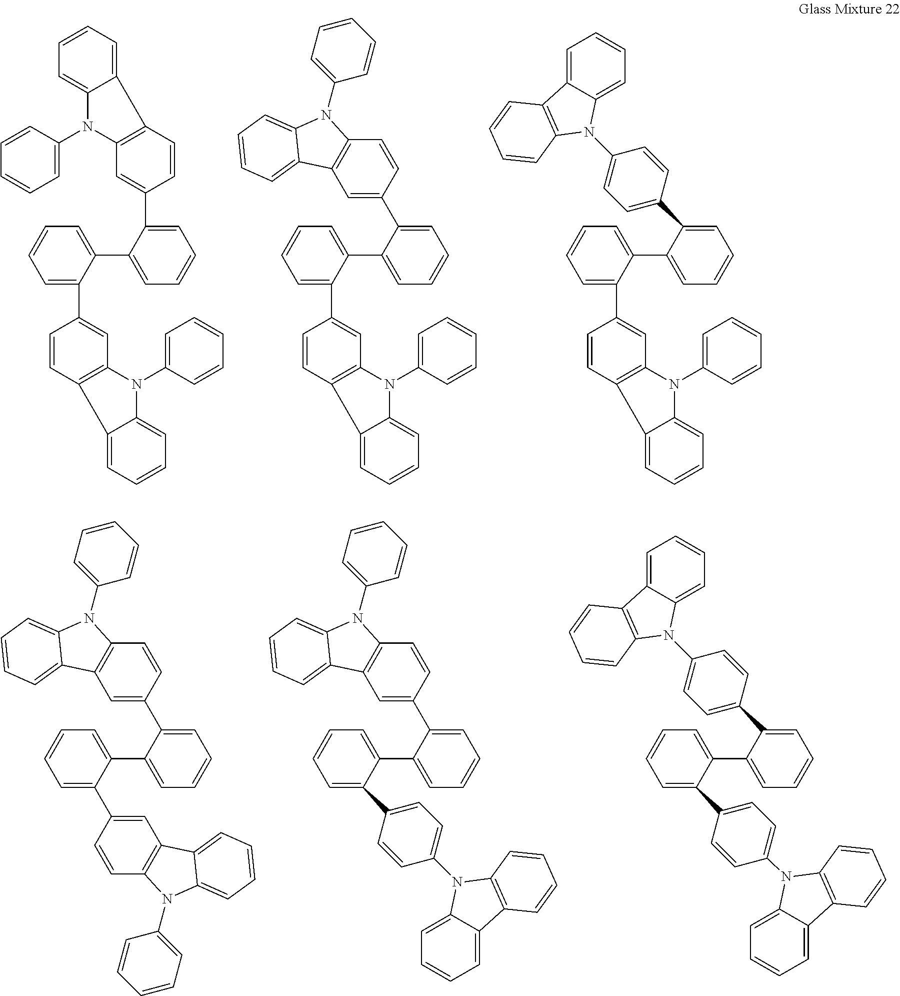

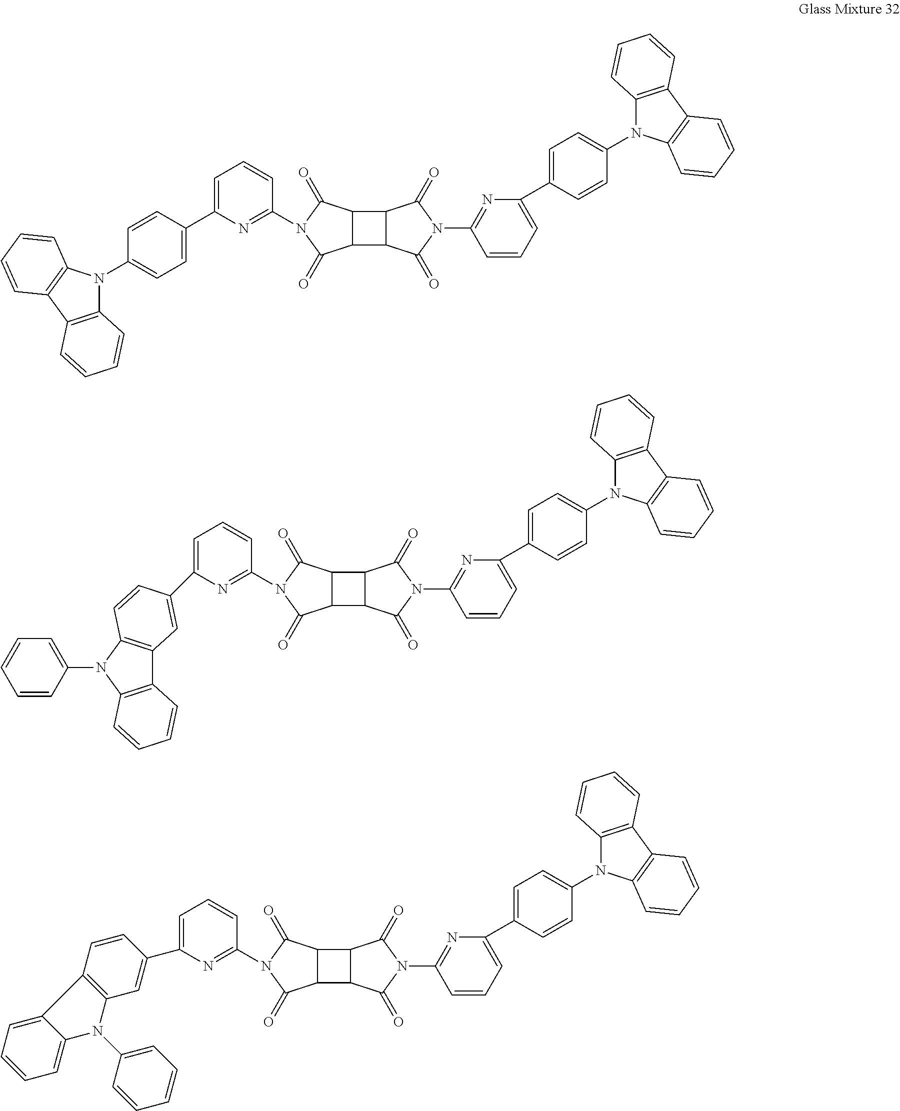 [SMILES: O=C1C2C(C(=O)N1c1cccc(-c3ccc(-n4c5ccccc5c5ccccc54)cc3)n1)C1C(=O)N(c3cccc(-c4ccc(-n5c6ccccc6c6ccccc65)cc4)n3)C(=O)C21 ; O=C1C2C(C(=O)N1c1cccc(-c3ccc(-n4c5ccccc5c5ccccc54)cc3)n1)C1C(=O)N(c3cccc(-c4ccc5c(c4)c4ccccc4n5-c4ccccc4)n3)C(=O)C21 ; O=C1C2C(C(=O)N1c1cccc(-c3ccc(-n4c5ccccc5c5ccccc54)cc3)n1)C1C(=O)N(c3cccc(-c4ccc5c6ccccc6n(-c6ccccc6)c5c4)n3)C(=O)C21]

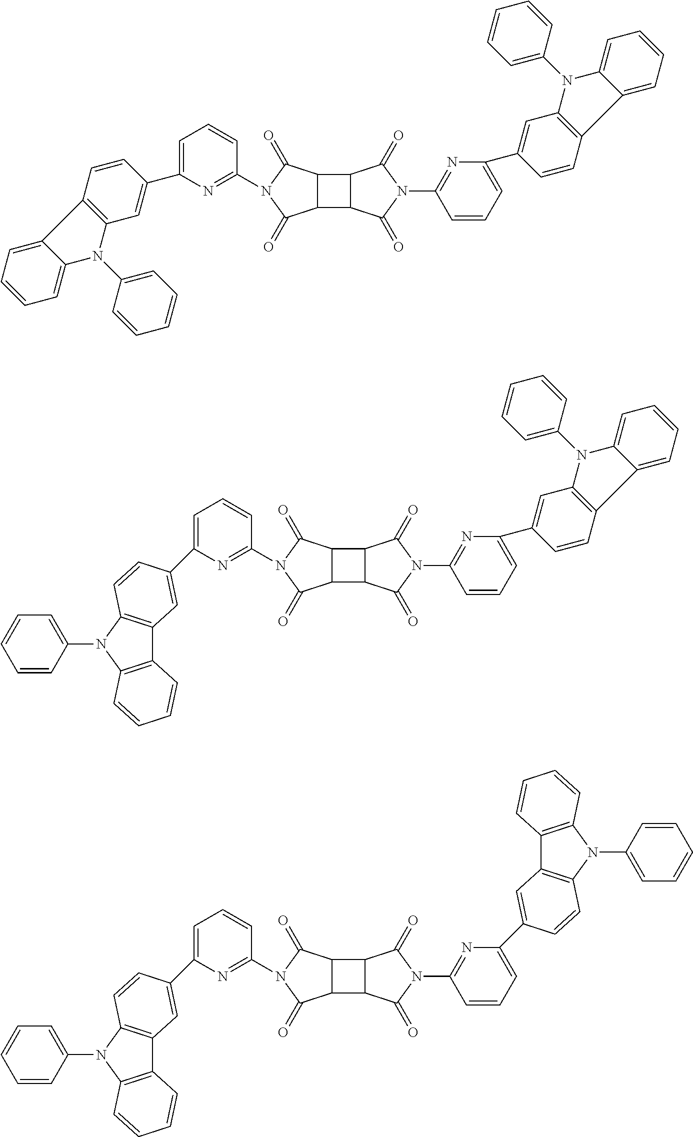 [SMILES: O=C1C2C(C(=O)N1c1cccc(-c3ccc4c5ccccc5n(-c5ccccc5)c4c3)n1)C1C(=O)N(c3cccc(-c4ccc5c6ccccc6n(-c6ccccc6)c5c4)n3)C(=O)C21 ; O=C1C2C(C(=O)N1c1cccc(-c3ccc4c(c3)c3ccccc3n4-c3ccccc3)n1)C1C(=O)N(c3cccc(-c4ccc5c6ccccc6n(-c6ccccc6)c5c4)n3)C(=O)C21 ; O=C1C2C(C(=O)N1c1cccc(-c3ccc4c(c3)c3ccccc3n4-c3ccccc3)n1)C1C(=O)N(c3cccc(-c4ccc5c(c4)c4ccccc4n5-c4ccccc4)n3)C(=O)C21]

Other examples of non-crystallizable glass mixtures include

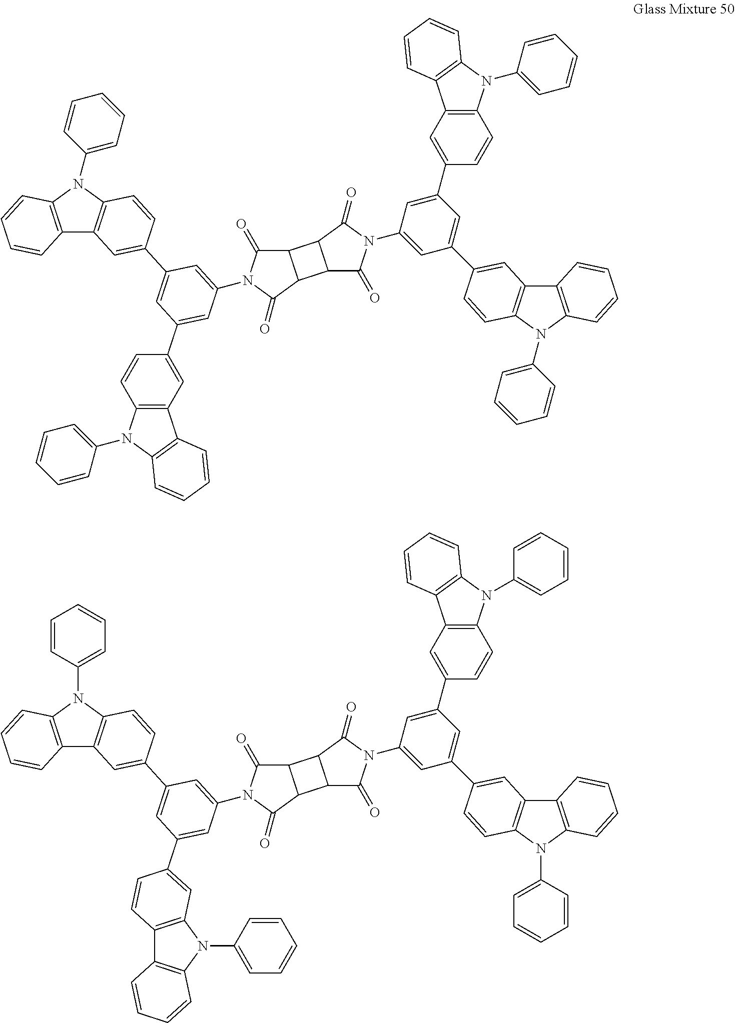 [SMILES: O=C1C2C(C(=O)N1c1cc(-c3ccc4c(c3)c3ccccc3n4-c3ccccc3)cc(-c3ccc4c(c3)c3ccccc3n4-c3ccccc3)c1)C1C(=O)N(c3cc(-c4ccc5c(c4)c4ccccc4n5-c4ccccc4)cc(-c4ccc5c(c4)c4ccccc4n5-c4ccccc4)c3)C(=O)C21 ; O=C1C2C(C(=O)N1c1cc(-c3ccc4c(c3)c3ccccc3n4-c3ccccc3)cc(-c3ccc4c(c3)c3ccccc3n4-c3ccccc3)c1)C1C(=O)N(c3cc(-c4ccc5c(c4)c4ccccc4n5-c4ccccc4)cc(-c4ccc5c6ccccc6n(-c6ccccc6)c5c4)c3)C(=O)C21]

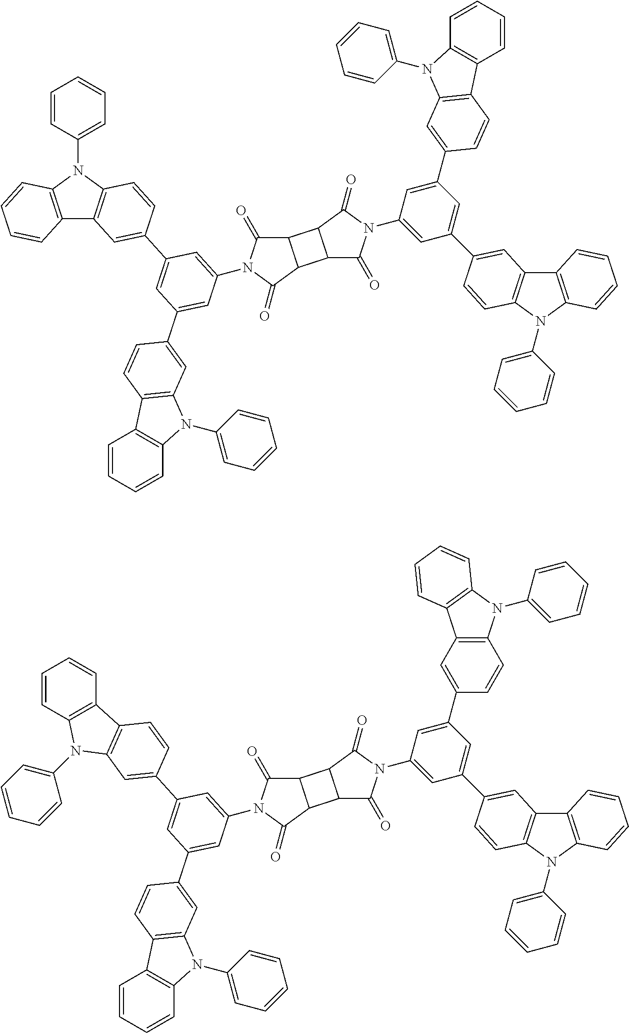 [SMILES: O=C1C2C(C(=O)N1c1cc(-c3ccc4c(c3)c3ccccc3n4-c3ccccc3)cc(-c3ccc4c5ccccc5n(-c5ccccc5)c4c3)c1)C1C(=O)N(c3cc(-c4ccc5c(c4)c4ccccc4n5-c4ccccc4)cc(-c4ccc5c6ccccc6n(-c6ccccc6)c5c4)c3)C(=O)C21 ; O=C1C2C(C(=O)N1c1cc(-c3ccc4c(c3)c3ccccc3n4-c3ccccc3)cc(-c3ccc4c(c3)c3ccccc3n4-c3ccccc3)c1)C1C(=O)N(c3cc(-c4ccc5c6ccccc6n(-c6ccccc6)c5c4)cc(-c4ccc5c6ccccc6n(-c6ccccc6)c5c4)c3)C(=O)C21]

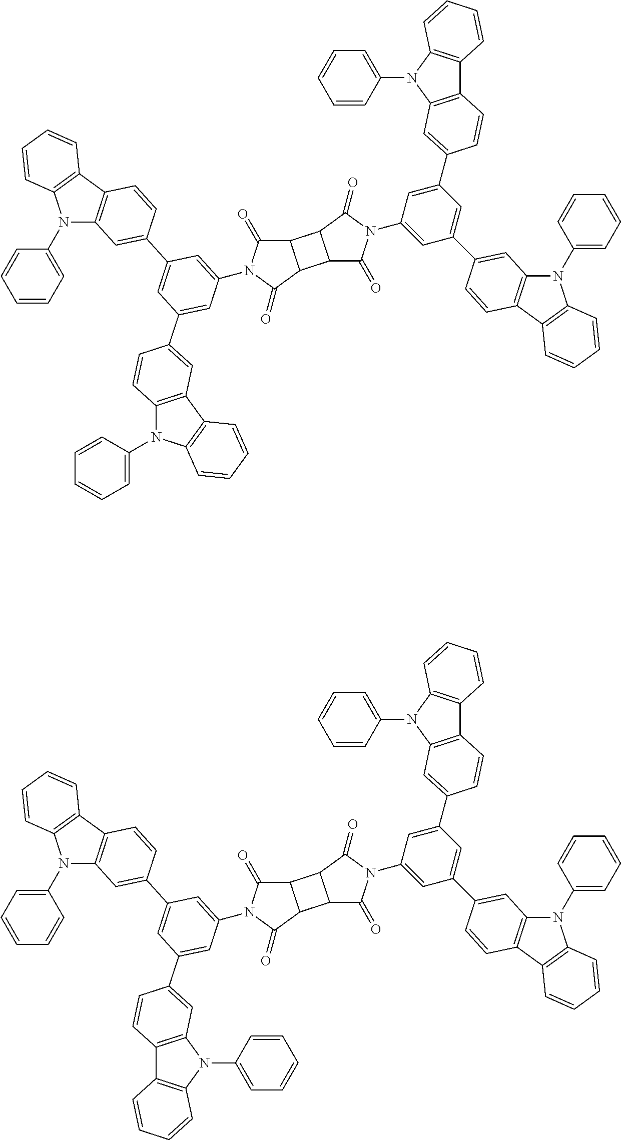 [SMILES: O=C1C2C(C(=O)N1c1cc(-c3ccc4c(c3)c3ccccc3n4-c3ccccc3)cc(-c3ccc4c5ccccc5n(-c5ccccc5)c4c3)c1)C1C(=O)N(c3cc(-c4ccc5c6ccccc6n(-c6ccccc6)c5c4)cc(-c4ccc5c6ccccc6n(-c6ccccc6)c5c4)c3)C(=O)C21 ; O=C1C2C(C(=O)N1c1cc(-c3ccc4c5ccccc5n(-c5ccccc5)c4c3)cc(-c3ccc4c5ccccc5n(-c5ccccc5)c4c3)c1)C1C(=O)N(c3cc(-c4ccc5c6ccccc6n(-c6ccccc6)c5c4)cc(-c4ccc5c6ccccc6n(-c6ccccc6)c5c4)c3)C(=O)C21]

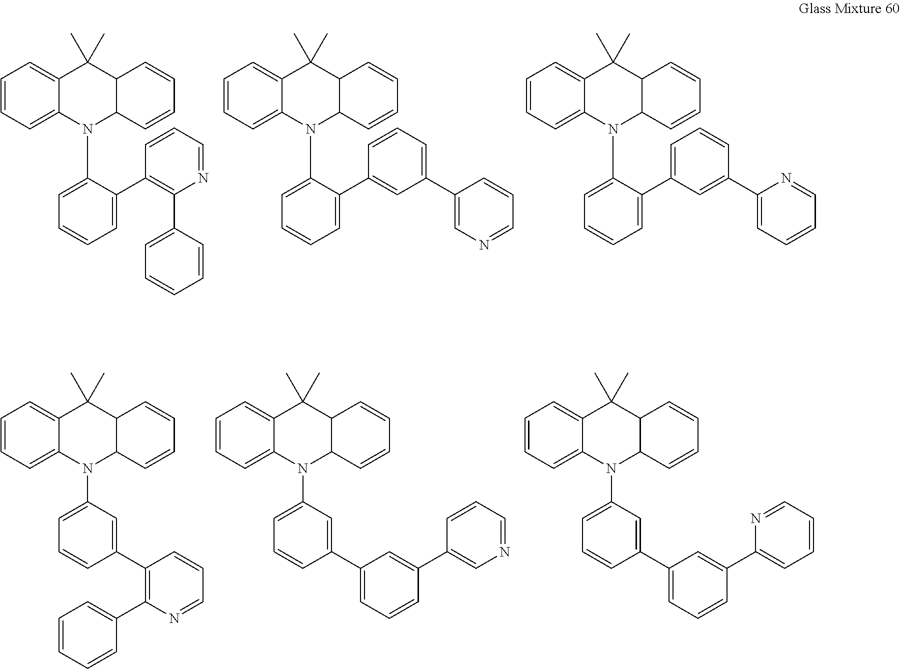

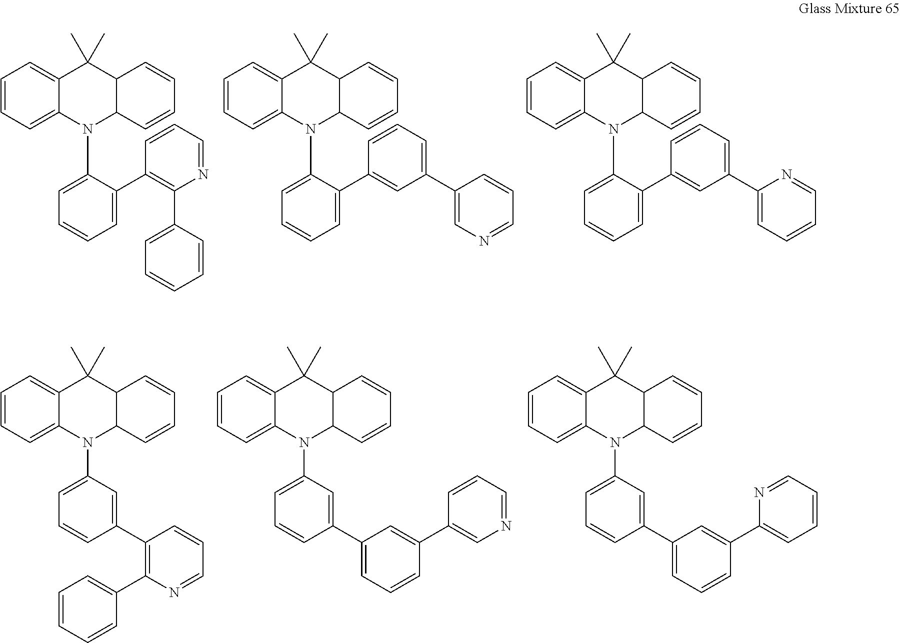

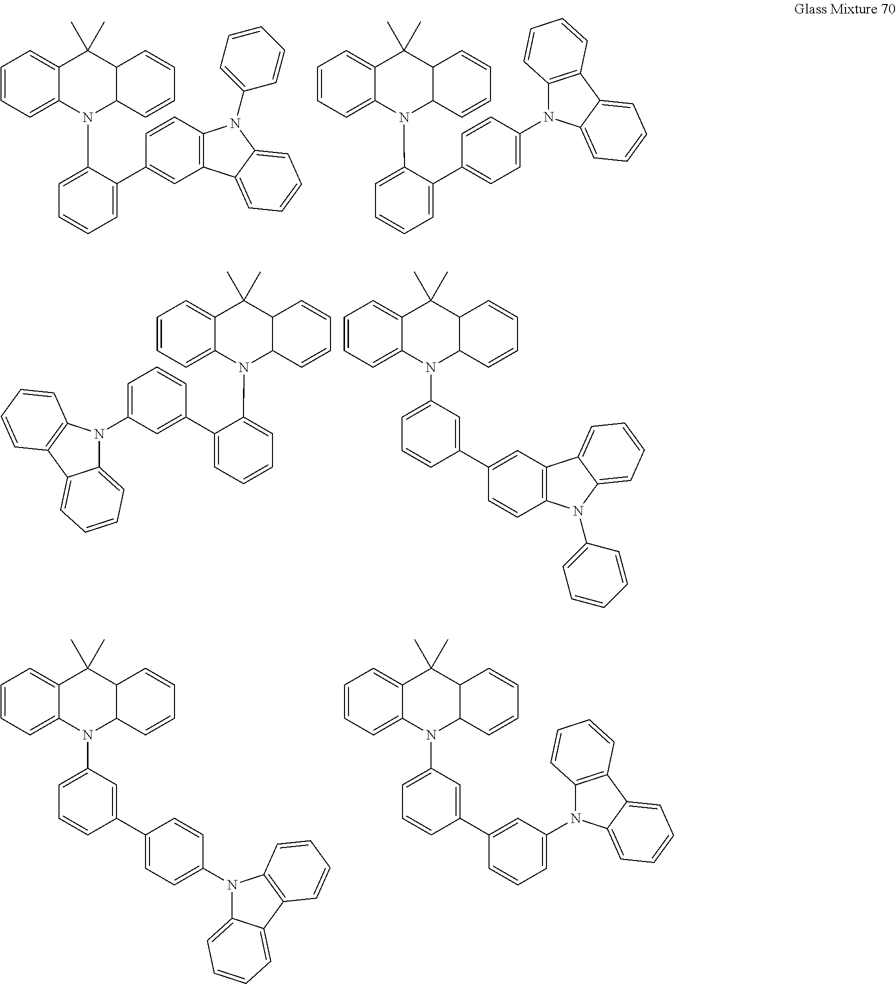

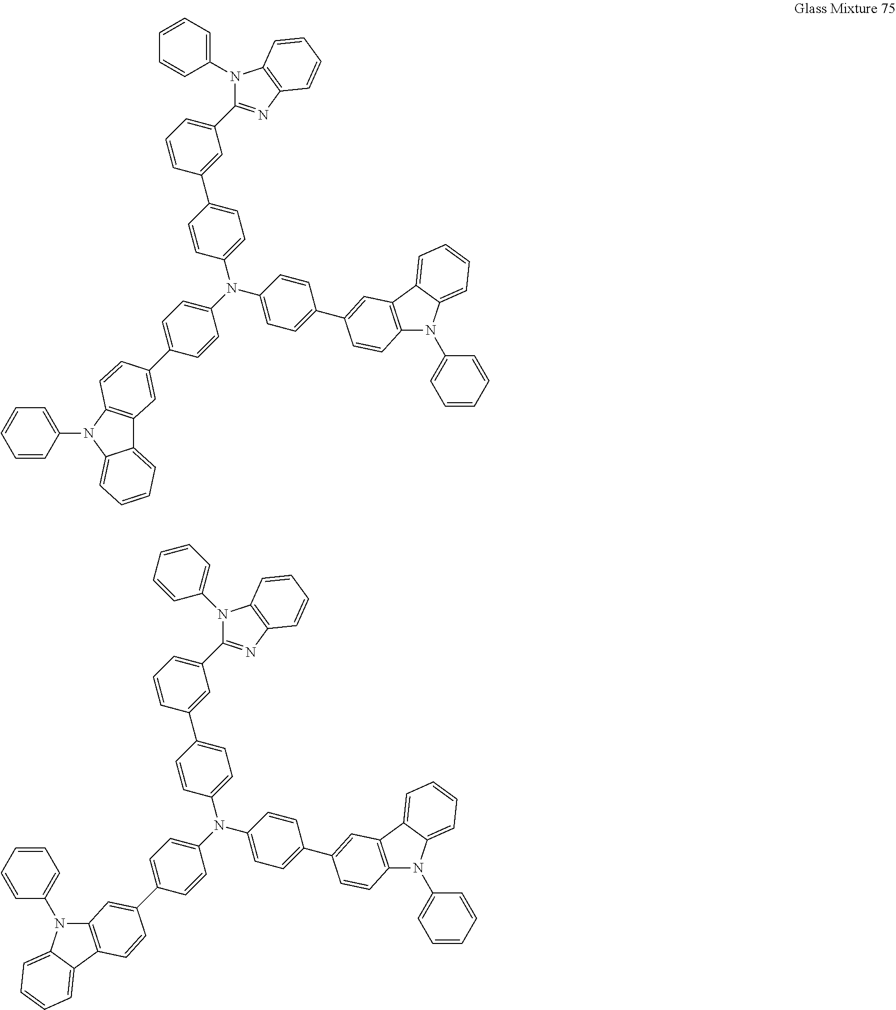 [SMILES: c1ccc(-n2c(-c3cccc(-c4ccc(N(c5ccc(-c6ccc7c(c6)c6ccccc6n7-c6ccccc6)cc5)c5ccc(-c6ccc7c(c6)c6ccccc6n7-c6ccccc6)cc5)cc4)c3)nc3ccccc32)cc1 ; c1ccc(-n2c(-c3cccc(-c4ccc(N(c5ccc(-c6ccc7c(c6)c6ccccc6n7-c6ccccc6)cc5)c5ccc(-c6ccc7c8ccccc8n(-c8ccccc8)c7c6)cc5)cc4)c3)nc3ccccc32)cc1]

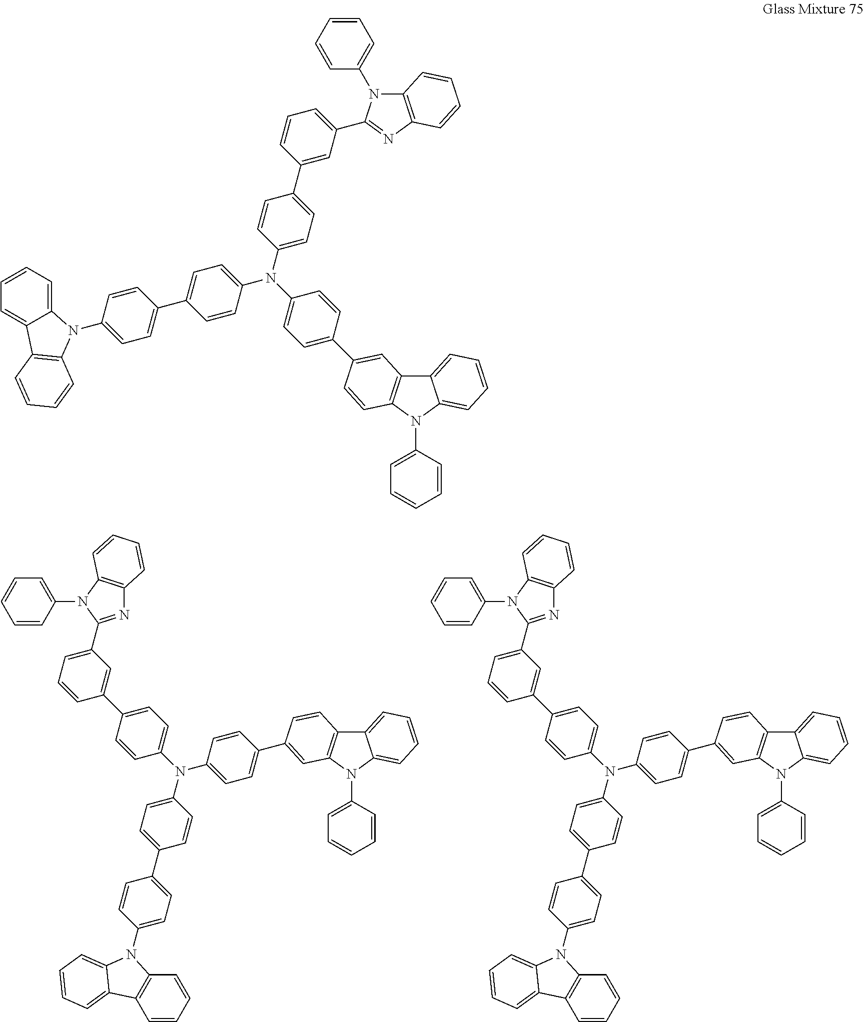 [SMILES: c1ccc(-n2c(-c3cccc(-c4ccc(N(c5ccc(-c6ccc(-n7c8ccccc8c8ccccc87)cc6)cc5)c5ccc(-c6ccc7c(c6)c6ccccc6n7-c6ccccc6)cc5)cc4)c3)nc3ccccc32)cc1 ; c1ccc(-n2c(-c3cccc(-c4ccc(N(c5ccc(-c6ccc(-n7c8ccccc8c8ccccc87)cc6)cc5)c5ccc(-c6ccc7c8ccccc8n(-c8ccccc8)c7c6)cc5)cc4)c3)nc3ccccc32)cc1 ; c1ccc(-n2c(-c3cccc(-c4ccc(N(c5ccc(-c6ccc(-n7c8ccccc8c8ccccc87)cc6)cc5)c5ccc(-c6ccc7c8ccccc8n(-c8ccccc8)c7c6)cc5)cc4)c3)nc3ccccc32)cc1]

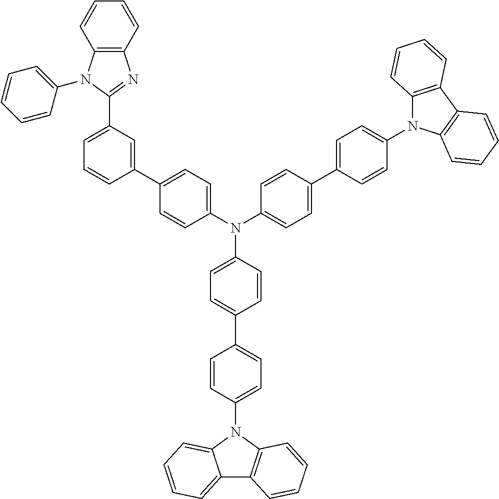 [SMILES: c1ccc(-n2c(-c3cccc(-c4ccc(N(c5ccc(-c6ccc(-n7c8ccccc8c8ccccc87)cc6)cc5)c5ccc(-c6ccc(-n7c8ccccc8c8ccccc87)cc6)cc5)cc4)c3)nc3ccccc32)cc1]

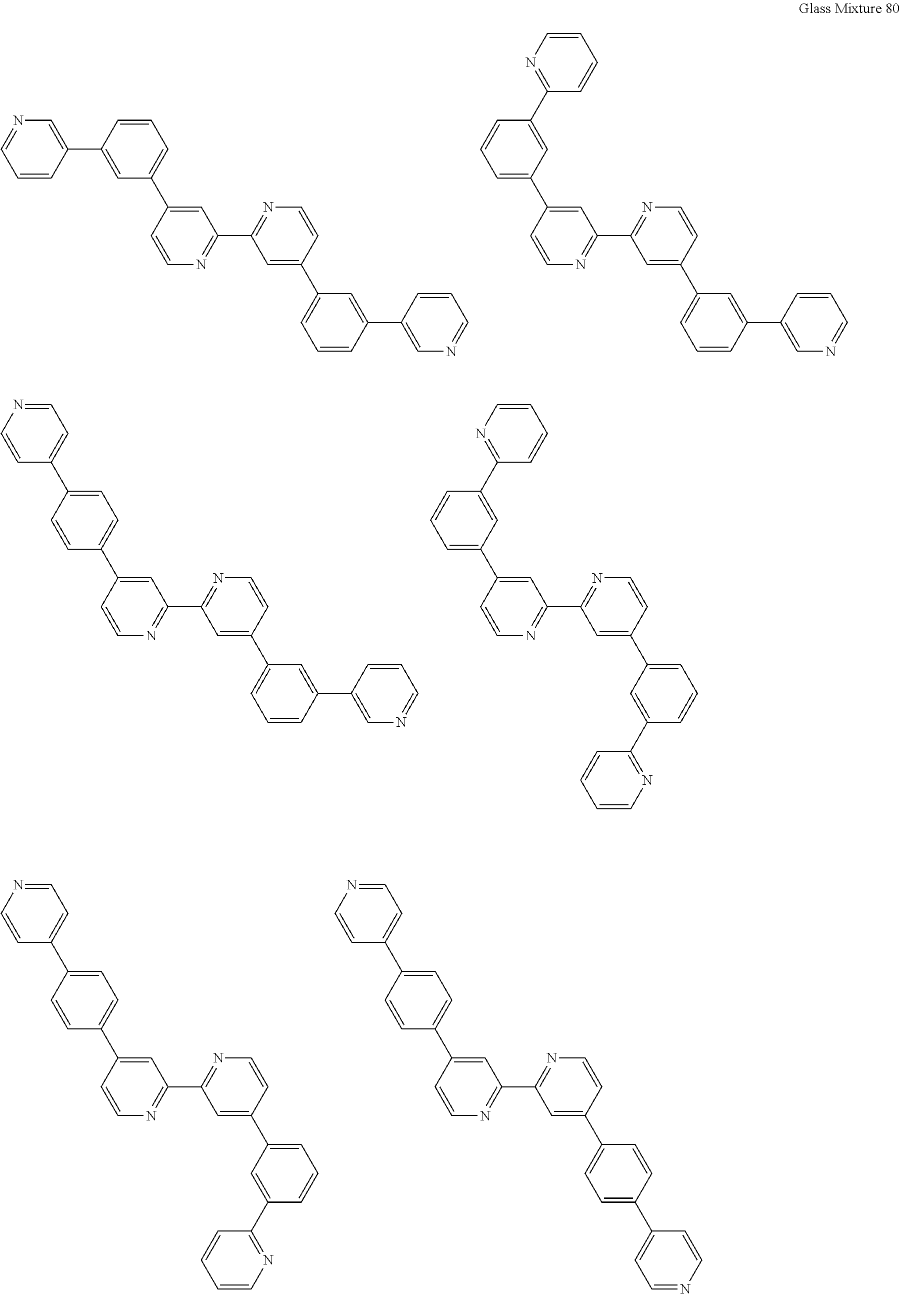 [SMILES: c1cncc(-c2cccc(-c3ccnc(-c4cc(-c5cccc(-c6cccnc6)c5)ccn4)c3)c2)c1 ; c1ccc(-c2cccc(-c3ccnc(-c4cc(-c5cccc(-c6cccnc6)c5)ccn4)c3)c2)nc1 ; c1cncc(-c2cccc(-c3ccnc(-c4cc(-c5ccc(-c6ccncc6)cc5)ccn4)c3)c2)c1 ; c1ccc(-c2cccc(-c3ccnc(-c4cc(-c5cccc(-c6ccccn6)c5)ccn4)c3)c2)nc1 ; c1ccc(-c2cccc(-c3ccnc(-c4cc(-c5ccc(-c6ccncc6)cc5)ccn4)c3)c2)nc1 ; c1cc(-c2ccc(-c3ccnc(-c4cc(-c5ccc(-c6ccncc6)cc5)ccn4)c3)cc2)ccn1]

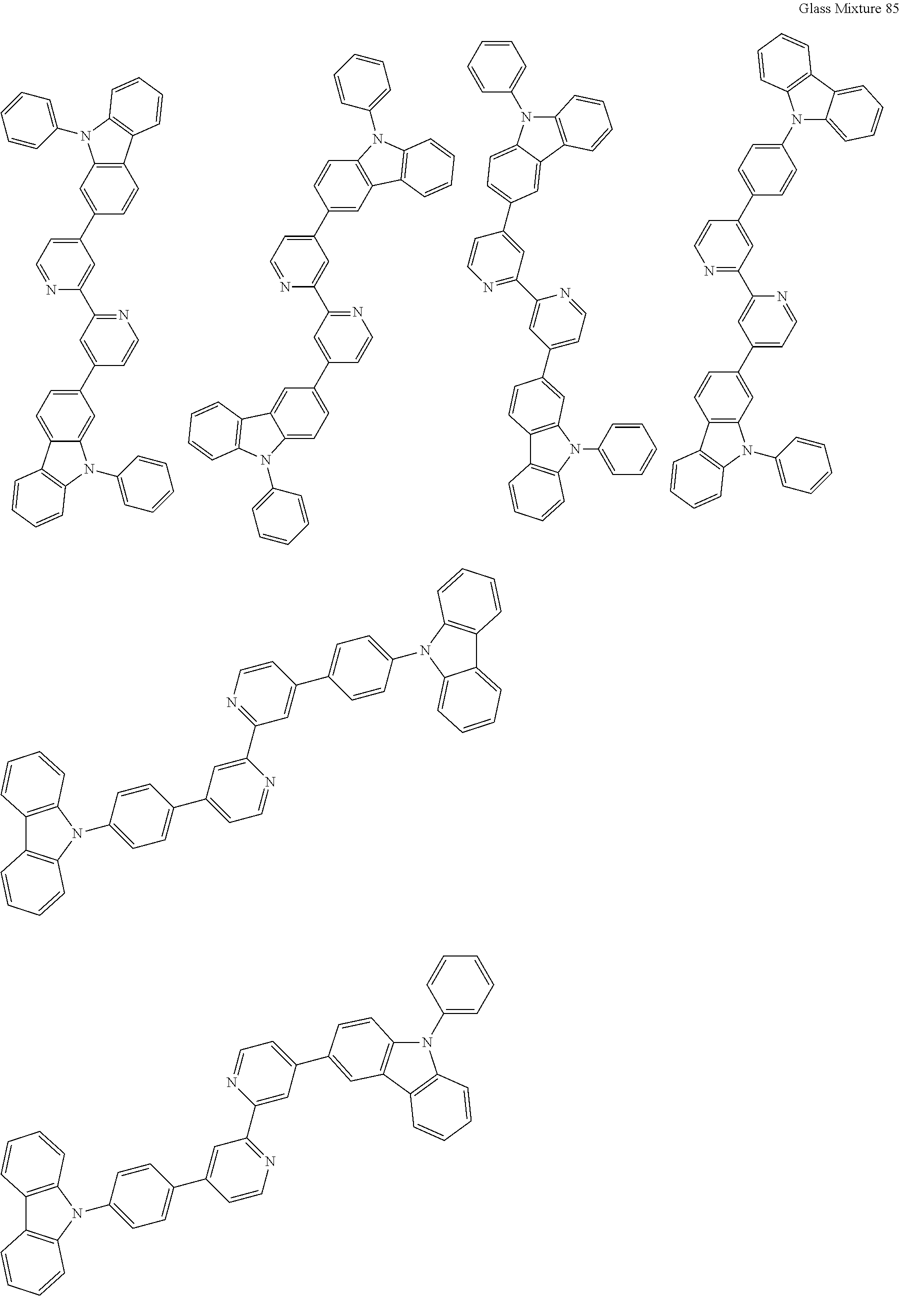

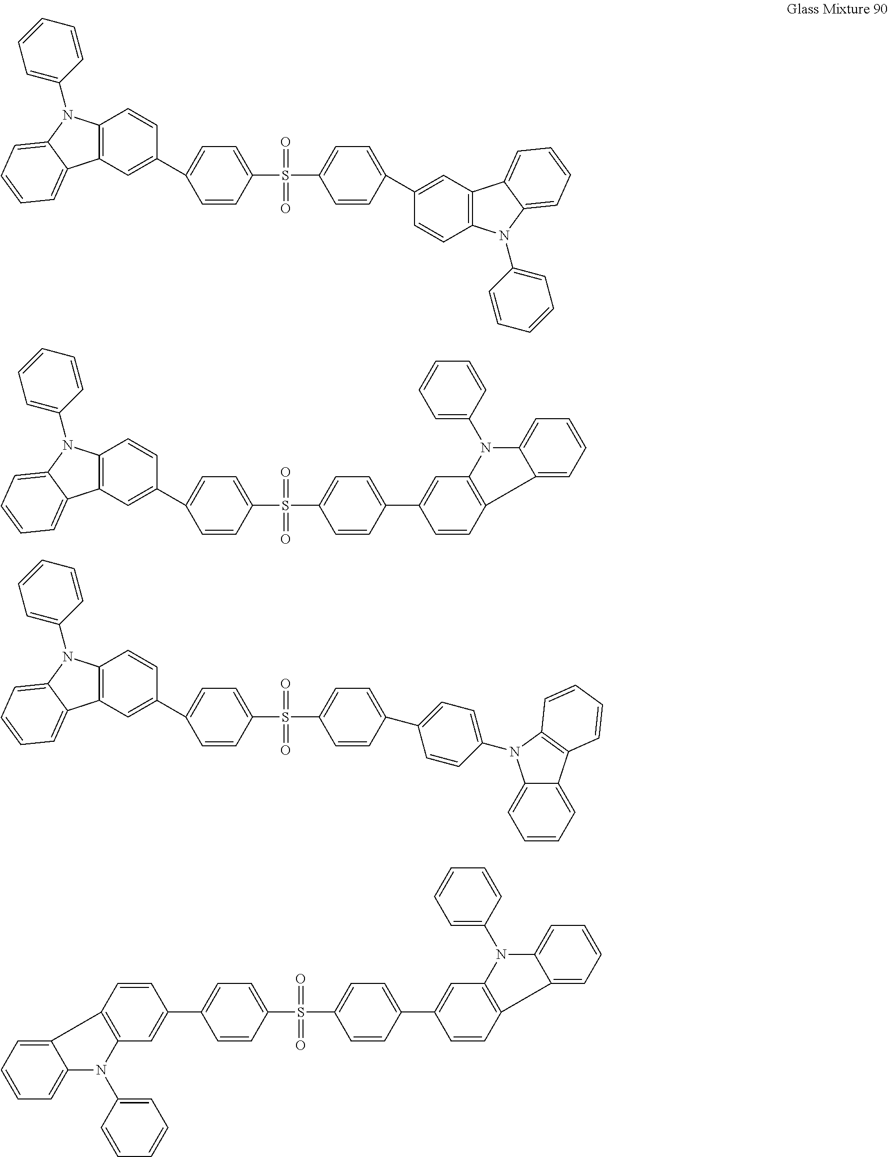

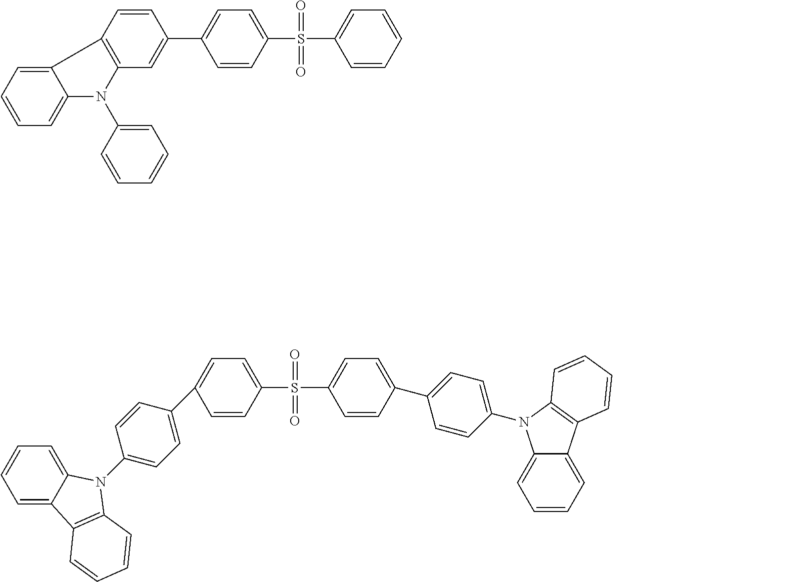 [SMILES: O=S(=O)(c1ccccc1)c1ccc(-c2ccc3c4ccccc4n(-c4ccccc4)c3c2)cc1 ; O=S(=O)(c1ccc(-c2ccc(-n3c4ccccc4c4ccccc43)cc2)cc1)c1ccc(-c2ccc(-n3c4ccccc4c4ccccc43)cc2)cc1]

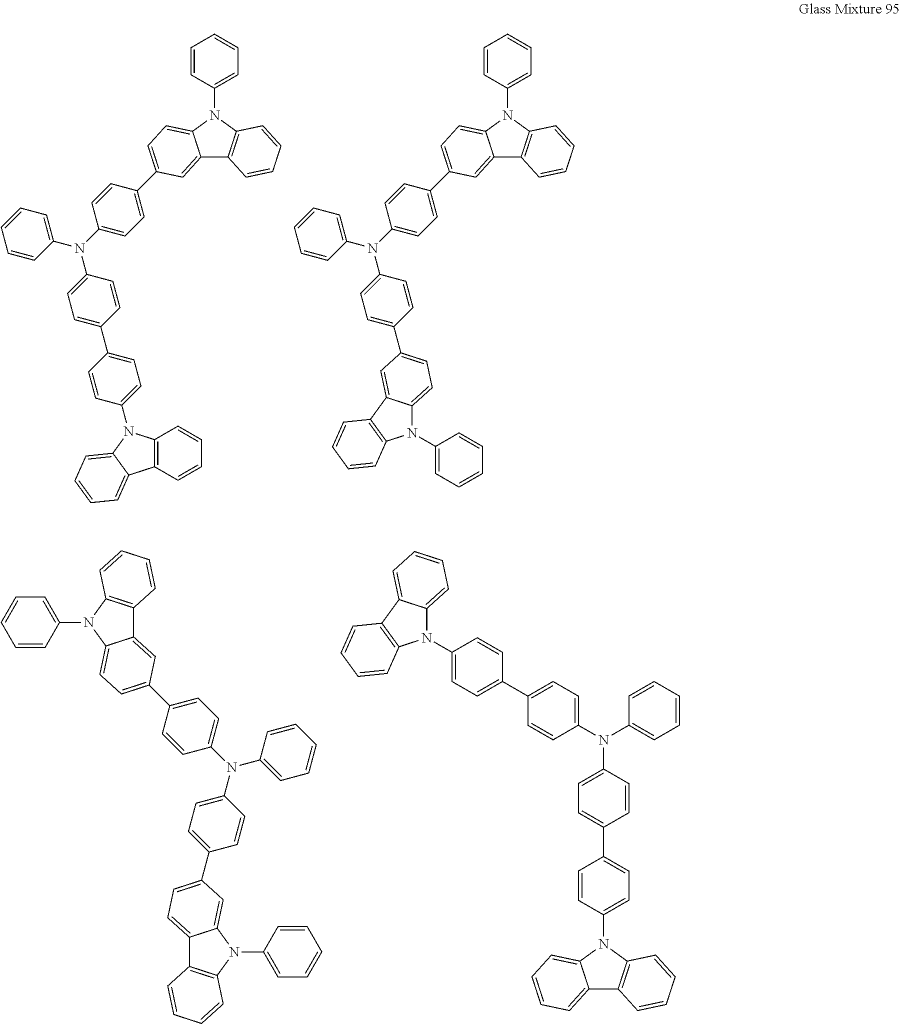 [SMILES: c1ccc(N(c2ccc(-c3ccc(-n4c5ccccc5c5ccccc54)cc3)cc2)c2ccc(-c3ccc4c(c3)c3ccccc3n4-c3ccccc3)cc2)cc1 ; c1ccc(N(c2ccc(-c3ccc4c(c3)c3ccccc3n4-c3ccccc3)cc2)c2ccc(-c3ccc4c(c3)c3ccccc3n4-c3ccccc3)cc2)cc1 ; c1ccc(N(c2ccc(-c3ccc4c(c3)c3ccccc3n4-c3ccccc3)cc2)c2ccc(-c3ccc4c5ccccc5n(-c5ccccc5)c4c3)cc2)cc1 ; c1ccc(N(c2ccc(-c3ccc(-n4c5ccccc5c5ccccc54)cc3)cc2)c2ccc(-c3ccc(-n4c5ccccc5c5ccccc54)cc3)cc2)cc1]

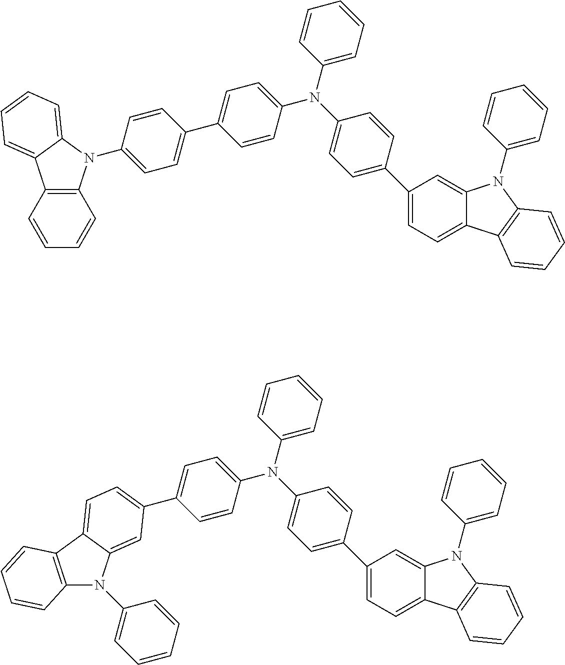 [SMILES: c1ccc(N(c2ccc(-c3ccc(-n4c5ccccc5c5ccccc54)cc3)cc2)c2ccc(-c3ccc4c5ccccc5n(-c5ccccc5)c4c3)cc2)cc1 ; c1ccc(N(c2ccc(-c3ccc4c5ccccc5n(-c5ccccc5)c4c3)cc2)c2ccc(-c3ccc4c5ccccc5n(-c5ccccc5)c4c3)cc2)cc1]

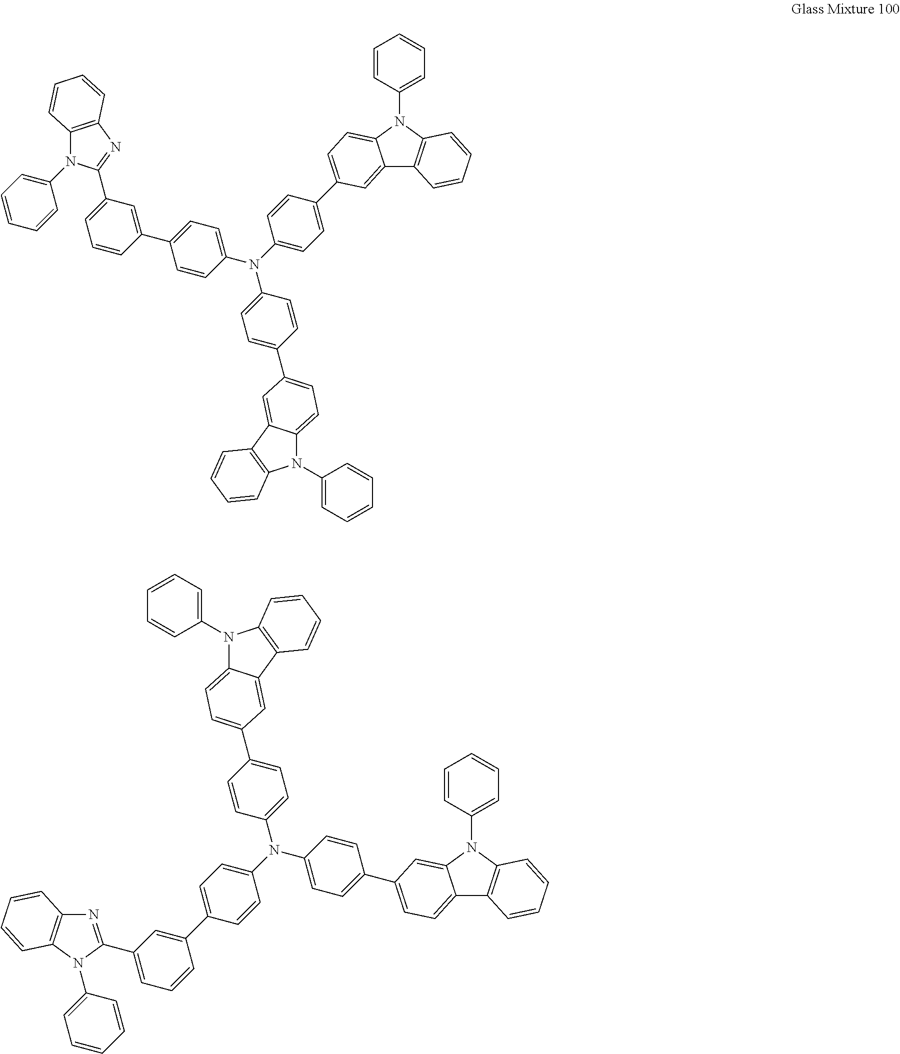 [SMILES: c1ccc(-n2c(-c3cccc(-c4ccc(N(c5ccc(-c6ccc7c(c6)c6ccccc6n7-c6ccccc6)cc5)c5ccc(-c6ccc7c(c6)c6ccccc6n7-c6ccccc6)cc5)cc4)c3)nc3ccccc32)cc1 ; c1ccc(-n2c(-c3cccc(-c4ccc(N(c5ccc(-c6ccc7c(c6)c6ccccc6n7-c6ccccc6)cc5)c5ccc(-c6ccc7c8ccccc8n(-c8ccccc8)c7c6)cc5)cc4)c3)nc3ccccc32)cc1]

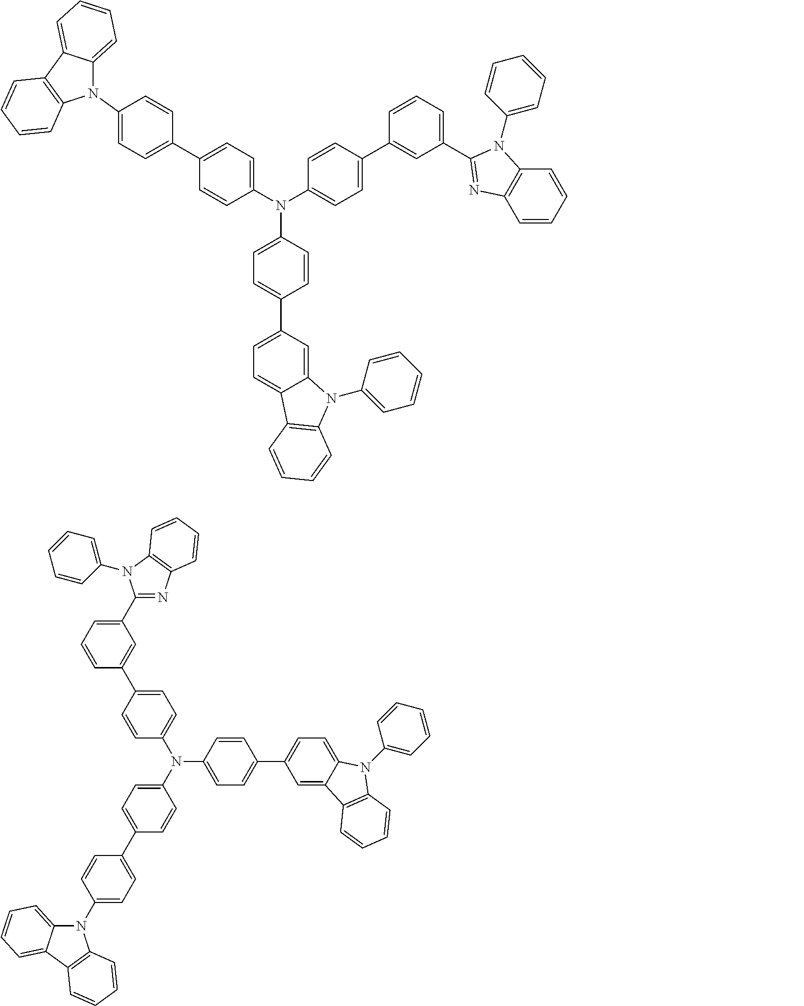 [SMILES: c1ccc(-n2c(-c3cccc(-c4ccc(N(c5ccc(-c6ccc(-n7c8ccccc8c8ccccc87)cc6)cc5)c5ccc(-c6ccc7c8ccccc8n(-c8ccccc8)c7c6)cc5)cc4)c3)nc3ccccc32)cc1 ; c1ccc(-n2c(-c3cccc(-c4ccc(N(c5ccc(-c6ccc(-n7c8ccccc8c8ccccc87)cc6)cc5)c5ccc(-c6ccc7c(c6)c6ccccc6n7-c6ccccc6)cc5)cc4)c3)nc3ccccc32)cc1]

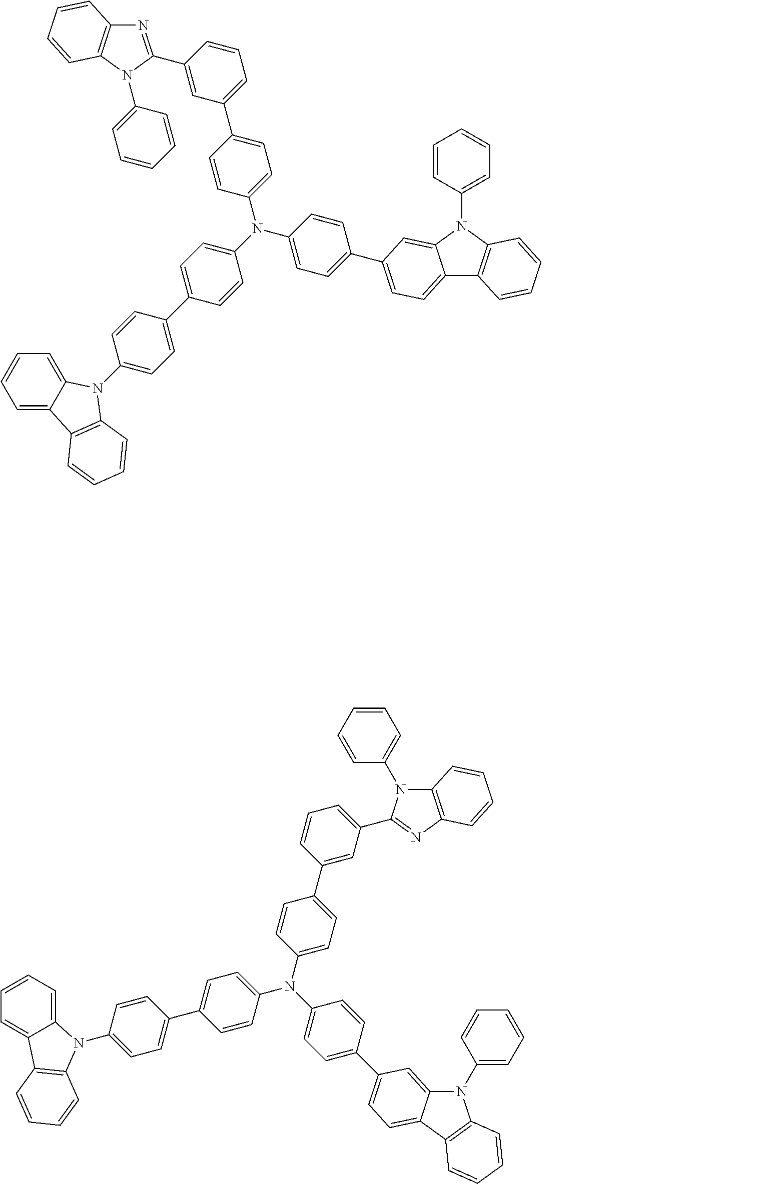 [SMILES: c1ccc(-n2c(-c3cccc(-c4ccc(N(c5ccc(-c6ccc(-n7c8ccccc8c8ccccc87)cc6)cc5)c5ccc(-c6ccc7c8ccccc8n(-c8ccccc8)c7c6)cc5)cc4)c3)nc3ccccc32)cc1 ; c1ccc(-n2c(-c3cccc(-c4ccc(N(c5ccc(-c6ccc(-n7c8ccccc8c8ccccc87)cc6)cc5)c5ccc(-c6ccc7c8ccccc8n(-c8ccccc8)c7c6)cc5)cc4)c3)nc3ccccc32)cc1]

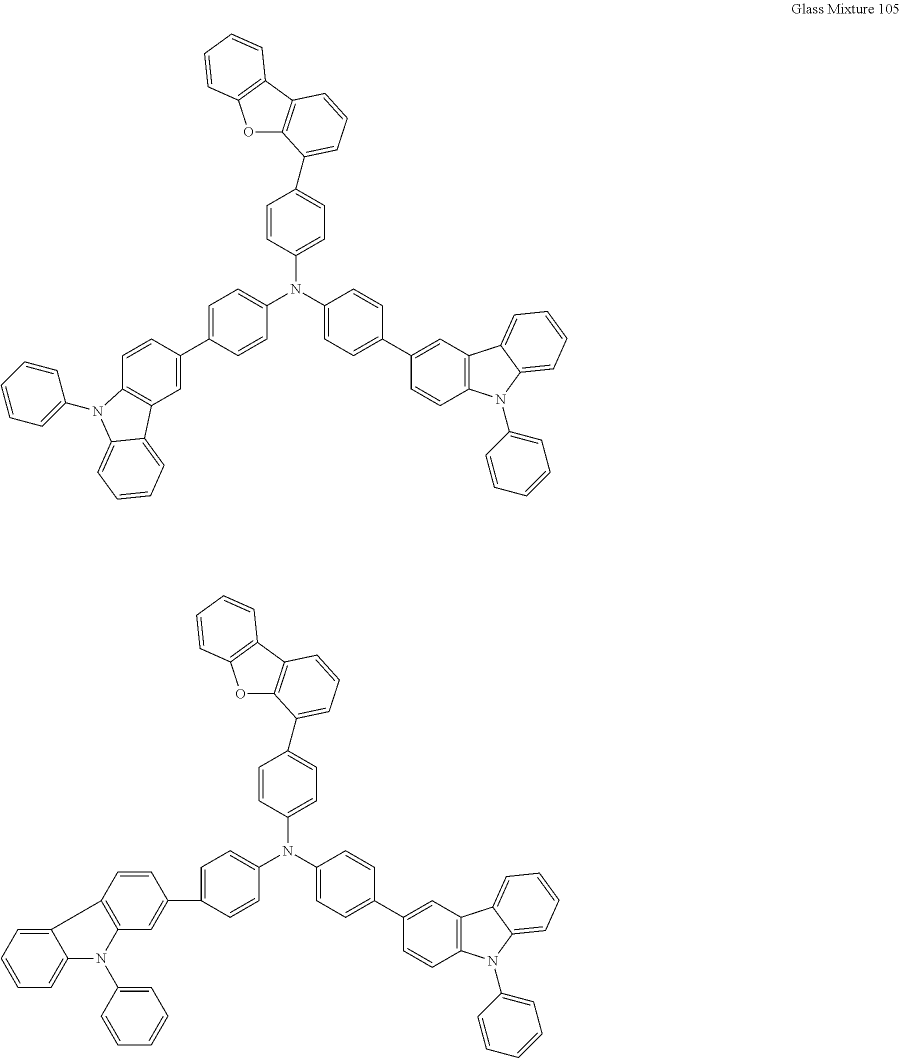 [SMILES: c1ccc(-n2c3ccccc3c3cc(-c4ccc(N(c5ccc(-c6ccc7c(c6)c6ccccc6n7-c6ccccc6)cc5)c5ccc(-c6cccc7c6oc6ccccc67)cc5)cc4)ccc32)cc1 ; c1ccc(-n2c3ccccc3c3cc(-c4ccc(N(c5ccc(-c6ccc7c8ccccc8n(-c8ccccc8)c7c6)cc5)c5ccc(-c6cccc7c6oc6ccccc67)cc5)cc4)ccc32)cc1]

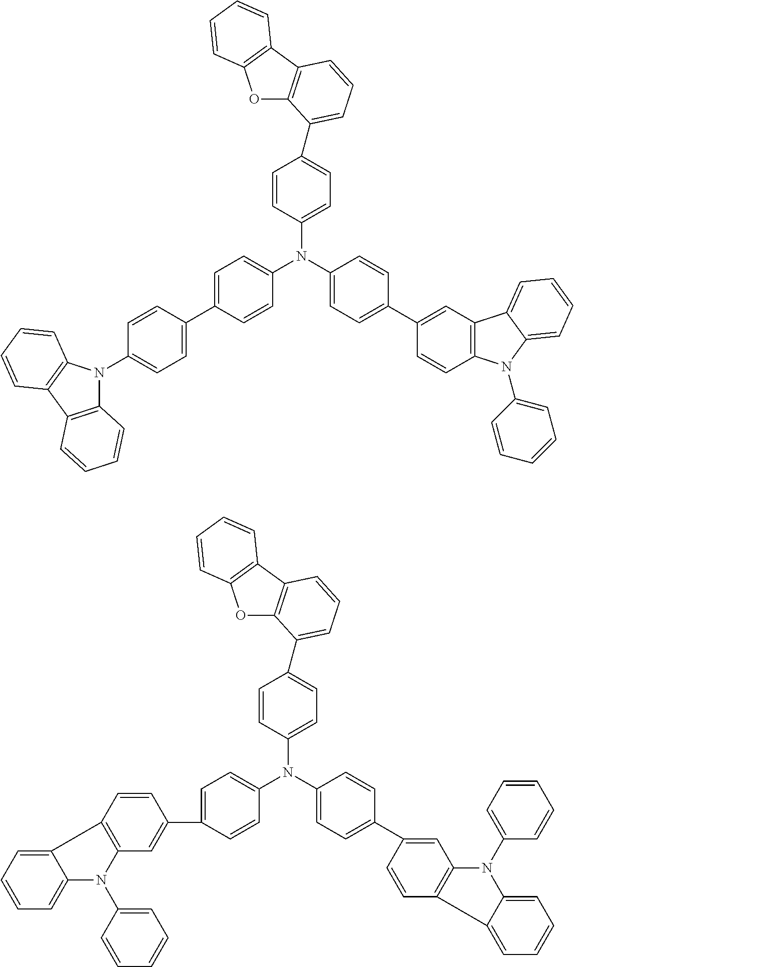 [SMILES: c1ccc(-n2c3ccccc3c3cc(-c4ccc(N(c5ccc(-c6ccc(-n7c8ccccc8c8ccccc87)cc6)cc5)c5ccc(-c6cccc7c6oc6ccccc67)cc5)cc4)ccc32)cc1 ; c1ccc(-n2c3ccccc3c3ccc(-c4ccc(N(c5ccc(-c6ccc7c8ccccc8n(-c8ccccc8)c7c6)cc5)c5ccc(-c6cccc7c6oc6ccccc67)cc5)cc4)cc32)cc1]

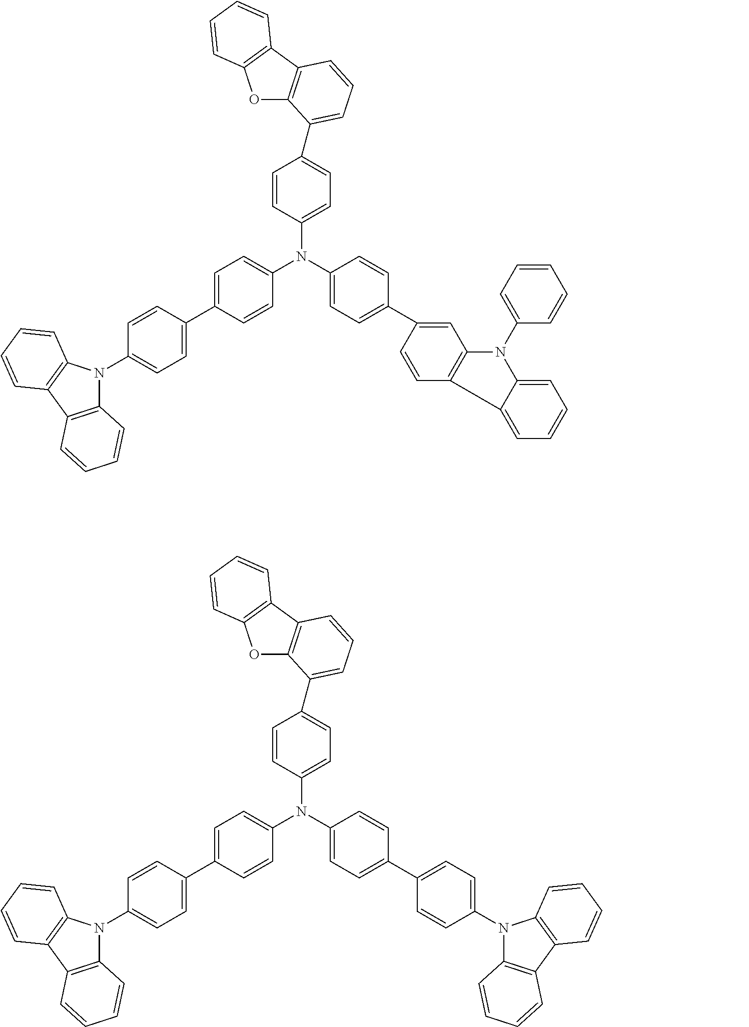 [SMILES: c1ccc(-n2c3ccccc3c3ccc(-c4ccc(N(c5ccc(-c6ccc(-n7c8ccccc8c8ccccc87)cc6)cc5)c5ccc(-c6cccc7c6oc6ccccc67)cc5)cc4)cc32)cc1 ; c1ccc2c(c1)oc1c(-c3ccc(N(c4ccc(-c5ccc(-n6c7ccccc7c7ccccc76)cc5)cc4)c4ccc(-c5ccc(-n6c7ccccc7c7ccccc76)cc5)cc4)cc3)cccc12]

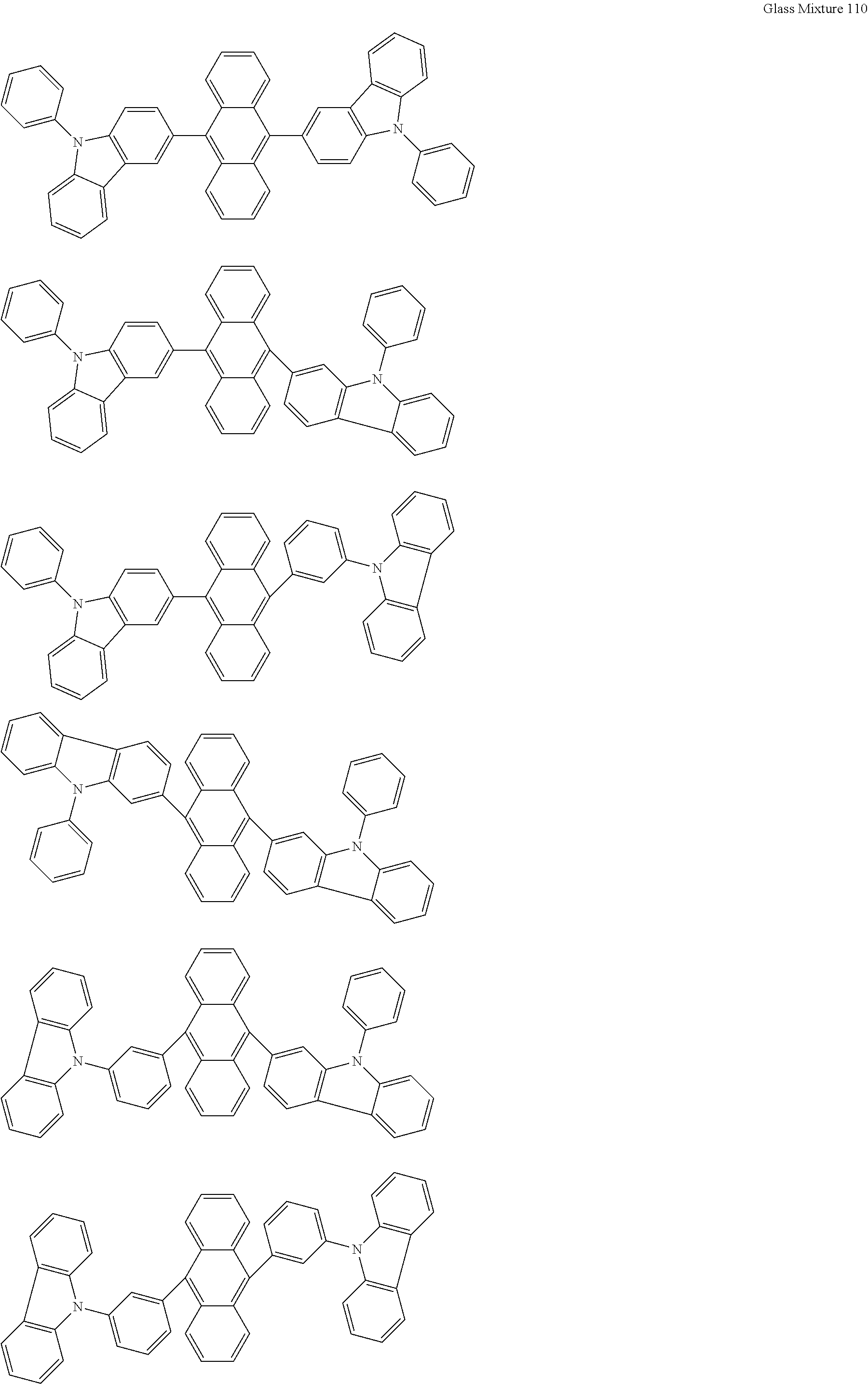

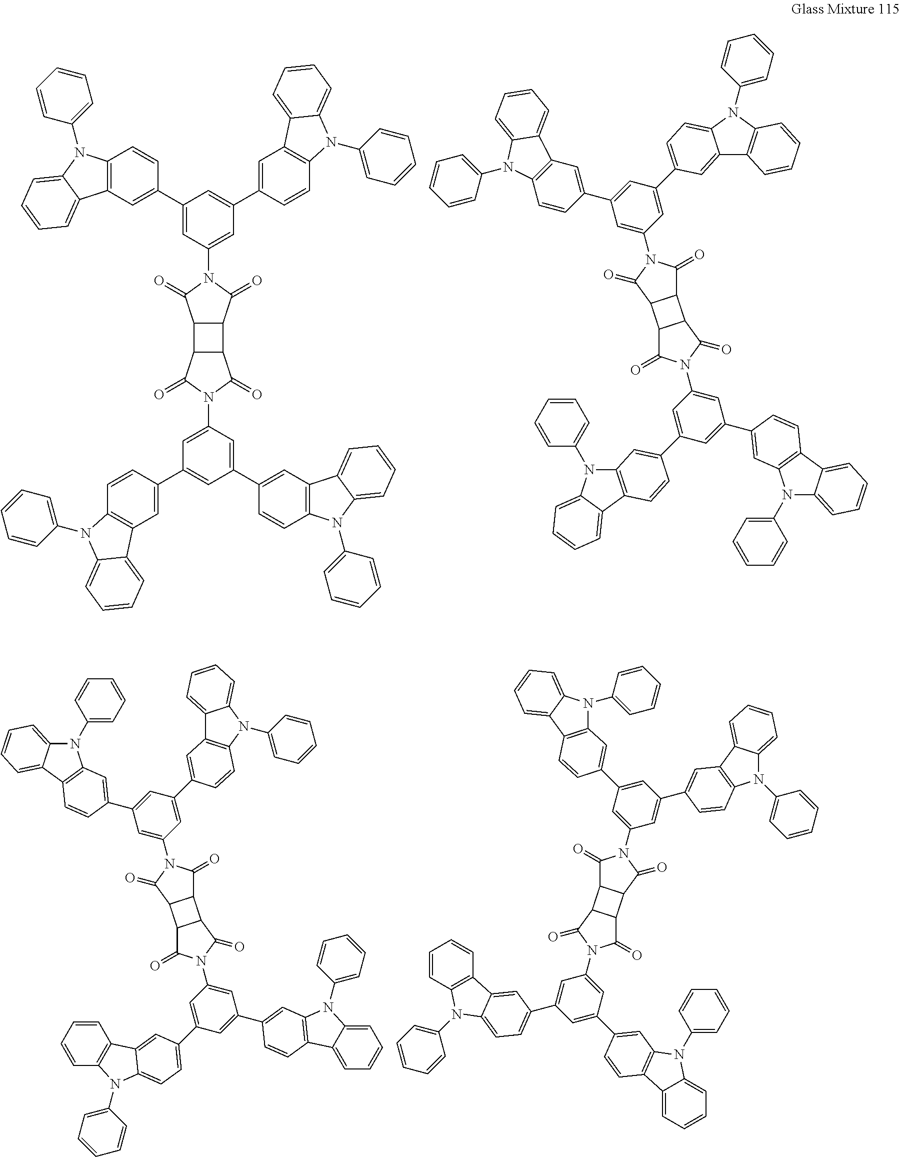

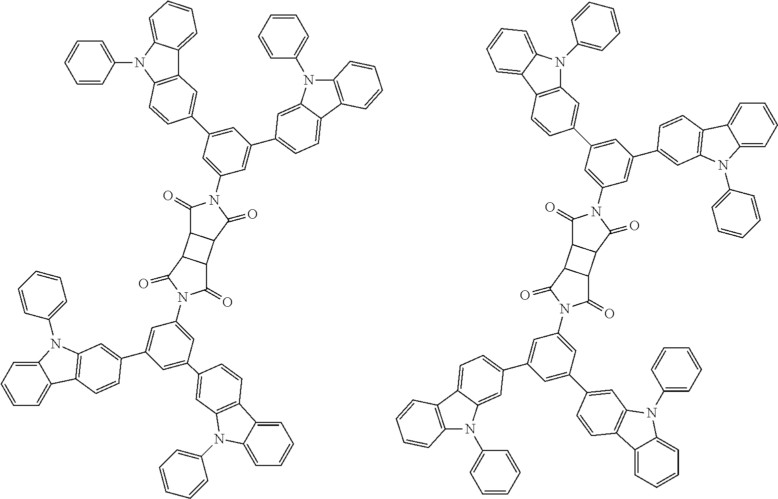 [SMILES: O=C1C2C(C(=O)N1c1cc(-c3ccc4c(c3)c3ccccc3n4-c3ccccc3)cc(-c3ccc4c5ccccc5n(-c5ccccc5)c4c3)c1)C1C(=O)N(c3cc(-c4ccc5c6ccccc6n(-c6ccccc6)c5c4)cc(-c4ccc5c6ccccc6n(-c6ccccc6)c5c4)c3)C(=O)C21 ; O=C1C2C(C(=O)N1c1cc(-c3ccc4c5ccccc5n(-c5ccccc5)c4c3)cc(-c3ccc4c5ccccc5n(-c5ccccc5)c4c3)c1)C1C(=O)N(c3cc(-c4ccc5c6ccccc6n(-c6ccccc6)c5c4)cc(-c4ccc5c6ccccc6n(-c6ccccc6)c5c4)c3)C(=O)C21]

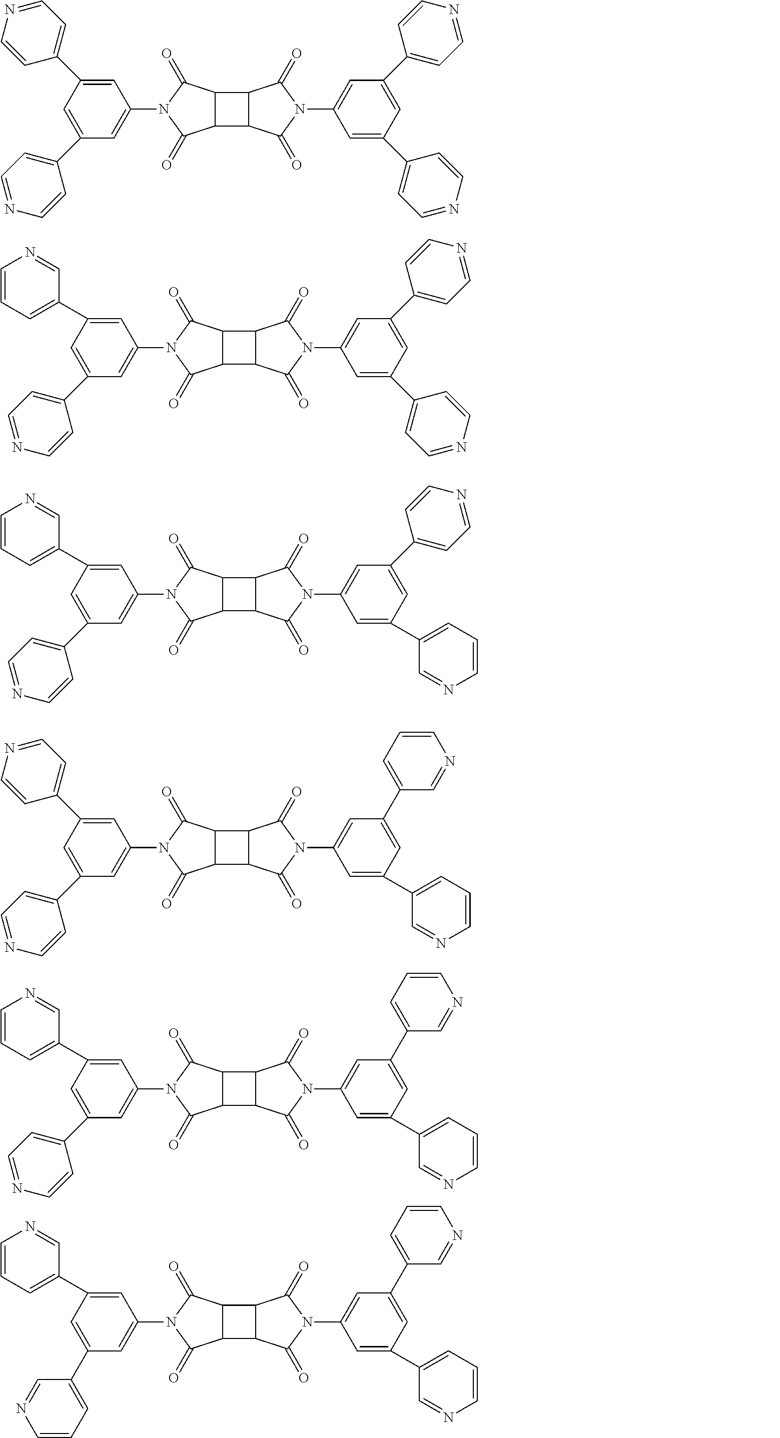

Hole-Transporting Glass Mixture 121 contains the following compounds:

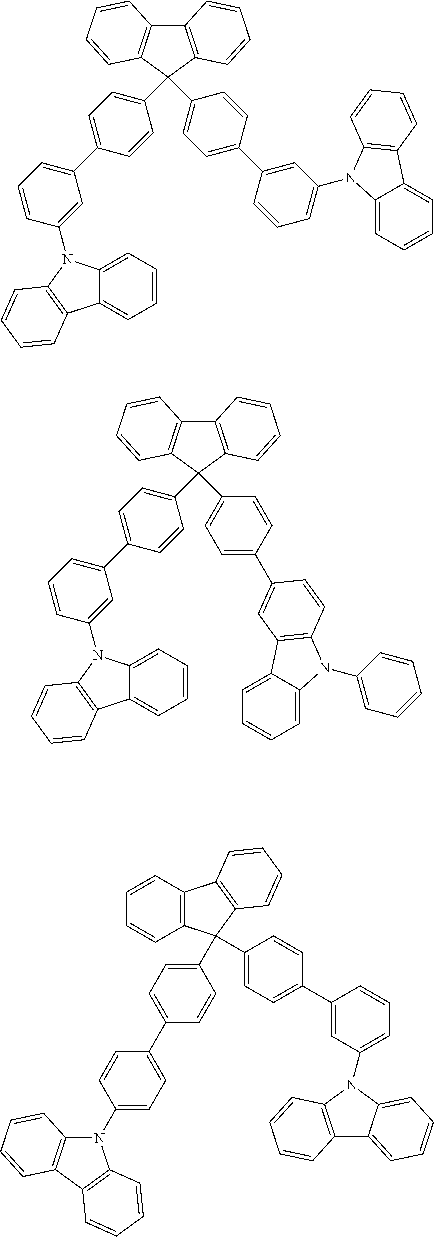 [SMILES: c1cc(-c2ccc(C3(c4ccc(-c5cccc(-n6c7ccccc7c7ccccc76)c5)cc4)c4ccccc4-c4ccccc43)cc2)cc(-n2c3ccccc3c3ccccc32)c1 ; c1ccc(-n2c3ccccc3c3cc(-c4ccc(C5(c6ccc(-c7cccc(-n8c9ccccc9c9ccccc98)c7)cc6)c6ccccc6-c6ccccc65)cc4)ccc32)cc1 ; c1cc(-c2ccc(C3(c4ccc(-c5ccc(-n6c7ccccc7c7ccccc76)cc5)cc4)c4ccccc4-c4ccccc43)cc2)cc(-n2c3ccccc3c3ccccc32)c1]

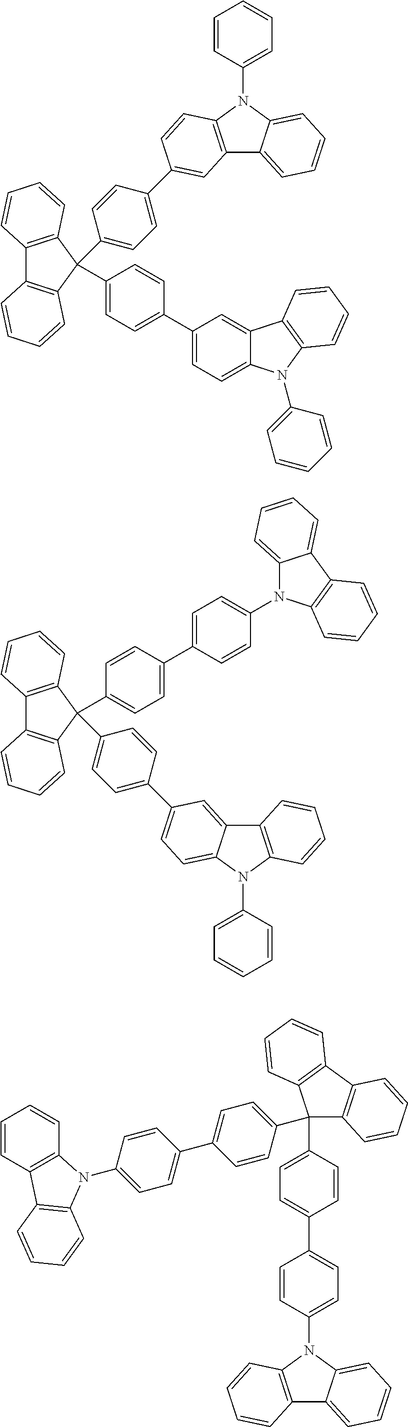

Hole-Transporting Glass Mixture 122 contains the following compounds:

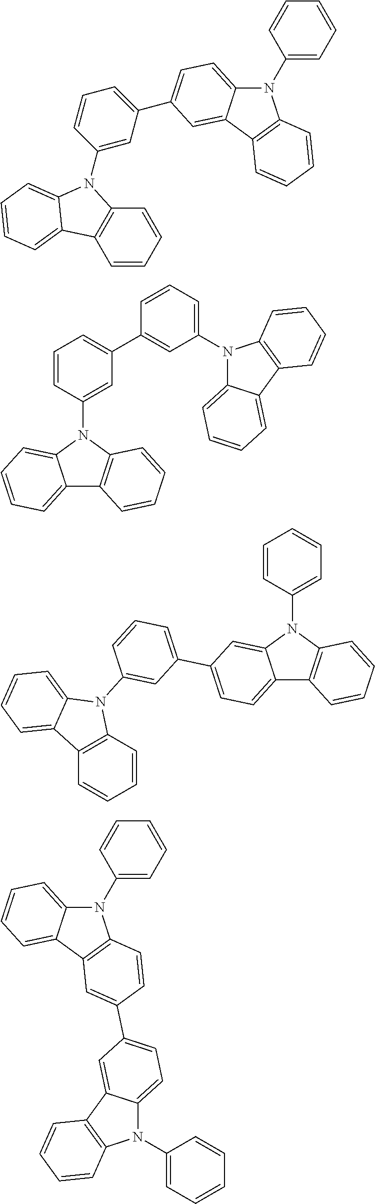

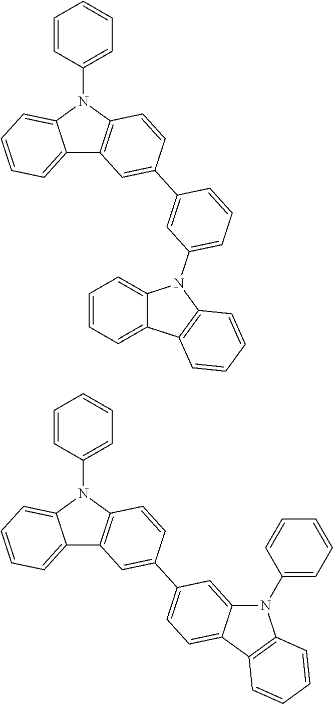 [SMILES: c1ccc(-n2c3ccccc3c3cc(-c4cccc(-n5c6ccccc6c6ccccc65)c4)ccc32)cc1 ; c1ccc(-n2c3ccccc3c3cc(-c4ccc5c6ccccc6n(-c6ccccc6)c5c4)ccc32)cc1]

Ambipolar Glass Mixture 123 contains the following compounds:

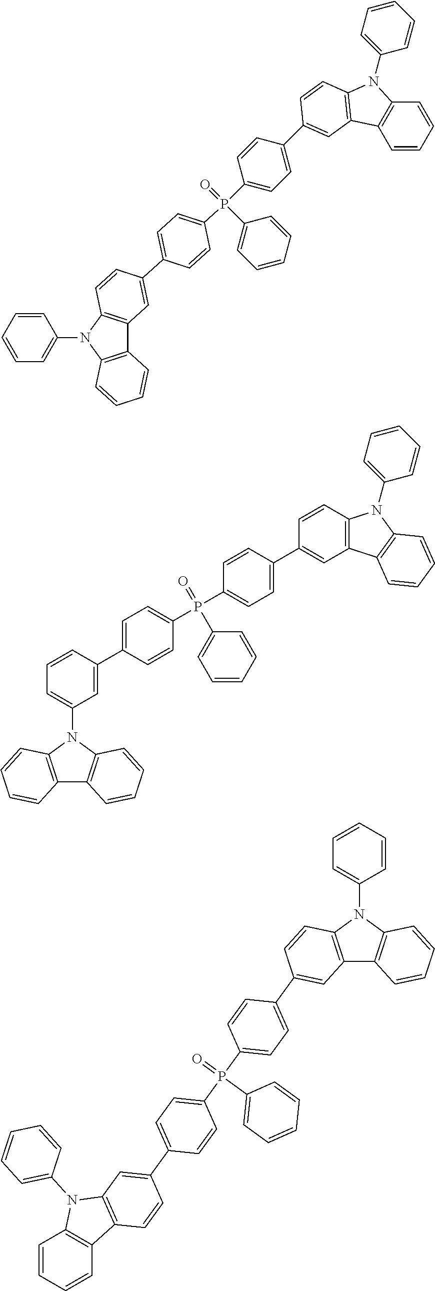 [SMILES: O=P(c1ccccc1)(c1ccc(-c2ccc3c(c2)c2ccccc2n3-c2ccccc2)cc1)c1ccc(-c2ccc3c(c2)c2ccccc2n3-c2ccccc2)cc1 ; O=P(c1ccccc1)(c1ccc(-c2cccc(-n3c4ccccc4c4ccccc43)c2)cc1)c1ccc(-c2ccc3c(c2)c2ccccc2n3-c2ccccc2)cc1 ; O=P(c1ccccc1)(c1ccc(-c2ccc3c(c2)c2ccccc2n3-c2ccccc2)cc1)c1ccc(-c2ccc3c4ccccc4n(-c4ccccc4)c3c2)cc1]

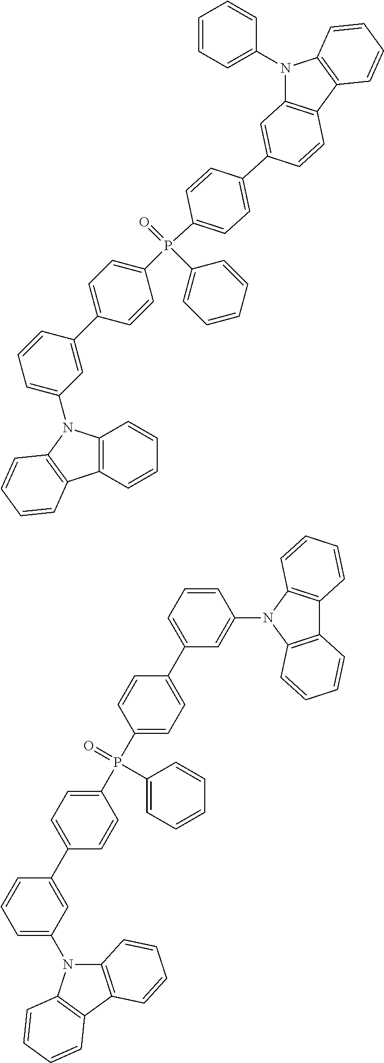 [SMILES: O=P(c1ccccc1)(c1ccc(-c2cccc(-n3c4ccccc4c4ccccc43)c2)cc1)c1ccc(-c2ccc3c4ccccc4n(-c4ccccc4)c3c2)cc1 ; O=P(c1ccccc1)(c1ccc(-c2cccc(-n3c4ccccc4c4ccccc43)c2)cc1)c1ccc(-c2cccc(-n3c4ccccc4c4ccccc43)c2)cc1]

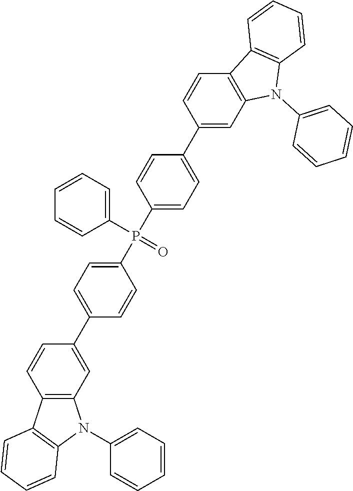 [SMILES: O=P(c1ccccc1)(c1ccc(-c2ccc3c4ccccc4n(-c4ccccc4)c3c2)cc1)c1ccc(-c2ccc3c4ccccc4n(-c4ccccc4)c3c2)cc1]

Ambipolar Glass Mixture 124 contains the following compounds:

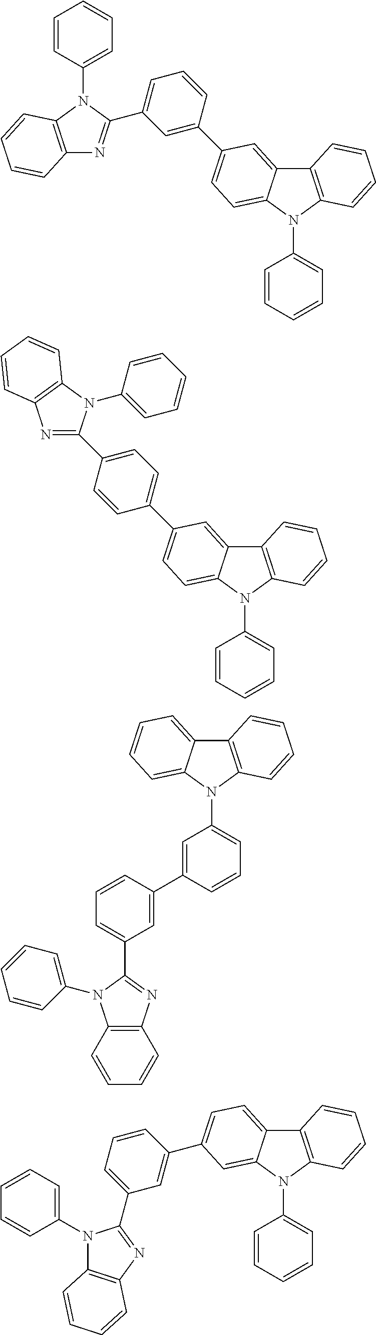

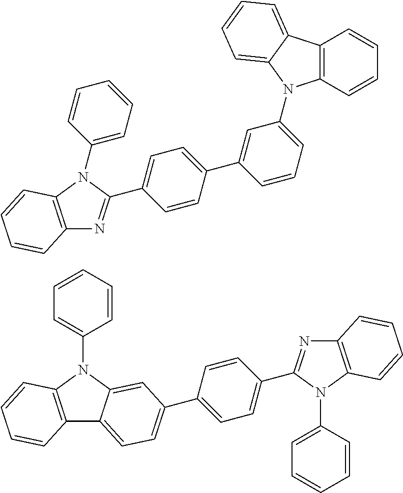

Electron-Transporting Glass Mixture 125 contains the following compounds:

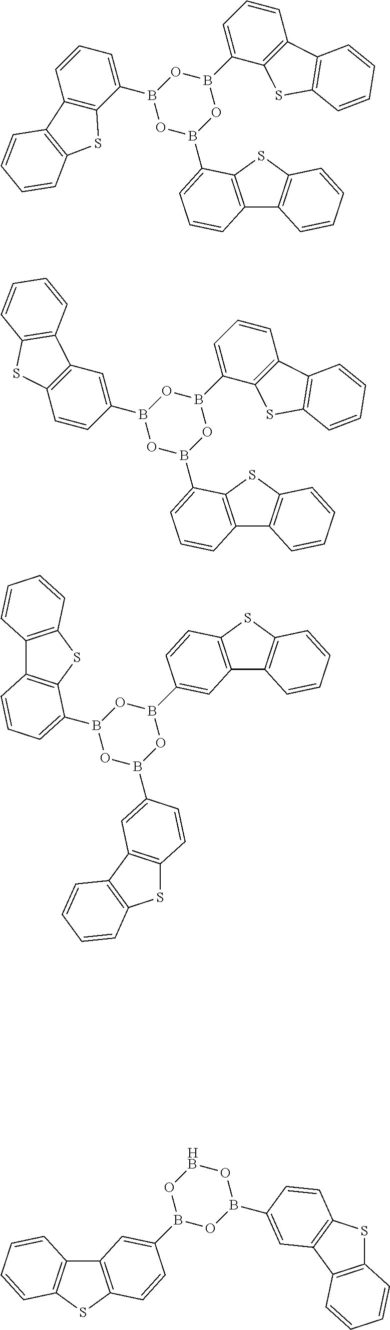

Hole-Transporting Glass Mixture 126 contains the following compounds:

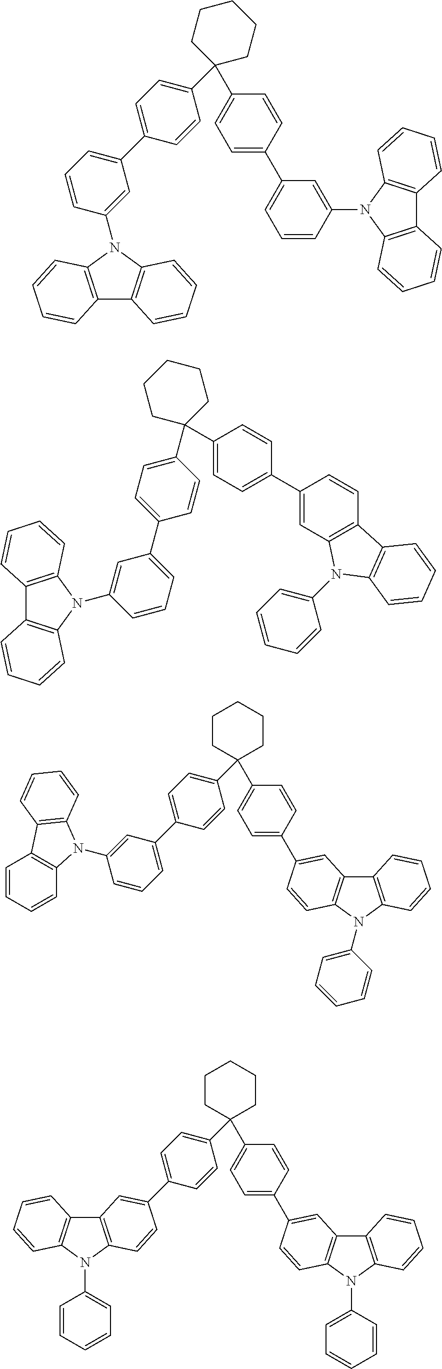

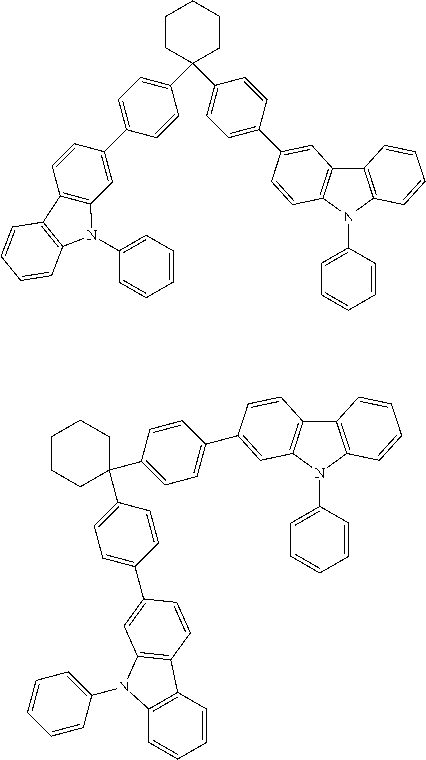 [SMILES: c1ccc(-n2c3ccccc3c3cc(-c4ccc(C5(c6ccc(-c7ccc8c9ccccc9n(-c9ccccc9)c8c7)cc6)CCCCC5)cc4)ccc32)cc1 ; c1ccc(-n2c3ccccc3c3ccc(-c4ccc(C5(c6ccc(-c7ccc8c9ccccc9n(-c9ccccc9)c8c7)cc6)CCCCC5)cc4)cc32)cc1]

Hole-Transporting Glass Mixture 127 contains the following compounds:

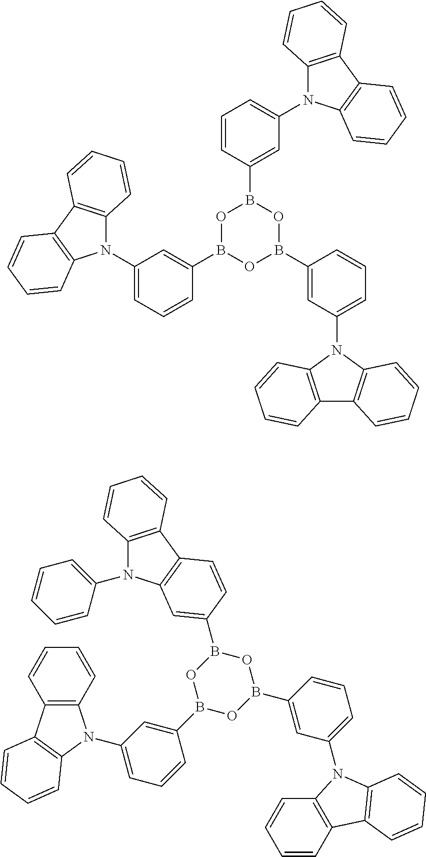 [SMILES: c1cc(B2OB(c3cccc(-n4c5ccccc5c5ccccc54)c3)OB(c3cccc(-n4c5ccccc5c5ccccc54)c3)O2)cc(-n2c3ccccc3c3ccccc32)c1 ; c1ccc(-n2c3ccccc3c3ccc(B4OB(c5cccc(-n6c7ccccc7c7ccccc76)c5)OB(c5cccc(-n6c7ccccc7c7ccccc76)c5)O4)cc32)cc1]

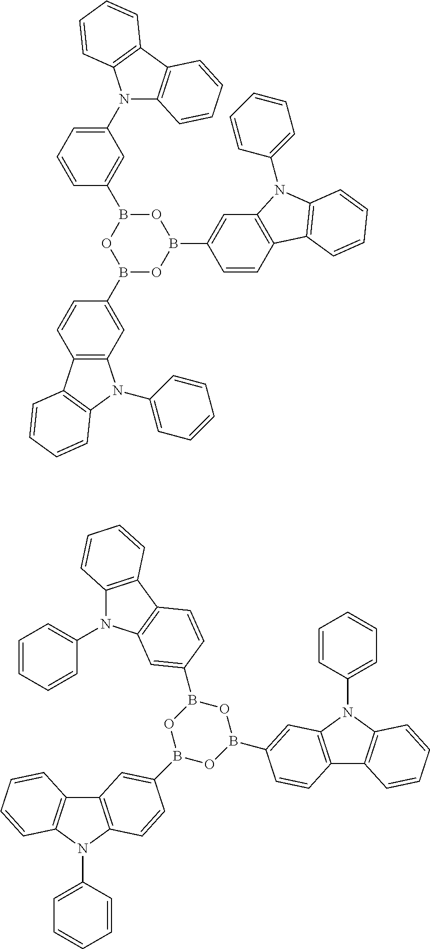 [SMILES: c1ccc(-n2c3ccccc3c3ccc(B4OB(c5cccc(-n6c7ccccc7c7ccccc76)c5)OB(c5ccc6c7ccccc7n(-c7ccccc7)c6c5)O4)cc32)cc1 ; c1ccc(-n2c3ccccc3c3cc(B4OB(c5ccc6c7ccccc7n(-c7ccccc7)c6c5)OB(c5ccc6c7ccccc7n(-c7ccccc7)c6c5)O4)ccc32)cc1]

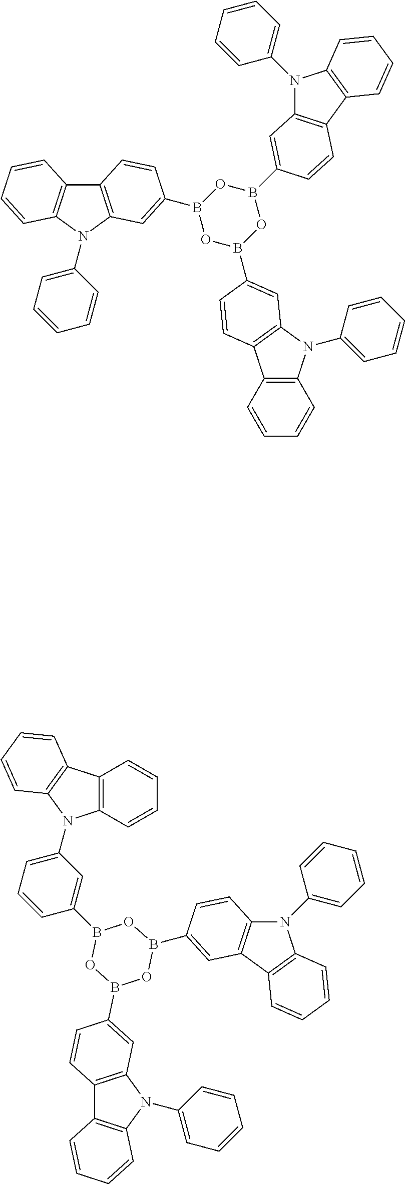 [SMILES: c1ccc(-n2c3ccccc3c3ccc(B4OB(c5ccc6c7ccccc7n(-c7ccccc7)c6c5)OB(c5ccc6c7ccccc7n(-c7ccccc7)c6c5)O4)cc32)cc1 ; c1ccc(-n2c3ccccc3c3cc(B4OB(c5cccc(-n6c7ccccc7c7ccccc76)c5)OB(c5ccc6c7ccccc7n(-c7ccccc7)c6c5)O4)ccc32)cc1]

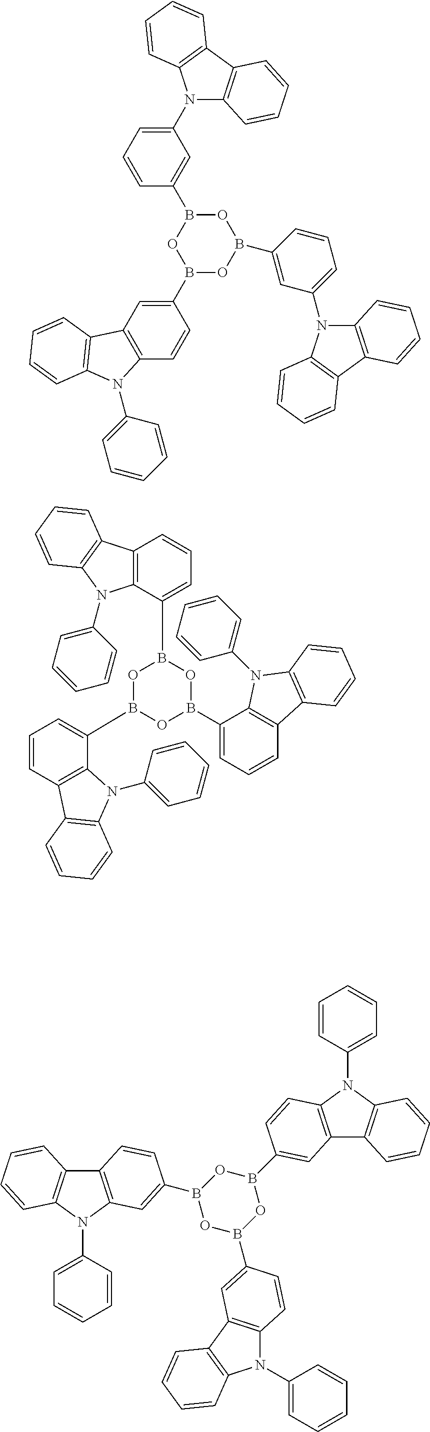

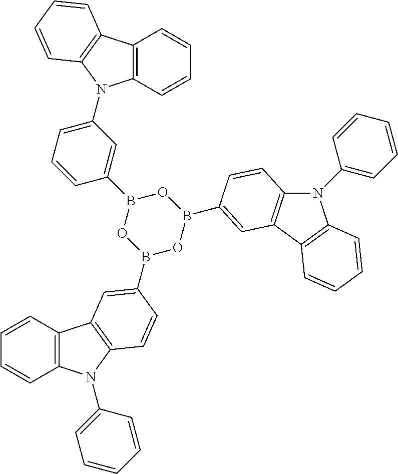 [SMILES: c1ccc(-n2c3ccccc3c3cc(B4OB(c5cccc(-n6c7ccccc7c7ccccc76)c5)OB(c5ccc6c(c5)c5ccccc5n6-c5ccccc5)O4)ccc32)cc1]

Hole-Transporting Glass Mixture 128 contains the following compounds:

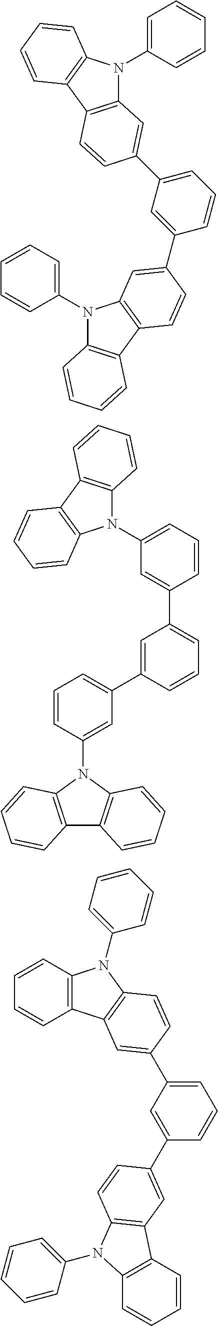

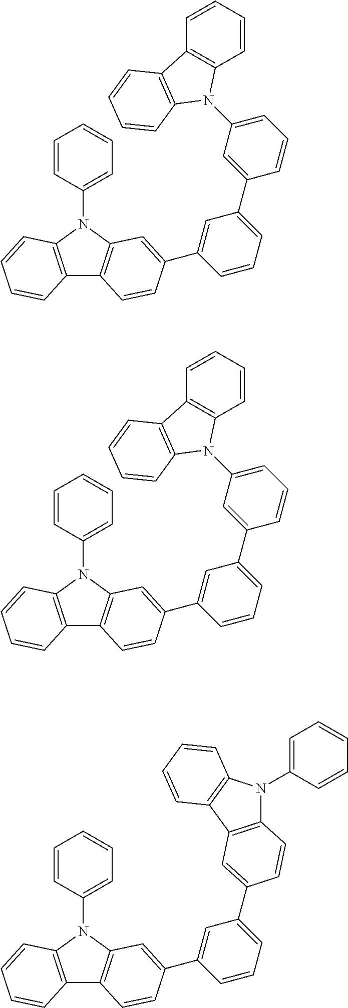 [SMILES: c1ccc(-n2c3ccccc3c3ccc(-c4cccc(-c5cccc(-n6c7ccccc7c7ccccc76)c5)c4)cc32)cc1 ; c1ccc(-n2c3ccccc3c3ccc(-c4cccc(-c5cccc(-n6c7ccccc7c7ccccc76)c5)c4)cc32)cc1 ; c1ccc(-n2c3ccccc3c3cc(-c4cccc(-c5ccc6c7ccccc7n(-c7ccccc7)c6c5)c4)ccc32)cc1]

Electron-Transporting Glass Mixture 129 contains the following compounds:

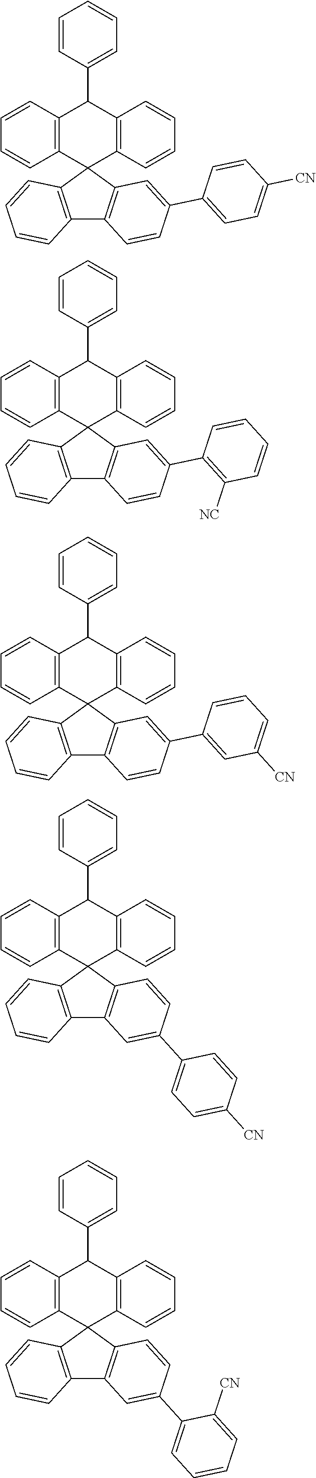

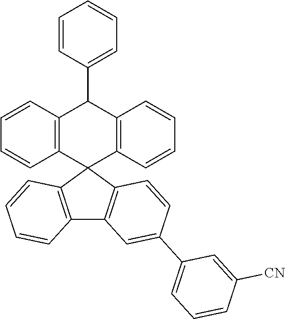 [SMILES: N#Cc1cccc(-c2ccc3c(c2)-c2ccccc2C32c3ccccc3C(c3ccccc3)c3ccccc32)c1]

Hole-Transporting Glass Mixture 130 contains the following compounds:

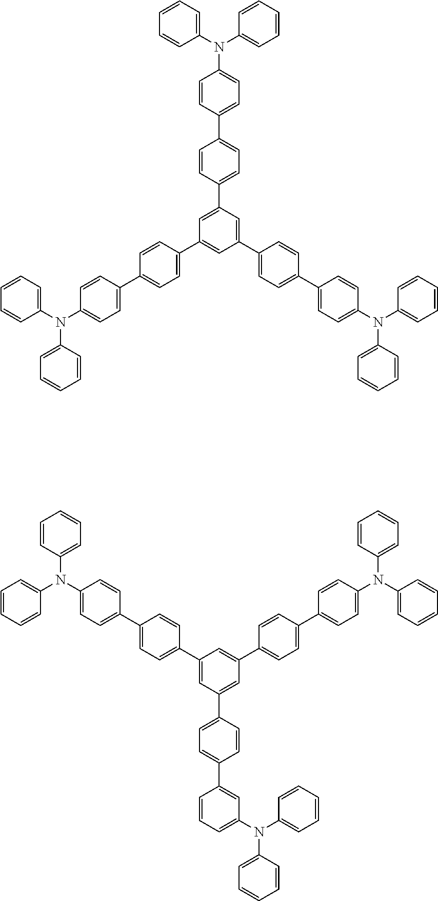 [SMILES: c1ccc(N(c2ccccc2)c2ccc(-c3ccc(-c4cc(-c5ccc(-c6ccc(N(c7ccccc7)c7ccccc7)cc6)cc5)cc(-c5ccc(-c6ccc(N(c7ccccc7)c7ccccc7)cc6)cc5)c4)cc3)cc2)cc1 ; c1ccc(N(c2ccccc2)c2ccc(-c3ccc(-c4cc(-c5ccc(-c6ccc(N(c7ccccc7)c7ccccc7)cc6)cc5)cc(-c5ccc(-c6cccc(N(c7ccccc7)c7ccccc7)c6)cc5)c4)cc3)cc2)cc1]

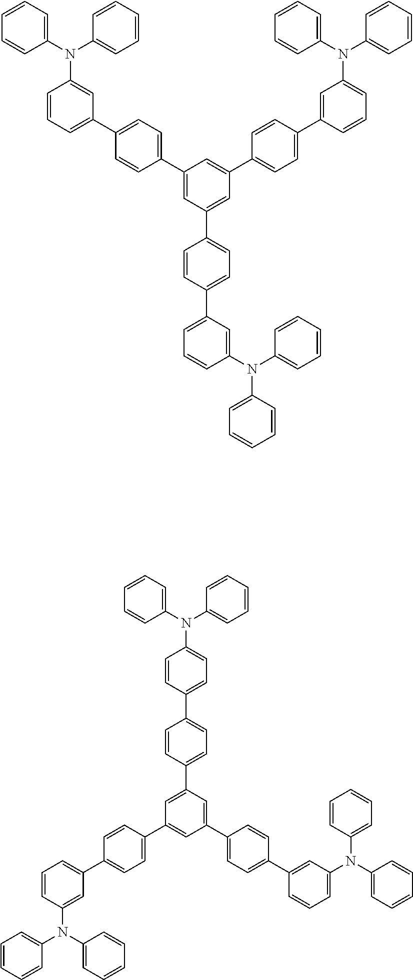 [SMILES: c1ccc(N(c2ccccc2)c2cccc(-c3ccc(-c4cc(-c5ccc(-c6cccc(N(c7ccccc7)c7ccccc7)c6)cc5)cc(-c5ccc(-c6cccc(N(c7ccccc7)c7ccccc7)c6)cc5)c4)cc3)c2)cc1 ; c1ccc(N(c2ccccc2)c2ccc(-c3ccc(-c4cc(-c5ccc(-c6cccc(N(c7ccccc7)c7ccccc7)c6)cc5)cc(-c5ccc(-c6cccc(N(c7ccccc7)c7ccccc7)c6)cc5)c4)cc3)cc2)cc1]

Electron-Transporting Glass Mixture 132 contains the following compounds:

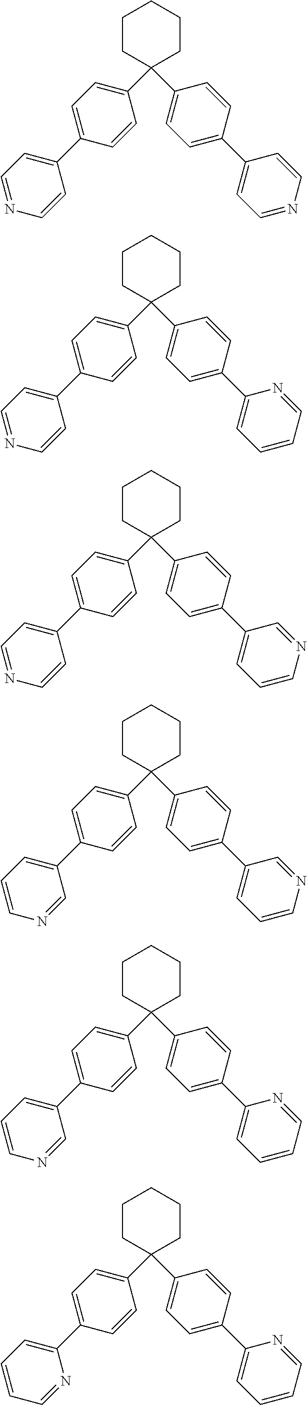 [SMILES: c1cc(-c2ccc(C3(c4ccc(-c5ccncc5)cc4)CCCCC3)cc2)ccn1 ; c1ccc(-c2ccc(C3(c4ccc(-c5ccncc5)cc4)CCCCC3)cc2)nc1 ; c1cncc(-c2ccc(C3(c4ccc(-c5ccncc5)cc4)CCCCC3)cc2)c1 ; c1cncc(-c2ccc(C3(c4ccc(-c5cccnc5)cc4)CCCCC3)cc2)c1 ; c1ccc(-c2ccc(C3(c4ccc(-c5cccnc5)cc4)CCCCC3)cc2)nc1 ; c1ccc(-c2ccc(C3(c4ccc(-c5ccccn5)cc4)CCCCC3)cc2)nc1]

Hole-Transporting Glass Mixture 133 contains the following compounds:

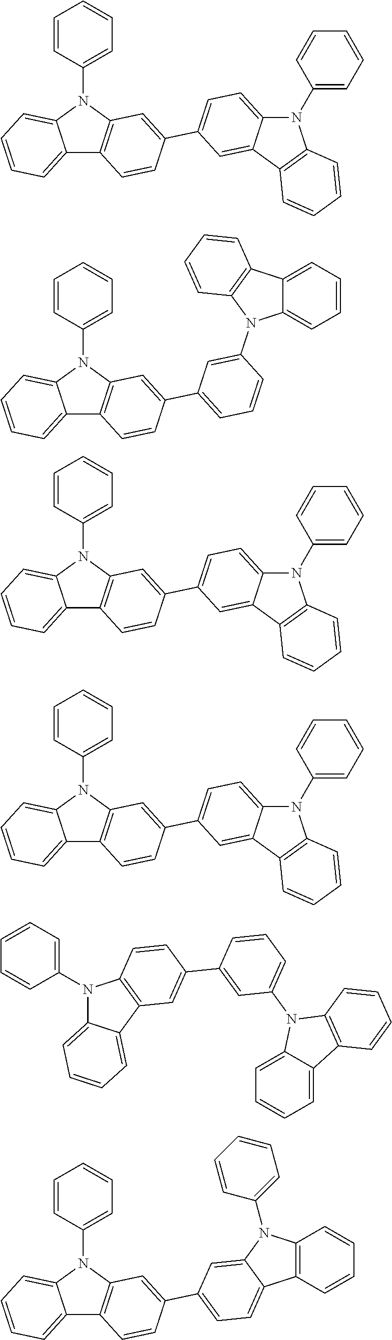

Hole-Transporting Glass Mixture 134 contains the following compounds:

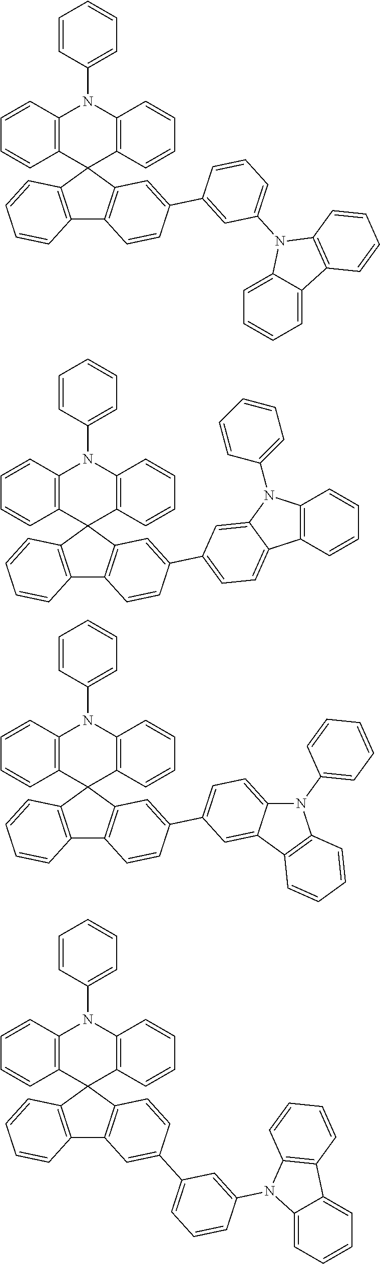

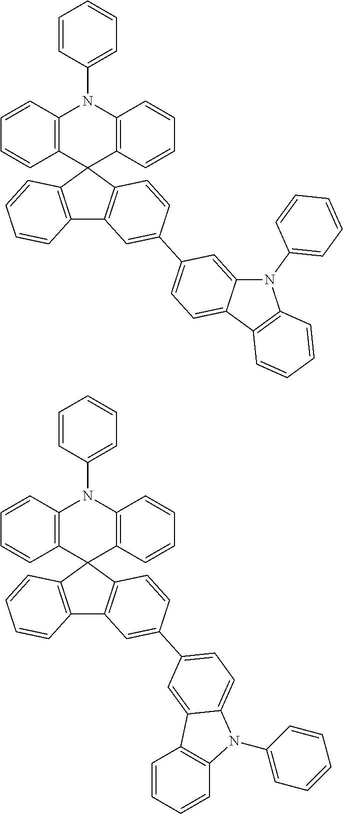 [SMILES: c1ccc(N2c3ccccc3C3(c4ccccc4-c4cc(-c5ccc6c7ccccc7n(-c7ccccc7)c6c5)ccc43)c3ccccc32)cc1 ; c1ccc(N2c3ccccc3C3(c4ccccc4-c4cc(-c5ccc6c(c5)c5ccccc5n6-c5ccccc5)ccc43)c3ccccc32)cc1]

Electron-Transporting Glass Mixture 135 contains the following compounds:

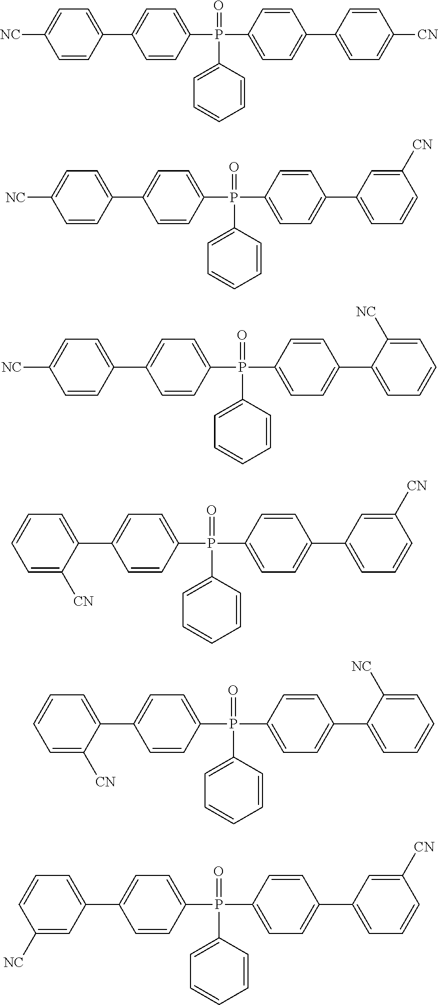 [SMILES: N#Cc1ccc(-c2ccc(P(=O)(c3ccccc3)c3ccc(-c4ccc(C#N)cc4)cc3)cc2)cc1 ; N#Cc1ccc(-c2ccc(P(=O)(c3ccccc3)c3ccc(-c4cccc(C#N)c4)cc3)cc2)cc1 ; N#Cc1ccc(-c2ccc(P(=O)(c3ccccc3)c3ccc(-c4ccccc4C#N)cc3)cc2)cc1 ; N#Cc1cccc(-c2ccc(P(=O)(c3ccccc3)c3ccc(-c4ccccc4C#N)cc3)cc2)c1 ; N#Cc1ccccc1-c1ccc(P(=O)(c2ccccc2)c2ccc(-c3ccccc3C#N)cc2)cc1 ; N#Cc1cccc(-c2ccc(P(=O)(c3ccccc3)c3ccc(-c4cccc(C#N)c4)cc3)cc2)c1]

Ambipolar Glass Mixture 136 contains the following compounds:

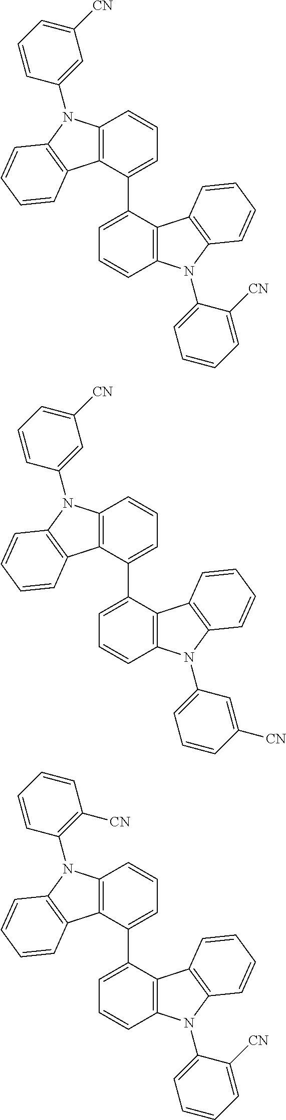 [SMILES: N#Cc1cccc(-n2c3ccccc3c3c(-c4cccc5c4c4ccccc4n5-c4ccccc4C#N)cccc32)c1 ; N#Cc1cccc(-n2c3ccccc3c3c(-c4cccc5c4c4ccccc4n5-c4cccc(C#N)c4)cccc32)c1 ; N#Cc1ccccc1-n1c2ccccc2c2c(-c3cccc4c3c3ccccc3n4-c3ccccc3C#N)cccc21]

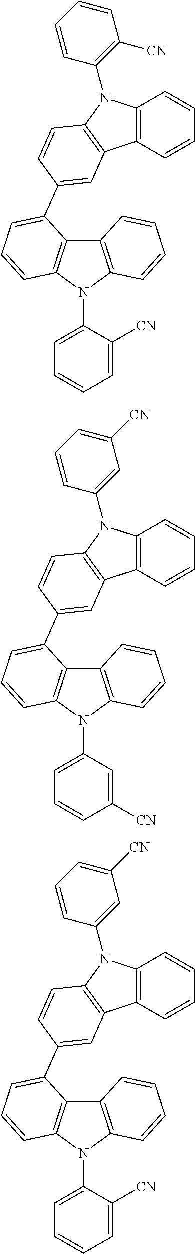

### GENERAL DEVICE ARCHITECTURE

Embodiments of this disclosure include simple structures comprising a single anode and cathode to more complex devices, such as passive matrix displays comprised of orthogonal arrays of anodes and cathodes to form pixels, and active-matrix displays where each pixel is controlled independently, for example, with a thin film transistor (TFT).

There are numerous configurations of the organic layers wherein the present invention can be successfully practiced. Essential requirements are a cathode, an anode, an HTL and an LEL. A typical structure contains a substrate, an anode, an optional hole-injecting layer, a hole-transporting layer, a light-emitting layer, an electron-transporting layer, and a cathode. These layers are described in detail below. Note that the substrate may alternatively be located adjacent to the cathode, or the substrate may actually constitute the anode or cathode. Also, the total combined thickness of the organic layers is less than 600 nm, less than 500 nm, or from 5 nm to 450 nm.

### SUBSTRATE

The substrate can either be light transmissive or opaque, depending on the intended direction of light emission. The light transmissive property is desirable for viewing the electroluminescence (EL) emission through the substrate. Transparent glass or organic material is commonly employed in such cases. For applications where the EL emission is viewed through the top electrode, the transmissive characteristic of the bottom support is immaterial, and therefore can be light transmissive, light absorbing or light reflective. Substrates for use in this case include, but are not limited to, glass, plastic, semiconductor materials, ceramics, and circuit board materials. Of course it is necessary to provide in these device configurations a light-transparent top electrode.

### ANODE

The conductive anode layer is commonly formed over the substrate and, when EL emission is viewed through the anode, should be transparent or substantially transparent to the emission of interest. Common transparent anode materials used in this invention are indium-tin oxide (ITO) and tin oxide, but other metal oxides can work including, but not limited to, aluminum- or indium-doped zinc oxide (IZO), magnesium-indium oxide, and nickel-tungsten oxide. In addition to these oxides, metal nitrides, such as gallium nitride, and metal selenides, such as zinc selenide, and metal sulfides, such as zinc sulfide, can be used in layer. For applications where EL emission is viewed through the top electrode, the transmissive characteristics of layer are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater. Desired anode materials are commonly deposited by any suitable means such as evaporation, sputtering, chemical vapor deposition, or electrochemical means. Anodes can be patterned using well-known photolithographic processes.

### HOLE-INJECTING LAYER (HIL)

Optionally, a hole-injecting layer may be disposed between anode and hole-transporting layer. The hole-injecting material can serve to improve the film formation property of subsequent organic layers and to facilitate injection of holes into the hole-transporting layer. Suitable materials for use in the hole-injecting layer include, but are not limited to, porphyrinic compounds such as those described in U.S. Pat. No. 4,720,432, and plasma-deposited fluorocarbon polymers such as those described in U.S. Pat. No. 6,208,075. Alternative hole-injecting materials reportedly useful in organic EL devices are described in EP 0 891 121 A1 and EP 1 029 909 A1.

### HOLE-TRANSPORT LAYER (HTL)

The hole-transporting layer of the organic EL device contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine group. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. Nos. 3,567,450 and 3,658,520.

One particular class of aromatic tertiary amines includes those which include at least two aromatic tertiary amine moieties as described in U.S. Pat. Nos. 4,720,432 and 5,061,569. Such compounds include those represented by structural formula (II).

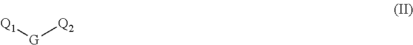

In formula (II), Q₁ and Q₂ are independently selected aromatic tertiary amine moieties and G is a linking group such as an arylene, cycloalkylene, or alkylene group of a carbon to carbon bond. In one embodiment, at least one of Q₁ or Q₂ contains a polycyclic fused ring group, e.g., a naphthalene. When G is an aryl group, it is conveniently a phenylene, biphenylene, or naphthalene group.

A useful class of triarylamine groups satisfying structural formula (II) and containing two triarylamine groups is represented by structural formula (III):

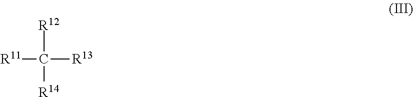

In formula (III), R¹¹ and R¹² each independently represents a hydrogen atom, an aryl group, or an alkyl group or R¹¹ and R¹² together represent the atoms completing a cycloalkyl group; and R¹³ and R¹⁴ each independently represents an aryl group, which is in turn substituted with a diaryl substituted amino group, as indicated by structural formula (IV):

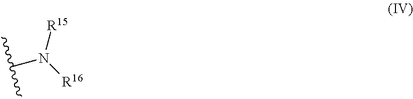

In formula (IV), R¹⁵ and R¹⁶ are independently selected aryl groups. In one embodiment, at least one of R¹⁵ and R¹⁶ contains a polycyclic fused ring group, e.g., naphthalene.

Another class of aromatic tertiary amine groups are the tetraaryldiamines. Tetraaryldiamines groups include two diarylamino groups, such as indicated by formula (IV), linked through an arylene group. Useful tetraaryldiamines include those represented by formula (V):

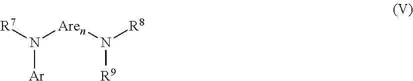

In formula (V), Are is selected from arylene group, such as a phenylene or anthracene group, n is an integer of from 1 to 4, and Ar, R⁷, R⁸, and R⁹ are independently selected aryl groups.

In a typical embodiment, at least one of Ar, R⁷, R⁸, and R⁹ is a polycyclic fused ring group, e.g., a naphthalene.

The various alkyl, alkylene, aryl, and arylene groups of the foregoing structural formulae (II), (III), (IV), (V), can each in turn be substituted. Typical substituents include alkyl groups, alkoxy groups, aryl groups, aryloxy groups, and halogen such as fluoride, chloride, and bromide. The various alkyl and alkylene groups typically contain from about 1 to 6 carbon atoms. The cycloalkyl moieties can contain from 3 to about 10 carbon atoms, but typically contain five, six, or seven ring carbon atoms (e.g., cyclopentyl, cyclohexyl, and cycloheptyl ring structures). The aryl and arylene groups are usually phenyl and phenylene moieties.

The hole-transporting layer can be formed of a single or a mixture of aromatic tertiary amine compounds. Specifically, one may employ a triarylamine, such as a triarylamine satisfying the formula (III), in combination with a tetraaryldiamine, such as indicated by formula (V). When a triarylamine is employed in combination with a tetraaryldiamine, the latter is positioned as a layer interposed between the triarylamine and the electron injecting and transporting layer. Illustrative of useful aromatic tertiary amines are the following:

1,1 Bis(4-di-p-tolylaminophenyl)cyclohexane

1,1-Bis(4-di-p-tolylaminophenyl)-4-phenylcyclohexane

4,4′-Bis(diphenylamino)quadriphenyl

Bis(4-dimethylamino-2-methylphenyl)-phenylmethane

N,N,N-Tri(p-tolyl)amine

4-(di-p-tolylamino)-4′-[4(di-p-tolylamino)-styryl]stilbene

N,N,N′,N′-Tetra-p-tolyl-4-4′-diaminobiphenyl

N,N,N′,N′-Tetraphenyl-4,4′-diaminobiphenyl

N,N,N′,N′-tetra-1-naphthyl-4,4′-diaminobiphenyl

N,N,N′,N′-tetra-2-naphthyl-4,4′-diaminobiphenyl

N-Phenylcarbazole

4,4′-Bis[N-(1-naphthyl)-N-phenylamino]biphenyl

4,4′-Bis[N-(1-naphthyl)-N-(2-naphthyl)amino]biphenyl

4,4″-Bis [N-(1-naphthyl)-N-phenylamino]p-terphenyl

4,4′-Bis[N-(2-naphthyl)-N-phenylamino]biphenyl

4,4′-Bis[N-(3-acenaphthenyl)-N-phenylamino]biphenyl

1,5-Bis [N-(1-naphthyl)-N-phenylamino]naphthalene

4,4′-Bis[N-(9-anthryl)-N-phenylamino]biphenyl

4,4″-Bis [N-(1-anthryl)-N-phenylamino]-p-terphenyl

4,4′-Bis[N-(2-phenanthryl)-N-phenylamino]biphenyl

4,4′-Bis[N-(8-fluoranthenyl)-N-phenylamino]biphenyl

4,4′-Bis[N-(2-pyrenyl)-N-phenylamino]biphenyl

4,4′-Bis[N-(2-naphthacenyl)-N-phenylamino]biphenyl

4,4′-Bis [N-(2-perylenyl)-N-phenylamino]biphenyl

4,4′-Bis[N-(1-coronenyl)-N-phenylamino]biphenyl

2,6-Bis(di-p-tolylamino)naphthalene

2,6-Bis[di-(1-naphthyl)amino]naphthalene

2,6-Bis[N-(1-naphthyl)-N-(-2-naphthyl)amino]naphthalene

N,N,N′,N′-Tetra(2-naphthyl)-4,4″-diamino-p-terphenyl

4,4′-Bis{N-phenyl-N-[4-(1-naphthyl)-phenyl]amino}biphenyl

4,4′-Bis[N-phenyl-N-(2-pyrenyl)amino]biphenyl

2,6-Bis[N,N-di(2-naphthyl)amine]fluorine

1,5-Bis[N-(1-naphthyl)-N-phenylamino]naphthalene

Another class of useful hole-transporting materials includes polycyclic aromatic compounds as described in EP 1 009 041. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly (4-styrenesulfonate) also called PEDOT/PSS. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly (4-styrenesulfonate) also called PEDOT/PSS.

### LIGHT-EMITTING LAYER (LEL)

As more fully described in U.S. Pat. Nos. 4,769,292 and 5,935,721, the light-emitting layer (LEL) of the OLED multilayer electroluminescent device includes a host and an emitter-dopant. The emitter dopant is chosen from luminescent material or fluorescent material where electroluminescence is produced as a result of electron-hole pair recombination in this region. The luminescent material can also phosphorescent or thermally delayed fluorescent. The host materials in the light-emitting layer can be an electron-transporting material, as defined below, a hole-transporting material, as defined above, or another material or combination of materials that support hole-electron recombination. The emitter-dopant is usually chosen from highly fluorescent dyes, but phosphorescent compounds, e.g., transition metal complexes as described in WO 98/55561, WO 00/18851, WO 00/57676, and WO 00/70655 are also useful. Emitter-dopants are typically coated as 0.01 to 10% by weight into the host material.

An important relationship for choosing a dye as a dopant is a comparison of the bandgap potential which is defined as the energy difference between the highest occupied molecular orbital and the lowest unoccupied molecular orbital of the molecule. For efficient energy transfer from the host to the dopant molecule, a necessary condition is that the band gap of the dopant is smaller than that of the host material.

Emitting molecules known to be of use include, but are not limited to, those disclosed in U.S. Pat. Nos. 4,768,292, 5,141,671, 5,150,006, 5,151,629, 5,405,709, 5,484,922, 5,593,788, 5,645,948, 5,683,823, 5,755,999, 5,928,802, 5,935,720, 5,935,721, and 6,020,078.

### PHOTOPHYSICAL CHARACTERIZATION

### Delayed Luminescence Spectra Collection

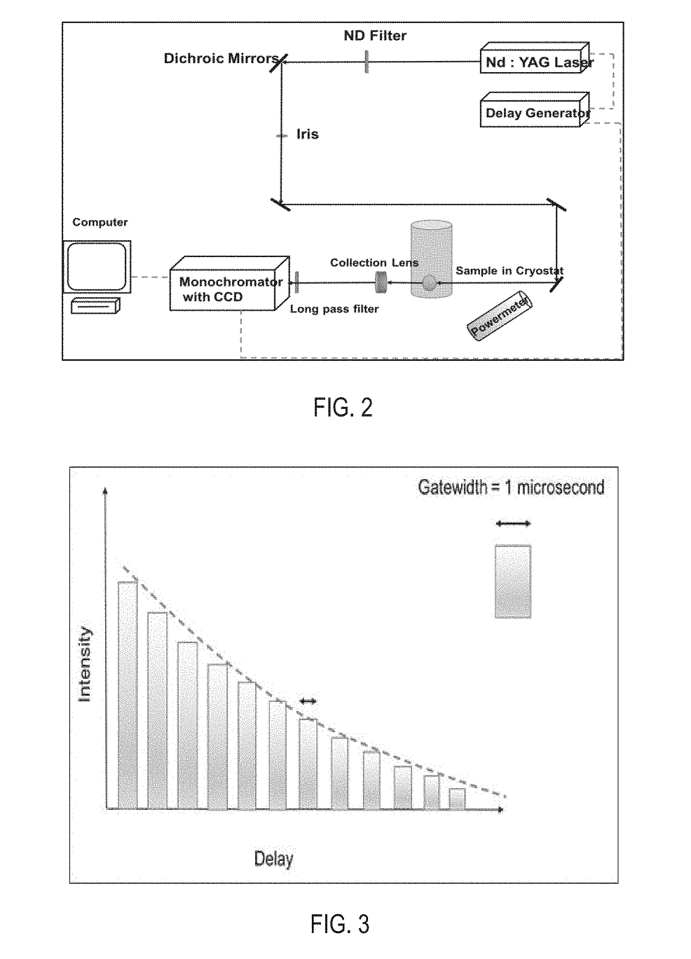

FIG. 2 shows the delayed luminescence spectral collection setup. In this figure, the optical path is represented by black lines and the dotted lines show the electrical connections. A pulsed Quanta Ray Nd: YAG laser with a repetition rate of 10 Hz was frequency doubled or tripled to produce a 355 nm or 532 nm pulses respectively. The film was placed in a cold finger sample holder with optical access and can be cooled with a liquid Helium closed cycle refrigerator (APD Cryogenics DE 202) to reach temperatures as low as 20 K. Samples were held at a pressure of around 10⁻² Torr. Emission spectra were obtained with an Oriel Instruments grating monochromator fitted with an Andor time-gated intensified charge coupled device (ICCD) for light detection. The ICCD can be controlled with the Andor Solis Software. The time between the excitation of the sample and the opening of the shutter is referred to as the time delay and the time that the gate voltage remained on is called the gate width. A more thorough description of the set-up can be obtained elsewhere (R. Chakraborty “Resolving puzzles in conjugated polymer photophysics-nanoseconds to microseconds”, PhD Thesis, 2017).

### Time Gated Data Collection

Triplet emission coming from simple intersystem crossing (ISC) from singlet exciton to triplet exciton follows an exponential decay. If we keep the gate width shorter than the excited state lifetime, we will see triplets. To collect the emission, the gate width was kept constant at 1 microsecond and the delay was varied. A simple collection scheme is shown in FIG. 3. The dashed line, in FIG. 3, is a visual guide and not intended to illustrate a real fit.

Two types of fluorescence processes are frequently encountered in studying the photophysics of OLED emitters—instantaneous or prompt fluorescence (PF) and delayed fluorescence (DF). The PF was recorded with the delay set to zero and with a short gate width ˜100 ns. Since the delayed fluorescence emission is so large and obeys algebraic decay laws, the choice of an ‘adequate’ detection width is tricky. As the delay time increases the decay becomes much slower. A constant detection width in linear time is a problem since the signal decreases at longer delay time. Hence, the delayed fluorescence signal collection was maintained at exponentially increasing intervals, making the data collection delays evenly spaced on log scale.

For time delays up to 1 microsecond (μs), gate width was maintained at 100 nanoseconds (ns). Beyond 1 μs time delay, the gate width was maintained at 10% of the delay, because it is believed to be a good compromise between time resolution and signal strength [C. Rothe and A. Monkman, Physical Review B, 68(7), (2003)]. To obtain true decay kinetics, the measured data points need to be scaled by the corresponding detection window. This was achieved by dividing each integrated value by the corresponding gate width. The pulse-to-pulse variation in the energy of the laser pulses was recorded using a standard joule/meter and was noted to be ˜+2%.

### Steady State Spectroscopy of Gold Nanoparticles

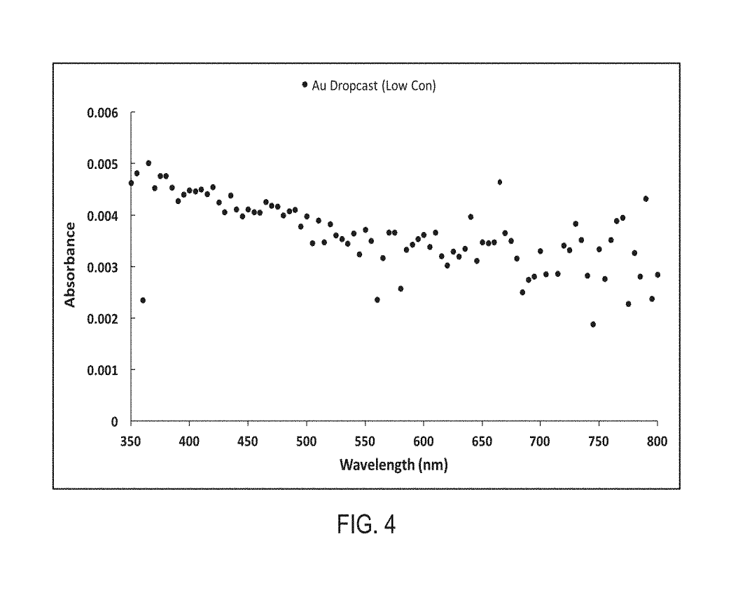

Room temperature absorption and emission spectra of gold nanoparticles (Au Nps) at a very low concentration dispersed in polystyrene matrix is shown in FIG. 4. Hardly any absorbance was observed in the optical range.

### EXAMPLES

### Comparative Example 1: Red Phosphorescent Emitter Ir(Piq)3 Neat Film

A 10 mg sample of tris [1-phenylisoquinoline-C2, N] iridium(III) (Ir(Piq)3), a red phosphorescent emitter obtained from Sigma Aldrich, was weighed and mixed with 10 ml of chloroform to make stock solutions with 1 milligram per milliliter (mg/mL) concentration. The solutions were stirred for about an hour to dissolve the emitter material completely.

A few drops of the stock solution were dropped onto clean 2 mm thick quartz discs obtained from Ted Pella Inc., placed in a Petri dish with a cover and dried while refrigerated to enforce slow solvent evaporation for about 2 hours in the dark to form drop cast neat films. The drop cast neat films were stored in glass containers, wrapped in aluminum foil to avoid light exposure and retained in a desiccator.

### Example 1: Red Phosphorescent Emitter Ir(Piq)3 Neat Film Incorporating Gold Nanoparticles

Dodecanethiol capped Au nanoparticles (Au Nps) of average diameter of 2 nm obtained from Nanocomposix and were incorporated into the Ir(Piq)3 stock solution. μL

Chloroform (10 mL) was added to a bottle containing 5 mg of Au nanoparticles to form a chloroform-Au solution. The chloroform-Au solution was stirred for about an hour. A 2 μL sample of chloroform-Au solution (0.5 mg/ml) was added to 20 μL of Ir(Piq)3 stock solution to form an Au-emitter solution. A few drops of the Au-emitter solution stock solution were dropped onto clean 2 mm thick quartz discs obtained from Ted Pella Inc., placed in a Petri dish with a cover, and were dried while refrigerated to enforce slow solvent evaporation for about 2 hours in the dark to form Au doped drop cast neat films. The Au doped drop cast neat films were stored in glass containers, wrapped in aluminum foil to avoid light exposure and retained in a desiccator.

### Absorption and Emission

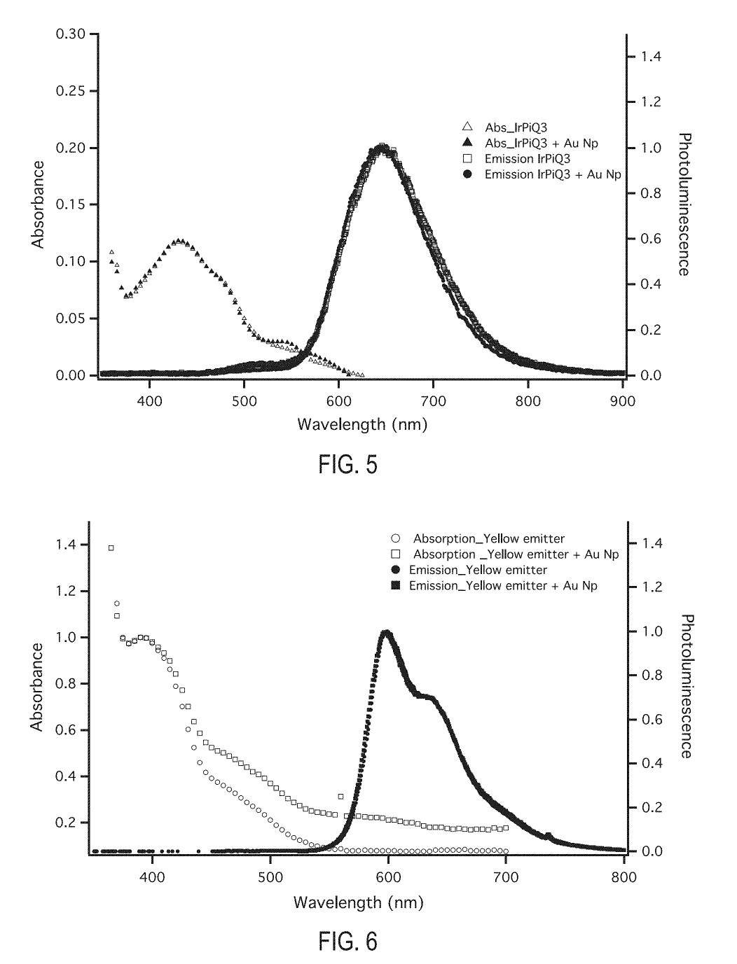

The absorption and emission of drop cast neat film of the phosphorescent emitter Ir(Piq)3 with and without Au nanoparticles are shown in FIG. 5. The spectra were normalized with the absorption max of Au nanoparticles doped film. The films were excited with 532 nm laser pulses. Emission spectra were collected at 100 microsecond gate width with no delay. Overall features of the films were unchanged. The addition of Au nanoparticles caused a blue shift in the emission peak from 644 nm for Ir(Piq)3 to 641 nm for Au Np doped Ir(Piq)3 film suggesting that Au nanoparticles prevent the molecules from coming close to each other thereby suppressing stacking interactions that tend to increase the conjugation length and red shift the spectra [C. J. Collison; V. Treemaneekarn; W. J. Oldham, Jr.; J. H. Hsu, and L. J. Rothberg, Synth. Met. 119, 515 (2001), J. Stampfl; W. Graupner; G. Leising and U. J. Scherf, J. Lumin, 63 (3), 117-123, (1995)]. Another interesting feature is the reduction in bandwidth or full width at half maxima (FWHM) by about 9 nm with the introduction of Au Nps.

The spectra in FIG. 6 were normalized PL spectra of PROPRIETARY PHOSPHORESCENT YELLOW EMITTER in HT-1700 host films at room temperature. The samples in FIG. 6 were excited with 355 nm laser pulses with no delay and a wide gate of 1 millisecond. The tiny spikes at around 740 nm in the Emission spectra are instrumental artifacts and were not observed while taking other readings.

### Time Resolved Emission

The time resolved emission spectra were integrated from 550 nm to 750 nm and plotted as a function of time delay as shown in FIG. 6. The decay plots were normalized with respect to the max value, i.e., the integrated intensity at 100 ns. The solid lines represent the single exponential fits to the data. Clearly one can see that the lifetime is reduced by ˜25% which correlates to the previous observation of higher luminescence of Au doped films with respect to neat films.

### Delayed Luminescence

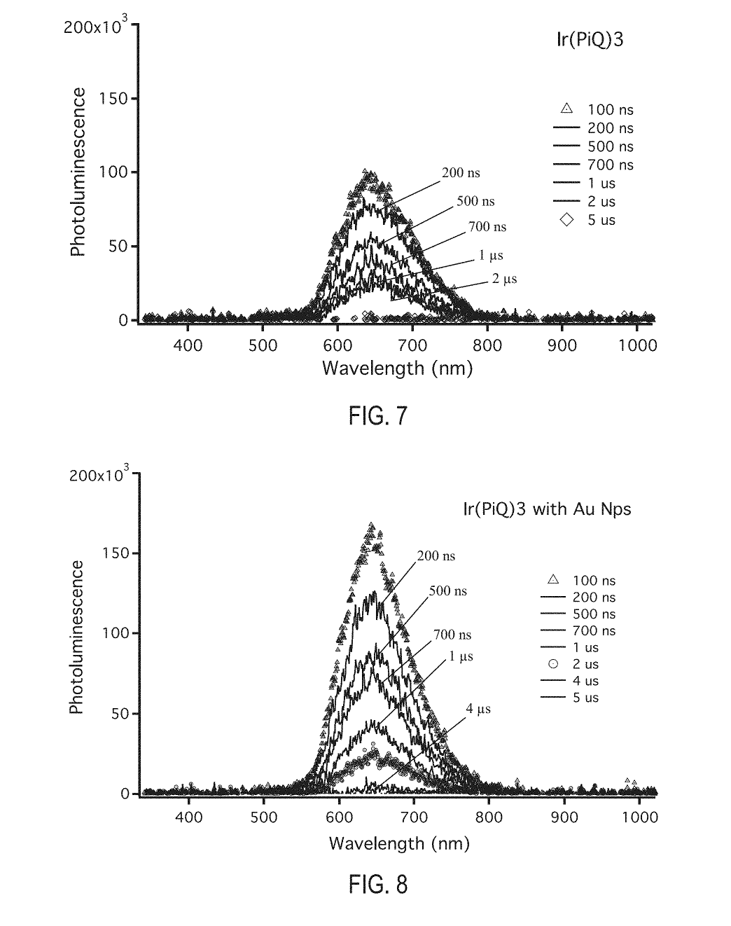

The delayed luminescence dynamics of the neat film and the Au Np doped Ir(PiQ)3 film is shown in FIGS. 7 and 8 respectively. The spectra in FIG. 7 were collected at room temperature with an excitation of 532 nm pulses. Excitation energy was recorded to be 2×10⁻⁴ J. The spectra in FIG. 8 were collected at room temperature with an excitation of 532 nm pulses. Excitation energy was recorded to be 2×10⁻⁴ J.

The delayed luminescence spectra resemble the respective prompt fluorescence spectra. The Au doped films showed much higher emission counts at all time scales with respect to their neat film counterparts. This is a hint that Au Nps enhance the efficiency of the films. All time resolved experiments were performed under vacuum.

Several reports have been presented on the use of noble metals to enhance the efficiency of devices by utilizing their surface plasmon resonance (SPR) properties [J. H. Park, et.al., Chem. Mater. 2004, 16,688-692]. SPR usually kicks in at around 30 nm and such sizes become comparable to layer thickness resulting in alteration of electrical properties. One remarkable feature of our claim is that our particles are on an average 2 nm—orders of magnitude smaller than the ones mentioned in other reports. Not to be bound by theory, it is believed that materials with noble metal nanoparticles do not exhibit signs of SPR, but rather enhance the efficiency by decreasing or tuning the lifetime. This phenomenon has been named the Metal Assisted Lifetime Tuning (MALT).

### Refractive Index Effect

In general, refractive index is a function of wavelength. The gold nanoparticles have a very low refractive index which can be tuned with size and concentration [S. Kubo et. Al; Nano Lett. 2007, 11 (3418-3423). This means adding gold nanoparticles would lower the refractive index of the EML, which would correspond to larger critical angle (from Snell's Law). This means greater amount of internal outcoupling is possible.

Transmittance is related to absorbance by Beer's Law equation as—

T=10^{-A}

where T is the optical transmittance and A is the absorbance.

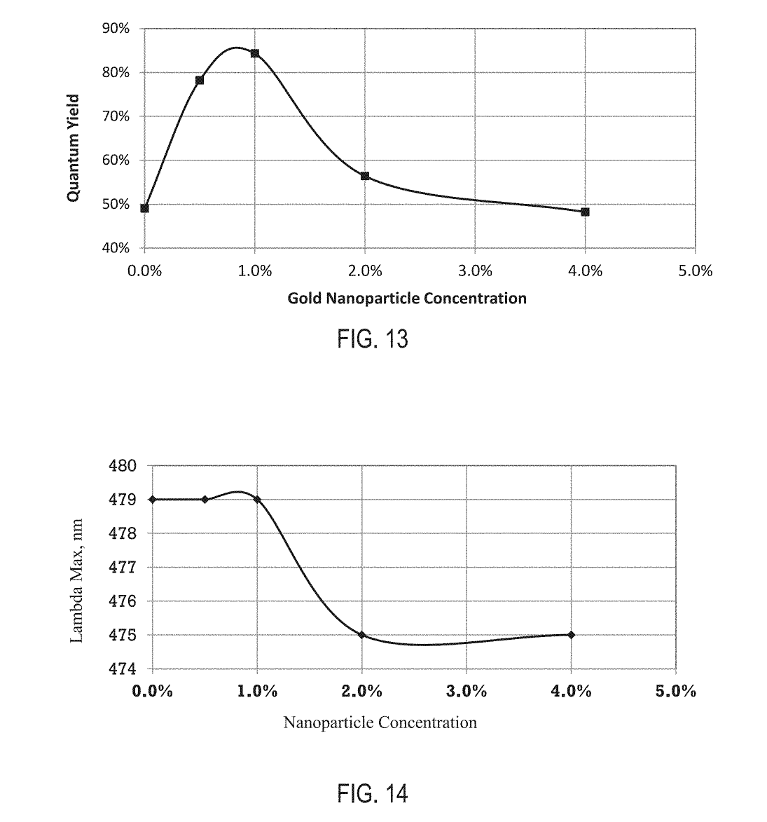

Based on the above equation and substituting the absorbance values, we calculated T_{no gold}=99% and T_{gold}=99.8%. Clearly the transmission is enhanced (FIG. 13). This enhancement of 3% in this particular case along with the lowering of refractive index is expected to be a powerful combination to enhance the outcoupling of light in an OLED device as per Fresnel equations.

### Comparative Example 2: Proprietary Phosphorescent Yellow Emitter in Non-Crystallizable Glass Mixture 22

A solution was made up consisting of 15 wt % of the of a proprietary phosphorescent yellow emitter and 85 w % of the non-crystallizable glass mixture 22 in dichloromethane. The solution was drop casted using the procedure of example 1.

### Example 2: Proprietary Phosphorescent Yellow Emitter in Non-Crystallizable Glass Mixture 22 Incorporating Gold Nanoparticles

The procedure of example 1 was followed to prepare the proceeding samples.

### Absorption and Emission

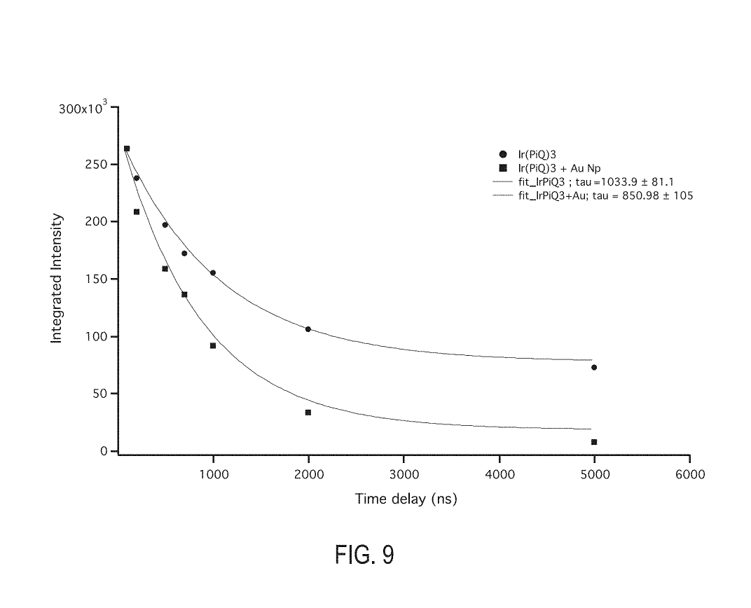

FIG. 9 shows the absorption and emission spectra for comparative example 2. The unfilled and filled circles represent the absorption and emission spectrum respectively for comparative example 2. The unfilled and filled squares represent the absorption and emission spectrum respectively for example 2. The absorption spectra were normalized to the absorption max of example 2. Overall the features remain same with the incorporation of Au Np. The emission spectra remain unchanged other than a slight bluer peak shift of ˜2 nm with the introduction of Au Nps. The peak max for proprietary phosphorescent yellow emitter was recorded at 599 nm and for the Au doped film it was 597 nm. The lifetime of Ir(PiQ)3 film was around 1050 ns and in good agreement with reported lifetime of 1.1 microseconds [H. Yersin, Highly Efficient OLEDs with Phosphorescent Materials, Wiley-VCH, 2008].

### Time Resolved Emission

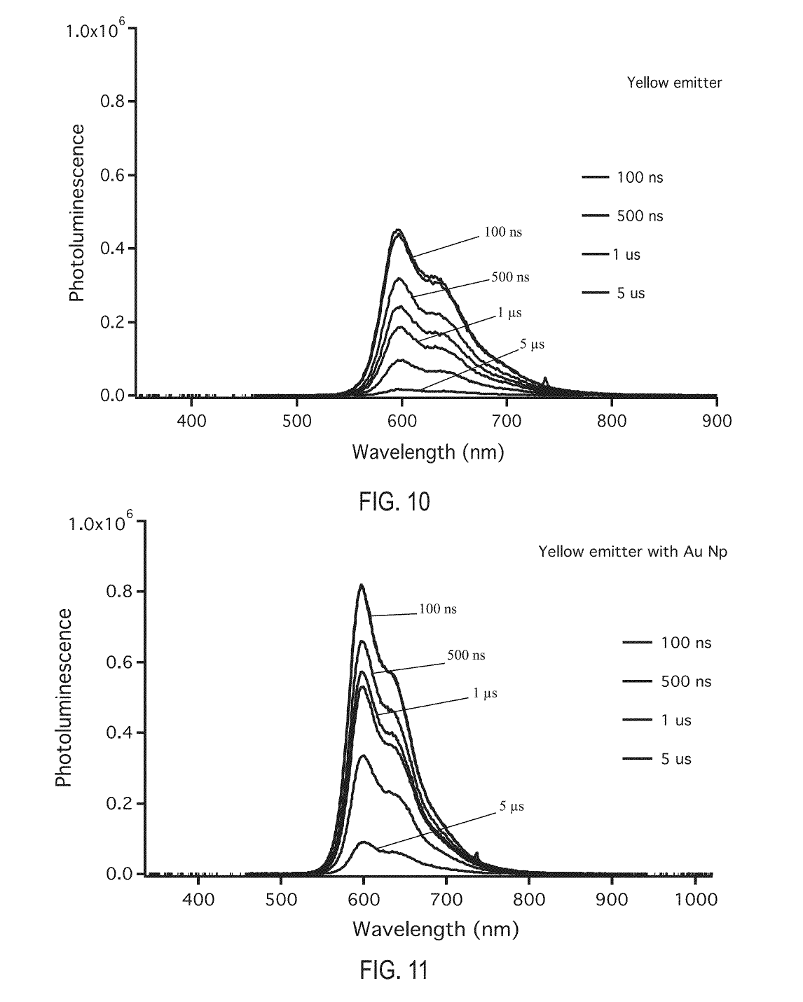

The spectra in FIG. 10 were collected at room temperature with an excitation of 355 nm pulses. Excitation energy was recorded to be 2×10⁻⁴ J. The time resolved emission spectra were integrated from 550 nm to 750 nm and plotted as a function of time delay as shown in FIG. 10. The decay plots were normalized with respect to the max value, i.e., the integrated intensity at 100 ns. The solid lines represent the single exponential fits to the data. Clearly one can see that the lifetime is reduced by approximately 25%, which correlates to the previous observation of higher luminescence of Au doped films with respect to neat films.

### Delayed Luminescence

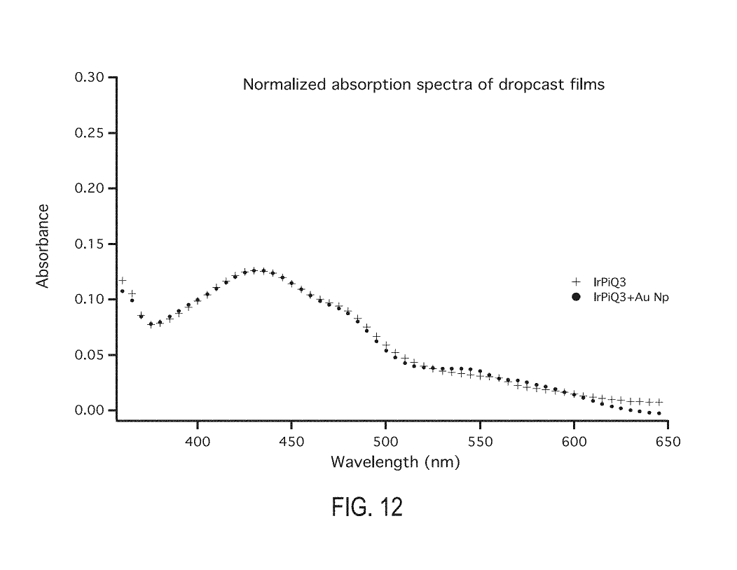

The delayed luminescence dynamics of the neat film and the Au Np doped Ir(PiQ)3 film is shown in FIGS. 11 and 12 respectively. The spectra in FIG. 11 were collected at room temperature with an excitation of 532 nm pulses. The samples to produce the spectra of FIG. 12 were excited with 355 nm laser pulses at room temperature under vacuum. Spectra was integrated from 550 nm to 750 nm. Error in each reading approximately ±2% came from the fluctuations in the laser pulses. Excitation energy was recorded to be 2×10⁻⁴ J. The delayed luminescence spectra resemble the respective prompt fluorescence spectra. The Au doped films showed much higher emission counts at all time scales with respect to their neat film counterparts. This is a hint that Au Nps enhance the efficiency of the films. All time resolved experiments were performed under vacuum.

### Example 3: Effect of Gold Nanoparticle Concentration in Neat DMAC-DPS Films

A sample of 0.4 mg of DMAC-DPS, 10,10′-(4,4′-Sulfonylbis(4,1-phenylene)) bis(9,9-dimethyl-9,10-dihydroacridine) a blue TADF emitter obtained from Lumtec were weighed and added to 6.4 mL of solvent to make 1 mg/mL of solution. A 1 mL aliquote of the above solution was transferred to 6 different vials marked A-E.

The Au nanoparticles were already dispersed in THF from earlier experiments. The concentration was 1 mg/mL. An aliquot of 5 μL, 10 μL, 20 μL, 40 μL and 100 μL of Au nps solution were added to the vials B, C, D, E and F to make concentrations of about 0.5%, 1%, 2%, 4% and 10% of Au nanoparticles by volume.

Absorption measurements were performed by taking a 0.1 mL aliquot of each of the solutions from the vials was added to 3 ml of THF in transparent quartz cuvettes of 1 cm path length for absorption measurements.

### Example 4 Effect of Gold Nanoparticle Concentration in Ambipolar Mixture 136: DMAC-DPS (90:10 Wt./Wt.) Film

The procedure of Example 3 was used, except that the ambipolar mixture 136 host material was introduced in a 90:10 wt./wt. ratio with DMAC-DPS.

### Example 5 Fabrication of and OLED Device Incorporating an Emitter Layer Containing Gold Nanoparticle: Effect of Gold Nanoparticle Concentration

A set of four devices were fabricated with structure below;

| Anode | HIL/HTL | EML | ETL | EIL | Cathode |
|---|---|---|---|---|---|
| ITO | PEDOT: | Host (90%) | TBPi | LiF | Al |
| 80 nm | PSS 40 nm | Phosphorescent | 30 nm | 5 nm | 100 nm |
| | | Yellow Emitter | | | |
| | | (10%) 20 nm | | | |
| | | Gold Nanoparticle: | | | |
| | | 0% 1%, 2%, 6% | | | |

PEDOT: PSS, poly (3,4-ethylenedioxythiophene)-poly (styrene sulfonate), Heraeus Clevios A14083, obtained from Ossila Ltd Sheffield UK with isopropanol and spun at 3000 rpm for a minute and baked in an oven at 120° C. for 6 minutes. After cooling, a similar procedure was followed for coating the emitter layer at 3000 rpm for one minute under a nitrogen flushed glove box. The four emitter layer solutions included asymmetric glass mixture 6 and the proprietary phosphorescent yellow emitter at a ratio of 90:10 wt./wt. respectively containing 0%, 1%, 2%, and 6% gold nanoparticle. Finally, the samples were transferred to a vacuum chamber where TPBi, LiF and Al layers were evaporated. The final devices were encapsulated before exposure to room atmosphere.

The graph in FIG. 13, the quantum yield for DMAC-DPS neat films as a function of gold nanoparticle concentration had a max at slightly less than 1.0% gold nanoparticles.

The graph in FIG. 14, the lambda max for DMAC-DPS neat films as a function of gold nanoparticle concentration decreased as the percent of nanoparticles increased.

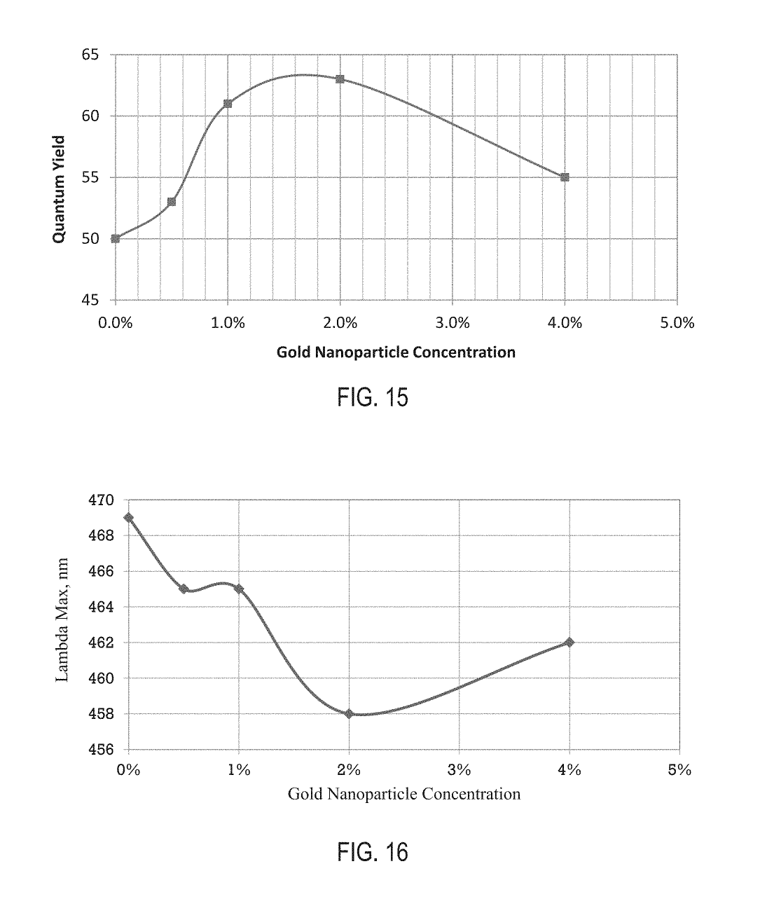

The graph in FIG. 15 shows the quantum yield for ambipolar mixture 136 and DMAC-DPS 90:10 wt/wt mixture as a function of gold nanoparticle concentration.

FIG. 16 shows the lambda max for ambipolar mixture 136 and DMAC-DPS 90:10 wt/wt mixture as a function of gold nanoparticle concentration.

### Electroluminescence Study:

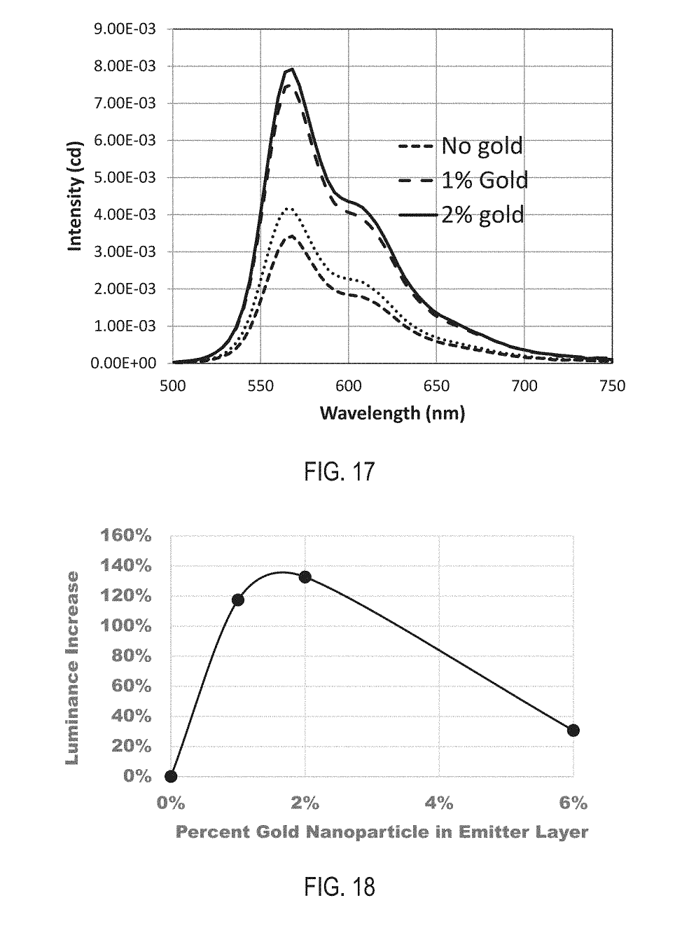

FIG. 17 shows the electroluminescence curves for the four devices. As can be seen the electroluminescence increases with concentration from 0 to 2% and decreases at 6% but is still slightly higher than the control even at 6%. This behavior is similar to the photoluminescence response, confirming that the gold nanoparticles enhance the efficiency of the OLED device.

### Comparative Luminance Study:

FIG. 18 shows the comparative luminance for devices as a function of gold nanoparticle concentration normalized with the control no gold device. The results show a 133% increase in luminance at 2% gold nanoparticle concentration.

1. A solvent coatable emitter composition comprising:
an emitter material; and
noble metal nanoparticles having a median size of less than or equal to 5 nanometers, wherein the size distribution is less than 20%.

2. The emitter composition of claim 1, wherein the median size of less than or equal to 2 nanometers.

3. The emitter composition of claim 1, wherein the noble metal nanoparticles are chosen from copper nanoparticles, silver nanoparticles, or gold nanoparticles.

4. The emitter composition of claim 1, wherein the emitter material is a triplet emitter.

5. The emitter composition of claim 1, wherein the emitter material is a thermally activated delayed fluorescence emitter.

6. The emitter composition of claim 1, further comprising a non-crystallizable molecular glass organic semiconductor.

7. The emitter composition of claim 6, wherein the non-crystallizable molecular glass organic semiconductor is a hole-transporting molecular glass mixture.

8. The emitter composition of claim 6, wherein the non-crystallizable molecular glass organic semiconductor is an electron-transporting molecular glass mixture.

9. The emitter composition of claim 6, wherein the non-crystallizable molecular organic glass semiconductor is an ambipolar molecular glass mixture.

10. The emitter composition of claim 6, wherein the non-crystallizable molecular glass organic semiconductor is a high-entropy molecular glass mixture.

11. The emitter composition of claim 6, wherein the non-crystallizable molecular organic semiconductor is an isomeric molecular glass mixture.

12. The emitter composition of claim 6, wherein the non-crystallizable molecular organic semiconductor is selected from the group consisting of glass mixtures 4, 6, 7, 8, 9, 22, 32, 50, 60, 65, 70, 73, 80, 85, 90, 95, 100, 105, 110, 115, 121, 122, 123, 124, 125, 126, 127, 128, 129, 130, 132, 133, 134, 135, and 136.

13. The emitter composition of claim 1, wherein the refractive index of the emitter composition is less than the refractive index of an emitter composition without the noble metal nanoparticles.

14. An OLED multilayer electroluminescent device comprising:
a light-emitting layer (LEL) disposed between a cathode and an anode, the light-emitting layer comprising the emitter composition of claim 1 and a high-entropy non-crystallizable molecular semiconductor mixture host; and,
at least one charge-transporting layer,
wherein the charge transporting layer is disposed between:
(A) the cathode and the light-emitting layer;
(B) the anode and the light-emitting layer; or
(C) both (A) and (B).

15. The OLED device of claim 14, wherein the device is bottom emitting.

16. The OLED device of claim 14, wherein the device is top emitting.

17. The OLED device of claim 14, wherein the noble metal nanoparticles are chosen from gold nanoparticles, copper nanoparticles, or silver nanoparticles.

18. A method of making a light-emitting layer comprising:
dissolving an emitter in a solvent to form an emitter solvent;
adding a noble metal nanoparticle to the emitter solvent to form a nanoparticle/emitter solution;
coating the nanoparticle/emitter solution onto a host material; and
removing the solvent at a temperature of 25° C. or less than 25° C.

19. The method of making a light-emitting layer of claim 18, wherein the nanoparticle/emitter solution has a concentration of non-plasmonic molecular noble metal from 0.50 volume percent to 6 volume percent in the emitter/nanoparticle solution.

20. A method of making a light-emitting layer comprising:
forming a light-emitting layer;
coating the light-emitting layer with a noble metal solution, wherein noble metal solution comprises noble metal nanoparticles dispersed in solvent; and
removing the solvent at a temperature less than 50° C.
